(19) United States
(12) Patent Application Publication
(10) Pub. No.: US 2008/0118867 A1
(43) Pub. Date: May 22, 2008

(54) Pattern Forming Material, Pattern Forming Apparatus, And Pattern Forming Process

(76) Inventors: Morimasa Sato, Shizuoka (JP); Tomoko Tashiro, Shizuoka (JP); Masanobu Takashima, Shizuoka (JP); Shinichiro Serizawa, Shizuoka (JP)

Correspondence Address: SUGHRUE MION, PLLC, 2100 PENNSYLVANIA AVENUE, N.W., SUITE 800, WASHINGTON, DC, 20037, US

(21) Appl. No.: 11/596,056

(22) PCT Filed: May 9, 2005
(86) PCT No.: PCT/JP05/08818

§ 371 Date: Jul. 26, 2007

(30) Foreign Application Priority Data
May 12, 2004 (JP) 2004-142949
Jun. 16, 2004 (JP) 2004-178904
Nov. 12, 2004 (JP) 2004-329495
Nov. 12, 2004 (JP) 2004-329514
Apr. 28, 2005 (JP) 2005-133256

(51) Int. Cl. G03F 7/039; G03F 7/26; G03B 27/54

(52) U.S. Cl. 430/286.1; 430/322; 355/67

(57) ABSTRACT

The objects of the present invention are to provide pattern forming materials capable of effectively suppressing sensitivity drop of photosensitive layers as well as capable of forming highly fine and precise patterns, pattern forming apparatuses equipped with the pattern forming materials, and pattern forming processes utilizing the pattern forming materials. In order to attain the objects, a pattern forming material is provided which comprises a support, and a photosensitive layer on the support, wherein the photosensitive layer comprises a polymerization inhibitor, a binder, a polymerizable compound, and a photopolymerization initiator, the photosensitive layer is exposed by means of a laser beam and developed by means of a developer to form a pattern, and the minimum energy of the laser beam is 0.1 mJ/cm² to 10 mJ/cm², which is required to yield substantially the same thickness of photosensitive layer subsequent to the developing as the thickness of the photosensitive layer prior to the exposing.

### TECHNICAL FIELD

The present invention relates to pattern forming materials suited for dry film resists for example, pattern forming apparatuses equipped with the pattern forming materials, and pattern forming processes utilizing the pattern forming materials.

### BACKGROUND ART

Recently, pattern forming materials are widely utilized for forming permanent patterns such as wiring patterns, in which pattern forming materials are typically produced by coating a photosensitive resin composition on a substrate and drying the coating to form a photosensitive layer. Further, permanent patterns are produced by, for example, laminating a pattern forming material on a substrate such as copper laminated sheet, on which the permanent pattern is to be formed, to form a laminated sheet, exposing the photosensitive layer of the laminated sheet, then developing the photosensitive layer to form a pattern, and additional treatments such as etching.

Among various proposals in connection with the pattern forming materials, addition of polymerization inhibitor into the photosensitive resin composition is proposed so as to prolong the storage period or to improve the resolution, in which the polymerization inhibitor is comprised of a compound having a phenolic hydroxide group, aromatic ring, heterocyclic ring, or the like (see Patent Literatures 1 to 4, for example). However, any disclosures cannot be seen with respect to the effect to suppress sensitivity drop due to adding a photosensitizer into the photosensitive resin composition or highly sensitive dry resist film, in the publicly known literatures or in the prior art.

As such, pattern forming materials, capable of suppressing sensitivity drop of photosensitive layers as well as capable of forming highly fine and precise patterns, have not been provided yet; and pattern forming materials, pattern forming apparatuses, and pattern forming processes are needed for further improvements currently.

Patent Literature 1: Japanese Patent Application Laid-Open No. 2002-268211

Patent Literature 2: Japanese Patent Application Laid-Open No. 2003-29399

Patent Literature 3: Japanese Patent Application Laid-Open No. 2004-4527

Patent Literature 4: Japanese Patent Application Laid-Open No. 2004-4528

### DISCLOSURE OF INVENTION

The objects of the present invention are to provide pattern forming materials capable of effectively suppressing sensitivity drop of photosensitive layers as well as capable of forming highly fine and precise patterns, pattern forming apparatuses equipped with the pattern forming materials, and pattern forming processes utilizing is the pattern forming materials.

The objects of the present invention can be attained by the pattern forming material according to the present invention which comprises a support, and a photosensitive layer on the support, wherein the photosensitive layer comprises a polymerization inhibitor, a binder, a polymerizable compound, and a photopolymerization initiator, the photosensitive layer is exposed by means of a laser beam and developed by means of a developer to form a pattern, and the minimum energy of the laser beam is 0.1 mJ/cm² to 10 mJ/cm², which is required to yield substantially the same thickness of photosensitive layer subsequent to the developing as the thickness of the photosensitive layer prior to the exposing.

The photosensitive layer comprises a polymerization inhibitor, a binder, a polymerizable compound, and a photopolymerization initiator; therefore, the minimum energy of the laser beam falls in a range, which is required to yield substantially the same thickness of photosensitive layer subsequent to the developing as the thickness of the photosensitive layer prior to the exposing. Consequently, highly fine and precise patterns may be easily obtained from the pattern forming material through developing thereof.

Preferably, the haze of the support is 5.0% or less; the total light transmittance of the support is 86% or more; the haze and the total light transmittance of the support is determined at an optical wavelength of 405 nm; a coating layer that contains inert fine particles is provided on at least one side of the support; and the support is formed of a biaxially oriented polyester film.

Preferably, the laser beam from a laser source is modulated by a laser modulator that comprises plural imaging portions each capable of receiving the laser beam and outputting the modulated laser beam, the modulated laser beam is transmitted through a microlens array of plural microlenses each having a non-spherical surface capable of compensating the aberration due to distortion of the output surface of the imaging portions, and the photosensitive layer is exposed by the modulated and transmitted laser beam.

Preferably, the laser beam from a laser source is modulated by a laser modulator that comprises plural imaging portions each capable of receiving the laser beam and outputting the modulated laser beam, the modulated laser beam is transmitted through a microlens array of plural microlenses each having an aperture configuration capable of substantially shielding incident light other than the modulated laser beam from the laser modulator, and the photosensitive layer is exposed by the modulated and transmitted laser beam.

Preferably, the polymerization inhibitor comprises at least one of an aromatic ring, a heterocyclic ring, an imino group, and a phenolic hydroxide group; the polymerization inhibitor comprises a compound selected from the group consisting of compounds having at least two phenolic hydroxide groups, compounds having an aromatic group substituted by an imino group, compounds having a heterocyclic ring substituted by an imino group, and hindered amine compounds; the polymerization inhibitor comprises a compound selected from the group consisting of catechol, phenothiazine, phenoxazine, hindered amines, and derivatives thereof; and the content of the polymerization inhibitor is 0.005% by mass to 0.5% by mass based on the polymerizable compound.

Preferably, the minimum energy of the laser beam is determined at an optical wavelength of 405 nm.

Preferably, the photosensitive layer comprises a photosensitizer; the maximum absorption wavelength of the photosensitizer appears within a range of 380 nm to 450 nm; the photosensitizer is a fused ring compound; and the photosensitizer comprises a compound selected from the group consisting of acridones, acridines, and coumarins.

Preferably, the binder comprises a compound having an acidic group; the binder comprises a vinyl copolymer; the binder comprises a copolymer selected from the group consisting of styrene copolymers and styrene derivative copolymers; and the binder has an acidic value of 70 mg KOH/g to 250 mg KOH/g.

Preferably, the polymerizable compound comprises a monomer that contains at least one of a urethane group and an aryl group; and the polymerizable compound has a bisphenol backbone.

Preferably, the photopolymerization initiator comprises a compound selected from the group consisting of halogenated hydrocarbon derivatives, hexaaryl biimidazoles, oxime derivatives, organic peroxides, thio compounds, ketone compounds, aromatic onium salts, and metallocenes; and the photopolymerization initiator comprises a derivative of 2,4,5-triarylimidazole dimer.

Preferably, the thickness of the photosensitive layer is 1 μm to 100 μm; the support is of an elongated shape; the pattern forming material is of an elongated shape formed by winding into a roll shape; and a protective film is provided on the photosensitive layer of the pattern forming material.

In another aspect, the present invention provide a pattern forming apparatus that comprises a laser source, a laser modulator, and a pattern forming material, wherein the laser source is capable of irradiating a laser beam, and the laser modulator is capable of modulating the laser beam from the laser source and also capable of exposing the photosensitive layer of the pattern forming material, the pattern forming material comprises a support and a photosensitive layer on the support, the photosensitive layer comprises a polymerization inhibitor, a binder, a polymerizable compound, and a photopolymerization initiator, the photosensitive layer is exposed by means of a laser beam and developed by means of a developer to form a pattern, and the minimum energy of the laser beam is 0.1 mJ/cm² to 10 mJ/cm², which is required to yield substantially the same thickness of photosensitive layer subsequent to the developing as the thickness of the photosensitive layer prior to the exposing.

In the pattern forming apparatus, the laser modulator modulates the laser beam from the laser source and also exposes the photosensitive layer of the pattern forming material, and the minimum energy of the laser beam falls in a range. Consequently, highly fine and precise patterns may be easily obtained from the pattern forming material through developing thereof.

Preferably, the laser modulator further comprises a pattern signal generator configured to generate a control signal based on pattern information, and the laser modulator modulates the laser beam from the laser source depending on the control signal from the pattern signal generator. In this constitution, the laser beam from the laser source may be effectively modulated to form highly fine and precise patterns.

Preferably, the laser modulator is capable of controlling a part of the plural imaging portions depending on pattern information. In this constitution, the laser beam from the laser source may be modulated rapidly.

Preferably, the laser modulator is a spatial light modulator; the spatial light modulator is a digital micromirror device (DMD); and the imaging portions are comprised of micromirrors.

Preferably, the laser source is capable of irradiating two or more types of laser beams together with. In this constitution, the exposing may be performed with laser beam having longer focal depth. Consequently, highly fine and precise patterns may be easily obtained.

Preferably, the laser source comprises plural lasers, a multimode optical fiber, and a collective optical system that collects the laser beams from the plural lasers into the multimode optical fiber. In this constitution, the exposing may also be performed with laser beam having longer focal depth, and highly fine and precise patterns may be easily obtained.

In another aspect, the present invention provide a pattern forming process that comprises exposing a photosensitive layer of a pattern forming material, wherein the pattern forming material comprises a support and the photosensitive layer on the support, and the photosensitive layer comprises a polymerization inhibitor, a binder, a polymerizable compound, and a photopolymerization initiator, the photosensitive layer is exposed by means of a laser beam and developed by means of a developer to form a pattern, and the minimum energy of the laser beam is 0.1 mJ/cm² to 10 mJ/cm², which is required to yield substantially the same thickness of photosensitive layer subsequent to the developing as the thickness of the photosensitive layer prior to the exposing.

In the pattern forming process, the pattern forming material may bring about highly fine and precise patterns.

Preferably, the pattern forming material is laminated on the substrate under one of heating and pressing and is exposed; the exposing is performed image-wise depending on pattern information to be formed; the exposing is performed by means of a laser beam that is modulated depending on a control signal, and the control signal is generated depending on pattern information to be formed; and the exposing is performed by use of a laser source for irradiating a laser beam and a laser modulator for modulating the laser beam depending on pattern information to be formed.

Preferably, the photosensitive film is exposed by means of a laser beam subjected to modulating by a laser modulator and then compensating, and the compensating is performed by transmitting the modulated laser beam through plural microlenses each having a non-spherical surface capable of compensating the aberration due to distortion of the output surface of the imaging portion. In this constituent, the aberration may be suppressed and the distortion of images may be suppressed. Consequently, highly fine and precise patterns may be easily obtained.

Preferably, the photosensitive film is exposed by means of a laser beam subjected to modulating by a laser modulator and then transmitting through a microlens array of plural microlenses, and the microlens array has an aperture configuration of the plural microlenses capable of substantially shielding incident light other than the modulated laser beam from the laser modulator. In this constituent, the distortion of images may be suppressed; consequently, highly fine and precise patterns may be easily obtained.

Preferably, each of the microlenses has a non-spherical surface capable of compensating the aberration due to distortion of the output surface of the imaging portions; the non-spherical surface is a toric surface; each of the microlenses has a circular aperture configuration; and the aperture configuration of the plural microlenses is defined by light shielding provided on the microlens surface.

Preferably, the exposing is performed by the laser beam transmitted through an aperture array; the exposing is performed while moving relatively the laser beam and the photosensitive layer; the exposing is performed on a partial region of the photosensitive layer; and developing of the photosensitive layer is performed subsequent to the exposing.

Preferably, a permanent pattern is formed subsequent to the developing; and the permanent pattern is a wiring pattern, and the permanent pattern is formed by at least one of etching and plating.

### BRIEF DESCRIPTION OF DRAWINGS

FIG. 1 is a partially enlarged view that shows exemplarily a construction of a digital micromirror device (DMD).

FIG. 2A is a view that explains exemplarily the motion of the DMD.

FIG. 2B is a view that explains exemplarily the motion of the DMD.

FIG. 3A is an exemplary plan view that shows the exposing beam and the scanning line in the case that the DMD is not inclined.

FIG. 3B is an exemplary plan view that shows the exposing beam and the scanning line in the case that the DMD is inclined.

FIG. 4A is an exemplary view that shows an available region of the DMD.

FIG. 4B is an exemplary view that shows another available region of the DMD.

FIG. 5 is an exemplary plan view that explains a way to expose a photosensitive layer in one scanning by means of a scanner.

FIG. 6A is an exemplary plan view that explains a way to expose a photosensitive layer in plural scannings by means of a scanner.

FIG. 6B is another exemplary plan view that explains a way to expose a photosensitive layer in plural scannings by means of a scanner.

FIG. 7 is a schematic perspective view that shows exemplarily a pattern forming apparatus.

FIG. 8 is a schematic perspective view that shows exemplarily a scanner construction of a pattern forming apparatus.

FIG. 9A is an exemplary plan view that shows exposed regions formed on a photosensitive layer.

FIG. 9B is an exemplary plan view that shows regions exposed by respective exposing heads.

FIG. 10 is a schematic perspective view that shows exemplarily an exposing head containing a laser modulator.

FIG. 11 is an exemplary cross section that shows the construction of the exposing head shown in FIG. 10 in the sub-scanning direction along the optical axis.

FIG. 12 shows an exemplary controller to control the DMD based on pattern information.

FIG. 13A is an exemplary cross section that shows a construction of another exposing head in other connecting optical system along the optical axis.

FIG. 13B is an exemplary plan view that shows an optical image projected on an exposed surface when a microlens array is not employed.

FIG. 13C is an exemplary plan view that shows an optical image projected on an exposed surface when a microlens array is employed.

FIG. 14 is an exemplary view that shows distortion of a reflective surface of a micromirror that constitutes a DMD by means of contour lines.

FIG. 15A is an exemplary graph that shows height displacement of a micromirror along the X direction.

FIG. 15B is an exemplary graph that shows height displacement of a micromirror along the Y direction.

FIG. 16A is an exemplary front view that shows a microlens array employed in a pattern forming apparatus.

FIG. 16B is an exemplary side view that shows a microlens array employed in a pattern forming apparatus.

FIG. 17A is an exemplary front view that shows a microlens of a microlens array.

FIG. 17B is an exemplary side view that shows a microlens of a microlens array.

FIG. 18A is an exemplary view that schematically shows a laser collecting condition in a cross section of a microlens.

FIG. 18B is an exemplary view that schematically shows a laser collecting condition in another cross section of a microlens.

FIG. 19A is an exemplary view that shows a simulation of beam diameters near the focal point of a microlens in accordance with the present invention.

FIG. 19B is an exemplary view that shows another simulation similar to FIG. 19A in terms of other sites in accordance with the present invention.

FIG. 19C is an exemplary view that shows still another simulation similar to FIG. 19A in terms of other sites in accordance with the present invention.

FIG. 19D is an exemplary view that shows still another simulation similar to FIG. 19A in terms of other sites in accordance with the present invention.

FIG. 20A is an exemplary view that shows a simulation of beam diameters near the focal point of a microlens in a conventional pattern forming process.

FIG. 20B is an exemplary view that shows another simulation similar to FIG. 20A in terms of other sites.

FIG. 20C is an exemplary view that shows still another simulation similar to FIG. 20A in terms of other sites.

FIG. 20D is an exemplary view that shows still another simulation similar to FIG. 20A in terms of other sites.

FIG. 21 is an exemplary plan view that shows another construction of a combined laser source.

FIG. 22A is an exemplary front view that shows a microlens of a microlens array.

FIG. 22B is an exemplary side view that shows a microlens of a microlens array.

FIG. 23A is an exemplary view that schematically shows a laser collecting condition in the cross section of the microlens shown in FIG. 22B.

FIG. 23B is an exemplary view that schematically shows a laser collecting condition in another cross section of the microlens shown in FIG. 22B.

FIG. 24A is an exemplary view that explains the concept of compensation by an optical system of optical quantity distribution compensation.

FIG. 24B is another exemplary view that explains the concept of compensation by an optical system of optical quantity distribution compensation.

FIG. 24C is another exemplary view that explains the concept of compensation by an optical system of optical quantity distribution compensation.

FIG. 25 is an exemplary graph that shows an optical quantity distribution of Gaussian distribution without compensation of optical quantity.

FIG. 26 is an exemplary graph that shows a compensated optical quantity distribution by an optical system of optical quantity distribution compensation.

FIG. 27A (A) is an exemplary perspective view that shows a constitution of a fiber array laser source.

FIG. 27A (B) is a partially enlarged view of FIG. 27A (A).

FIG. 27A (C) is an exemplary plan view that shows an arrangement of emitting sites of laser output.

FIG. 27A (D) is an exemplary plan view that shows another arrangement of laser emitting sites.

FIG. 27B is an exemplary front view that shows an arrangement of laser emitting sites in a fiber array laser source.

FIG. 28 is an exemplary view that shows a construction of a multimode optical fiber.

FIG. 29 is an exemplary plan view that shows a construction of a combined laser source.

FIG. 30 is an exemplary plan view that shows a construction of a laser module.

FIG. 31 is an exemplary side view that shows a construction of the laser module shown in FIG. 30.

FIG. 32 is a partial side view that shows a construction of the laser module shown in FIG. 30.

FIG. 33 is an exemplary perspective view that shows a construction of a laser array.

FIG. 34A is an exemplary perspective view that shows a construction of a multi cavity laser.

FIG. 34B is an exemplary perspective view that shows a multi cavity laser array in which the multi cavity lasers shown in FIG. 34A are arranged in an array.

FIG. 35 is an exemplary plan view that shows another construction of a combined laser source.

FIG. 36A is an exemplary plan view that shows still another construction of a combined laser source.

FIG. 36B is an exemplary cross section of FIG. 36A along the optical axis.

FIG. 37A is an exemplary cross section of an exposing device that shows focal depth in the pattern forming process of the prior art.

FIG. 37B is an exemplary cross section of an exposing device that shows focal depth in the pattern forming process according to the present invention.

FIG. 38A is a front view of another exemplary microlens that constitute a microlens array.

FIG. 38B is a side view of another exemplary microlens that constitute a microlens array.

FIG. 39A is a front view of still another exemplary microlens that constitute a microlens array.

FIG. 39B is a side view of still another exemplary microlens that constitute a microlens array.

FIG. 40 is an exemplary graph that shows a lens configuration.

FIG. 41 is an exemplary graph that shows another lens configuration.

FIG. 42 is an exemplary perspective view that shows a microlens array.

FIG. 43 is an exemplary plan view that shows another microlens array.

FIG. 44 is an exemplary plan view that shows still another microlens array.

FIG. 45A is an exemplary longitudinal section that shows still another microlens array.

FIG. 45B is an exemplary longitudinal section that shows still another microlens array.

FIG. 45C is an exemplary longitudinal section that shows still another microlens array.

### BEST MODE FOR CARRYING OUT THE INVENTION

### Pattern Forming Material

The pattern forming material according to the present invention comprises a photosensitive layer on a substrate, and may comprise other layers depending on requirements.

The photosensitive layer comprises a polymerization inhibitor, binder, polymerizable compound, and photopolymerization initiator, and also may comprise the other ingredients such as a photosensitizer depending on requirements.

### <Photosensitive Layer>

In exposing and developing the photosensitive layer, the minimum energy of the laser beam, which is irradiated onto the photosensitive layer and is required to yield substantially the same thickness of photosensitive layer subsequent to the developing as the thickness of the photosensitive layer prior to the exposing, is 0.1 mJ/cm² to 10 mJ/cm² per unit surface area of the photosensitive layer. Specifically, the minimum energy of the laser beam may be properly selected depending on the application; the minimum energy of the laser beam is preferably 0.5 to 8 mJ/cm², more preferably is 1 to 5 mJ/cm².

When the minimum energy of the laser beam is less than 0.1 mJ/cm², fogs tend to appear in processing; and when the minimum energy of the laser beam is more than 10 mJ/cm², longer period is often necessary for processing such as exposing.

The minimum energy of the laser beam, defined as the minimum value within the range that yields substantially the same thickness of the photosensitive layer between unexposed condition and exposed-developed condition, means so-called sensitivity, which can be determined from the relation between the optical energy or exposed energy quantity and the thickness of hardened layer obtained subsequent to the exposing and the developing.

The thickness of hardened layer typically increases with the increase of exposed energy quantity, then saturates to a certain thickness that is approximately equivalent to the thickness of the photosensitive layer prior to the exposing. The so-called sensitivity can be determined by estimating the minimum exposed energy quantity at which the thickness of hardened layer saturates.

In the present invention, when the difference is within ±1 μm between the thickness of photosensitive layer subsequent to the developing and the thickness of photosensitive layer prior to the exposing, both of the thicknesses are defined to be substantially the same or equivalent between prior to the exposing and subsequent to the developing.

The method to measure the thickness of the photosensitive layer prior to the exposing and subsequent to the developing may be properly selected depending on the application; for example, various instruments or devices for measuring film thickness or surface roughness may be utilized (e.g., SURFCOM 1400D, by Tokyo Seimitsu Co., Ltd.).

### —Polymerization Inhibitor—

The polymerization inhibitor may be properly selected depending on the application. The polymerization inhibitor acts on polymerization initiating radicals generated from photopolymerization initiators to deactivate the radicals through, for is example, hydrogen donating or accepting, energy donating or accepting, or electron donating or accepting, thereby performs to inhibit the polymerization.

Examples of the polymerization inhibitor may be a compound selected from those having an isolated electron pair such as compounds containing oxygen, nitrogen, sulfur, metals, or the like, and compounds having π-electron such as aromatic compounds. Specifically, the polymerization inhibitor may be compounds having a phenolic hydroxide group, compounds having an imino group, compounds having a nitro group, compounds having a nitroso group, compounds having an aromatic ring, compounds having a hetero ring, compounds containing a metal atom such as organic complexes, and the like. Among these compounds, preferable are compounds having a phenolic hydroxide group, compounds having an imino group, compounds having an aromatic ring, and compounds having a hetero ring.

The compounds having a phenolic hydroxide group may be properly selected depending on the application; preferably, the compounds contain at least two phenolic hydroxide groups in the molecule. The at least two phenolic hydroxide groups may be attached to one aromatic group or different aromatic groups in one molecule.

The compounds containing at least two phenolic hydroxide groups in the molecule may be exemplified by the following formula.

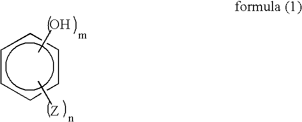

In the formula of phenolic compounds, Z is a substituent group; “m” is an integer of 2 or more; “n” is an integer of 0 or more; and preferably, m+n=6. When “n” is an integer of 2 or more, the respective Z may be identical or different. When “m” is less than 2, the resolution of the pattern forming material may be deteriorated.

Examples of the substituent include carboxylic group, sulfo group, cyano group; halogen atoms such as fluorine atom, chlorine atom, and bromine; hydroxyl group; alkoxy carbonyl groups having carbon atoms of 30 or less such as methoxy carbonyl group, ethoxy carbonyl group, and benzyloxy carbonyl group; aryloxy carbonyl groups having carbon atoms of 30 or less such as phenoxy carbonyl group; alkylsulfonyl aminocarbonyl groups having carbon atoms of 30 or less such as methylsulfonyl aminocarbonyl group and octylsulfonyl aminocarbonyl group; arylsulfonyl aminocarbonyl groups such as toluenesulfonyl aminocarbonyl group; acylamino sulfonyl groups having carbon atoms of 30 or less such as benzoylamino sulfonyl group, acetylamino sulfonyl group, and pivaloylamino sulfonyl group; alkoxy groups having carbon atoms of 30 or less such as methoxy group, ethoxy group, benzyloxy group, phenoxy ethoxy group, and phenethyloxy group; arylthio groups having carbon atoms of 30 or less; alkylthio groups such as phenylthio group, methylthio group, ethylthio group, and dodecylthio group; aryloxy groups having carbon atoms of 30 or less such as phenoxy group, p-tolyloxy group, 1-naphthoxy group, and 2-naphthoxy group; nitro group; alkyl groups having carbon atoms of 30 or less; alkoxy carbonyloxy groups such as methoxy carbonyloxy group, stearyloxy carbonyloxy group, and phenoxyethoxy carbonyloxy group; aryloxy carbonyloxy groups such as phenoxy carbonyloxy group, and chlorophenoxy carbonyloxy group; acyloxy groups having carbon atoms of 30 or less such as acetyloxy group and propionyloxy group; acyl groups having carbon atoms of 30 or less such as acetyl group, propionyl group, and benzoyl group; carbamoyl groups such as carbamoyl group, N,N-dimethyl carbamoyl group, morpholino carbonyl group, and piperidino carbonyl group; sulfamoyl groups such as sulfamoyl group, N,N-dimethyl sulfamoyl group, morpholino sulfonyl group, and piperidino sulfonyl group; alkyl sulfonyl groups having carbon atoms of 30 or less such as methylsulfonyl group, trifluoro methylsulfonyl group, ethylsulfonyl group, butylsulfonyl group, and dodecylsulfonyl group; arylsulfonyl groups such as benzene sulfonyl group, toluene sulfonyl group, naphthalene sulfonyl group, pyridine sulfonyl group, and quinoline sulfonyl group; aryl groups having carbon atoms of 30 or less such as phenyl group, dichlorophenyl group, toluic group, methoxyphenyl group, diethylamino phenyl group, acetylamino phenyl group, methoxycarbonyl phenyl group, hydroxyphenyl group, t-octyl phenyl group, and naphthyl group; substituted amino groups such as amino group, alkyl amino group, dialkyl amino group, aryl amino group, diaryl amino group, and acyl amino group; substitutes phosphonic groups such as phosphonic group, diethyl phosphonic group, and diphenyl phosphonic group; heterocyclic groups such as pyridyl group, quinolyl group, furyl group, thienyl group, tetrahydro furfuryl group, pyrazolyl group, isooxazolyl group, isothiazolyl group, imidazolyl group, oxazolyl group, thiazolyl group, pyridazyl group, pyrimidyl group, pyrazyl group, triazolyl group, tetrazolyl group, benzoxazolyl group, benzoimidazolyl group, isoquinolyl group, thiadiazoyl group, morpholino group, piperidino group, piperadino group, indryl group, isoindryl group, and thiomorpholino group; ureido groups such as methyl ureido group, dimethyl ureido group, and phenyl ureido group; sulfamoylamino groups such as dipropyl sulfamoylamino group; alkoxy carbonylamino groups such as ethoxy carbonylamino group; aryloxy carbonylamino groups such as phenyloxy carbonylamino group; alkylsulfinyl groups such as methylsulfinyl group; arylsulfinyl groups such as phenylsulfinyl group; silyl groups such as trimethoxy silyl group, triethoxy silyl group; and silyloxy groups such as trimethyl silyloxy group.

Examples of the compound expressed by the formula (1) of phenolic compounds described above include alkylcatechols such as catechol, resorcinol, 1,4-hydroquinone, 2-methylcatechol, 3-methylcatechol, 4-methylcatechol, 2-ethylcatechol, 3-ethylcatechol, 4-ethylcatechol, 2-propylcatechol, 3-propylcatechol, 4-propylcatechol, 2-n-butylcatechol, 3-n-butylcatechol, 4-n-butylcatechol, 2-tert-butylcatechol, 3-tert-butylcatechol, 4-tert-butylcatechol, and 3,5-di-tert-butylcatechol; alkylresorcinols such as 2-methylresorcinol, 4-methylresorcinol, 2-ethylresorcinol, 2-ethylresorcinol, 2-propyleneresorcinol, 4-propyleneresorcinol, 2-n-butylresorcinol, 4-n-butylresorcinol, 2-tert-butylresorcinol, and 4-tert-butylresorcinol; alkyl hydroquinones such as methyl hydroquinone, ethyl hydroquinone, propyl hydroquinone, tert-butyl hydroquinone, and 2,5-di-tert-butyl hydroquinone; pyrogallol, and phloroglucin.

Further, preferable examples of the compounds having a phenolic hydroxide group include the compounds of aromatic rings, in which each ring having at least one phenolic hydroxide group and the rings are connected by a divalent connecting group together with.

Examples of the divalent connecting group include connecting groups such as those having 1 to 20 carbon atoms, oxygen atom, nitrogen atom, sulfur atom, SO, SO₂ and the like. Sulfur atom, oxygen atom, SO, and SO₂ may bond directly to the compounds having a phenolic hydroxide group. The carbon atom and oxygen atom may be attached with at least a substituent group, examples of which are those of Z in phenolic compounds of formula (1). Further, the aromatic ring may be attached with at least a substituent group, examples of which are those of Z in phenolic compounds of formula (1).

Additional examples of the compounds having a phenolic hydroxide group include bisphenol A, bisphenol S, bisphenol M, bisphenol compounds employed as a color developer in thermosensitive paper, bisphenol compounds described in JP-A No. 2003-305945, hindered phenol compounds utilized as an antioxidant, and the like. Further, mono-phenol compounds having a substituent group such as 4-methoxyphenol, 4-methoxy-2-hydroxy benzophenone, β-naphthol, 2,6-di-t-butyl-4-cresol, methyl salicylate, dimethylamino phenol, and the like may be exemplified. Bisphenol compounds having a phenolic hydroxide group are commercially available from Honshu Chemical Industries Co.

The compounds having an imino group set forth above may be properly selected depending on the application; preferably the compound has a molecular mass of no less than 50, and more preferably of no less than 70.

Preferably, the compounds having an imino group have a cyclic structure substituted by an imino group. Preferably, the cyclic structure is a condensed aromatic ring or hetero ring, in particular the condensed aromatic ring. The cyclic structure may contain oxygen, nitrogen, or sulfur atom.

Examples of the compounds having an imino group set forth above include phenothiazine, dihydrophenazine, hydroquinoline, or those substituted by Z in phenolic compounds of formula (1).

Preferable examples of the compound with an imino group having a cyclic structure substituted by an imino group are hindered amine derivatives that contain hindered amine. Examples of the hindered amine are the hindered amines described in JP-A No. 2003-246138.

The compounds having a nitro group or nitroso group set forth above may be properly selected depending on the application, preferably the compounds have a molecular mass of no less than 50, and more preferably of no less than 70.

Examples of the compounds having a nitro group or nitroso group include nitrobenzene, chelate compounds of nitroso compounds and aluminum, and the like.

The compounds having an aromatic ring set forth above may be properly selected depending on the application; preferably the aromatic ring is substituted by a substituent having an isolated electron pair such as that containing oxygen, nitrogen, sulfur, metals, or the like.

Specific examples of the compounds having an aromatic ring are the compounds having at least a phenolic hydroxide group set forth above, compounds having an imino group set forth above, compounds containing an aniline skeleton such as methylene blue, crystal violet, and the like.

The compounds having a hetero ring may be properly selected depending on the application; preferably the hetero ring contains an atom having an isolated electron pair such as oxygen, nitrogen, sulfur, or the like. Examples of the compounds having a hetero ring include pyridine, quinoline, and the like.

The compounds having a metal atom set forth above may be properly selected depending on the application; preferably, the metal atom exhibits an affinity with a radical generated from the polymerization initiator, examples thereof include Cu, Al, Ti, and the like.

Among the polymerization inhibitors exemplified above, preferable are compounds having at least two phenolic hydroxide groups, compounds having an aromatic ring substituted by an imino group, and compounds having an hetero ring substituted by an imino group; particularly preferable are compounds having a ring configuration in part of which an imino group constitutes and hindered amine compounds. More specifically, catechol, phenothiazine, phenoxazine, hindered amines, and derivatives thereof are preferable.

Polymerization inhibitors are typically included into commercially available polymerizable compounds in a small amount. In the present invention, from the viewpoint of increasing the resolution, different polymerization inhibitors are included other than the polymerization inhibitors included in the commercially available polymerizable compounds. Accordingly, the polymerization inhibitor incorporated according to the present invention is preferably other compound than the polymerization inhibitors of mono-phenol compounds such as 4-methoxyphenol usually included in the commercially available polymerizable compounds to enhance stability.

By the way, the polymerization inhibitor may be added previously into a solution of photosensitive composition before producing the pattern forming material.

The content of the polymerization inhibitor is preferably 0.005 to 0.5% by mass based on the polymerizable compound in the photosensitive layer, more preferably is 0.01 to 0.4% by mass, and still more preferably is 0.02 to 0.2% by mass. When the content is less than 0.005% by mass, the resolution of the pattern forming material may be deteriorated, when the content is more than 0.5% by mass, the sensitivity to the active energy rays of the pattern forming material may be insufficient.

The content of the polymerization inhibitor described above means the content other than the polymerization inhibitors included in the commercial polymerizable compounds to enhance stability such as 4-methoxyphenol.

### —Binder—

Preferably, the binder is swellable in alkaline liquids, more preferably, the binder is soluble in alkaline liquids. The binders that are swellable or soluble in alkaline liquids are those having an acidic group, for example.

The acidic group may be properly selected depending on the application without particular limitations; examples thereof include carboxyl group, sulfonic acid group, phosphoric acid group, and the like. Among these groups, carboxyl group is preferable.

Examples of the binders that contain a carboxyl group include vinyl copolymers, polyurethane resins, polyamide acid resins, and modified epoxy resins that contain a carboxyl group. Among these, vinyl copolymers containing a carboxyl group are preferable from the viewpoints of solubility in coating solvents, solubility in alkaline developers, ability to be synthesized, easiness to adjust film properties, and the like. Further, copolymers of styrene and styrene derivatives are preferable from the viewpoint of developing property.

The vinyl copolymers containing a carboxyl group may be synthesized by copolymerizing at least (i) a vinyl polymer containing a carboxyl group, and (ii) a monomer capable of copolymerizing with the vinyl monomer.

Examples of vinyl polymers containing a carboxyl group include (meth)acrylic acid, vinyl benzoic acid, maleic acid, maleic acid monoalkylester, fumaric acid, itaconic acid, crotonic acid, cinnamic acid, acrylic acid dimer, adducts of a monomer containing a hydroxy group such as 2-hydroxyethyl(meth)acrylate and a cyclic anhydride such as maleic acid anhydride, phthalic acid anhydride, and cyclohexane dicarbonic acid anhydride, and carboxy-polycaprolactone mono(meth)acrylate. Among these, (meth)acrylic acid is preferable in particular from the view points of copolymerizing ability, cost, solubility, and the like.

In addition, as for the precursor of carboxyl group, monomers containing anhydride such as maleic acid anhydride, itaconic acid anhydride, and citraconic acid anhydride may be employed.

The monomer capable of copolymerizing may be properly selected depending on the application; examples thereof include (meth)acrylate esters, crotonate esters, vinyl esters, maleic acid diesters, fumaric acid diesters, itaconic acid diesters, (meth)acrylic amides, vinyl ethers, vinyl alcohol esters, styrenes such as styrene and derivatives thereof; methacrylonitrile; heterocyclic compounds with a substituted vinyl group such as vinylpyridine, vinylpyrrolidone, and vinylcarbazole; N-vinyl formamide, N-vinyl acetamide, N-vinyl imidazole, vinyl caprolactone, 2-acrylamide-2-methylpropane sulfonic acid, phosphoric acid mono(2-acryloyloxyethylester), phosphoric acid mono(1-methyl-2-acryloyloxyethylester), and vinyl monomers containing a functional group such as a urethane group, urea group, sulfonic amide group, phenol group, and imide group. Among them, styrenes are preferable.

Examples of (meth)acrylate esters include methyl(meth)acrylate, ethyl(meth)acrylate, n-propyl(meth)acrylate, isopropyl(meth)acrylate, n-butyl(meth)acrylate, isobutyl(meth)acrylate, t-butyl(meth)acrylate, n-hexyl(meth)acrylate, cyclohexyl(meth)acrylate, t-butylcyclohexyl(meth)acrylate, 2-ethylhexyl(meth)acrylate, t-octyl(meth)acrylate, dodecyl(meth)acrylate, octadecyl(meth)acrylate, acetoxyethyl(meth)acrylate, phenyl(meth)acrylate, 2-hydroxyethyl(meth)acrylate, 2-methoxyethyl(meth)acrylate, 2-ethoxyethyl(meth)acrylate (meth)acrylate, 2-(2-methoxyethoxy)ethyl (meth)acrylate, 3-phenoxy-2-hydroxypropyl(meth)acrylate, benzil(meth)acrylate, diethyleneglycol monomethylether (meth)acrylate, diethyleneglycol monoethylether (meth)acrylate, diethyleneglycol monophenylether (meth)acrylate, triethyleneglycol monomethylether (meth)acrylate, triethyleneglycol monoethylether (meth)acrylate, polyethyleneglycol monomethylether (meth)acrylate, polyethyleneglycol monoethylether (meth)acrylate, β-phenoxyethoxyethyl (meth)acrylate, nonylphenoxy polyethyleneglycol (meth)acrylate, dicyclopentanyl (meth)acrylate, dicyclopentenyl oxyethyl (meth)acrylate, trifluoroethyl (meth)acrylate, octafluoropentyl (meth)acrylate, perfluorooctylethyl (meth)acrylate, tribromophenyl (meth)acrylate, and tribromophenyloxyethyl (meth)acrylate.

Examples of crotonate esters include butyl crotonate, and hexyl crotonate.

Examples of vinyl esters include vinyl acetate, vinyl propionate, vinyl butyrate, vinylmethoxy acetate, and vinyl benzoate.

Examples of maleic acid diesters include dimethyl maleate, diethyl maleate, and dibutyl maleate.

Examples of fumaric acid diesters include dimethyl fumarate, diethyl fumarate, and dibutyl fumarate.

Examples of itaconic acid diesters include dimethyl itaconate, diethyl itaconate, and dibutyl itaconate.

Examples of (meth)acrylic amides include (meth)acrylamide, N-methyl (meth)acrylamide, N-ethyl (meth)acrylamide, N-propyl (meth)acrylamide, N-isopropyl (meth)acrylamide, N-n-butyl (meth)acrylamide, N-t-butyl (meth)acrylamide, N-cyclohexyl (meth)acrylamide, N-(2-methoxyethyl) (meth)acrylamide, N,N-dimethyl (meth)acrylamide, N,N-diethyl (meth)acrylamide, N-phenyl (meth)acrylamide, N-benzil (meth)acrylamide, (meth)acryloyl morpholine, and diacetone acrylamide.

Examples of the styrenes include styrene, methylstyrene, dimethylstyrene, trimethylstyrene, ethylstyrene, isopropylstyrene, butylstyrene, hydroxystyrene, methoxystyrene, butoxystyrene, acetoxystyrene, chlorostyrene, dichlorostyrene, bromostyrene, chloromethylstyrene; hydroxystyrene with a protective group such as t-Boc capable of being de-protected by an acid substance; vinylmethyl benzoate, and α-methylstyrene.

Examples of vinyl ethers include methyl vinylether, butyl vinylether, hexyl vinylether, and methoxyethyl vinylether.

The process to synthesize the vinyl monomer containing a functional group is an addition reaction of an isocyanate group and a hydroxy group or amino group for example; specifically, an addition reaction between a monomer containing an isocyanate group and a compound containing one hydroxyl group or a compound containing one primary or secondary amino group, and an addition reaction between a monomer containing a hydroxy group or a monomer containing a primary or secondary amino group and a mono isocyanate are exemplified.

Examples of the monomers containing an isocyanate group include the compounds expressed by the following formulas (2) to (4).

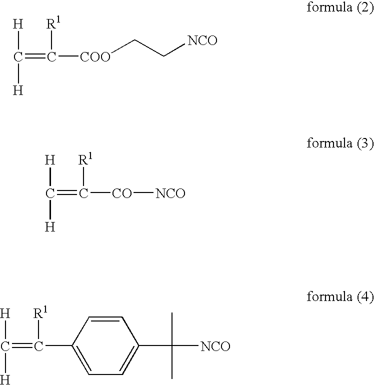

In the above formulas (2) to (4), R¹ represents a hydrogen atom or a methyl group.

Examples of mono isocyanates set forth above include cyclohexyl isocyanate, n-butyl isocyanate, toluic isocyanate, benzil isocyanate, and phenyl isocyanate.

Examples of the monomers containing a hydroxyl group include the compounds expressed by the following formulas (5) to (13).

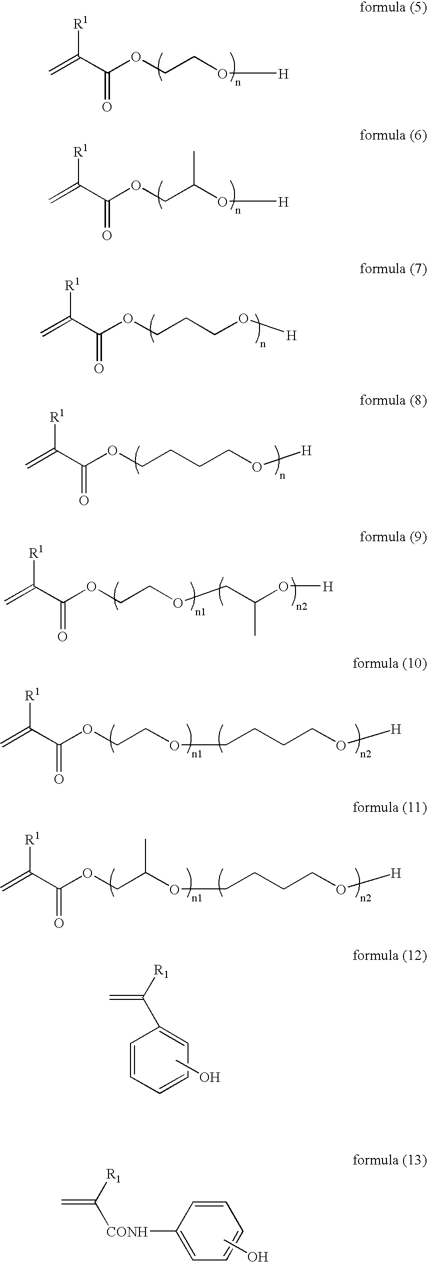

In the above formulas (5) to (13), R₁ represents a hydrogen atom or a methyl group, and “n” represents an integer of one or more.

Examples of the compounds containing one hydroxyl group include alcohols such as methanol, ethanol, n-propanol, i-propanol, n-butanol, sec-butanol, t-butanol, n-hexanol, 2-ethylhexanol, n-decanol, n-dodecanol, n-octadecanol, cyclopentanol, cyclohexanol, benzil alcohol, and phenylethyl alcohol; phenols such as phenol, cresol, and naphthol; examples of the compounds containing additionally a substituted group include fluoroethanol, trifluoroethanol, methoxyethanol, phenoxyethanol, chlorophenol, dichlorophenol, methoxyphenol, and acetoxyphenol.

Examples of monomers containing a primary or secondary amino group set forth above include vinylbenzil amine.

Examples of compounds containing a primary or secondary amino group include alkylamines such as methylamine, ethylamine, n-propylamine, i-propylamine, n-butylamine, sec-butylamine, t-butylamine, hexylamine, 2-ethylhexylamine, decylamine, dodecylamine, octadecylamine, dimethylamine, diethylamine, dibutylamine, and dioctylamine; cyclic alkylamines such as cyclopentylamine and cyclohexylamine; aralkylamines such as benzilamine and phenethylamine; arylamines such as aniline, toluicamine, xylylamine, and naphthylamine; combination thereof such as N-methyl-N-benzilamine; and amines containing a substituted group such as trifluoroethylamine, hexafluoro isopropylamine, methoxyaniline, and methoxy propylamine.

Examples of the copolymerizable monomers other than set forth above include methyl (meth)acrylate, ethyl (meth)acrylate, butyl (meth)acrylate, benzil (meth)acrylate, 2-ethylhexyl (meth)acrylate, styrene, chlorostyrene, bromostyrene, and hydroxystyrene.

The above noted copolymerizable monomers may be used alone or in combination.

The vinyl copolymers set forth above may be prepared by copolymerizing the appropriate monomers in accordance with conventional processes; for example, such a solution polymerization process is available as dissolving the monomers into an appropriate solvent, adding a radical polymerization initiator, thereby causing a polymerization in the solvent; alternatively such a so-called emulsion polymerization process is available as polymerizing the monomers under the condition that the monomers are dispersed in an aqueous solvent.

The solvent utilized in the solution polymerization process may be properly selected depending on the monomers, solubility of the resultant copolymer and the like; examples of the solvents include methanol, ethanol, propanol, isopropanol, 1-methoxy-2-propanol, acetone, methyl ethyl ketone, methylisobutylketone, methoxypropyl acetate, ethyl lactate, ethyl acetate, acetonitrile, tetrahydrofuran, dimethylformamide, chloroform, and toluene. These solvents may be used alone or in combination.

The radical polymerization initiator set forth above may be properly selected without particular limitations; examples thereof include azo compounds such as 2,2′-azobis(isobutyronitrile) (AIBN) and 2,2′-azobis-(2,4′-dimethylvaleronitrile); peroxides such as benzoyl peroxide; persulfates such as potassium persulfate and ammonium persulfate.

The content of the polymerizable compound having a carboxyl group in the vinyl copolymers set forth above may be properly selected without particular limitations; preferably, the content is 5 to 50 mole %, more preferably is 10 to 40 mole %, and still more preferably is 15 to 35 mole %.

When the content is less than 5 mole %, the developing ability in alkaline solution may be insufficient, and when the content is more than 50 mole %, the durability of the hardening portion or imaging portion is insufficient against the developing liquid.

The molecular mass of the binder having a carboxyl group set forth above may be properly selected without particular limitations; preferably the mass-averaged molecular mass is 2000 to 300000, more preferably is 4000 to 150000.

When the mass-averaged molecular mass is less than 2000, the film strength is likely to be insufficient, and also the production process tends to be unstable, and when the mass-averaged molecular mass is more than 300000, the developing ability tends to decrease.

The binder having a carboxyl group set forth above may be used alone or in combination. As for the combination of two or more of the binders, such combination may be exemplified as two or more of binders having different copolymer components, two or more of binders having different mass-averaged molecular mass, and two or more of binders having different dispersion levels.

In the binder having a carboxyl group set forth above, a part or all of the carboxyl groups may be neutralized by a basic substance. Further, the binder may be combined with a resin of different type selected from polyester resins, polyamide resins, polyurethane resins, epoxy resins, polyvinyl alcohols, gelatin, and the like.

In addition, the binder having a carboxyl group set forth above may be a resin soluble in an alkaline liquid as described in Japanese Patent No. 2873889.

The content of the binder in the photosensitive layer set forth above may be properly selected without particular limitations; preferably the content is 10 to 90% by mass, more preferably is 20 to 80% by mass, and still more preferably is 40 to 80% by mass.

When the content is less than 10% by mass, the developing ability in alkaline solutions or the adhesive property with substrates for forming printed wiring boards such as a cupper laminated board tends to decrease, and when the content is more than 90% by mass, the stability of developing period or the strength of the hardening film or the tenting film may be insufficient. The content of the binder may be considered as the sum of the binder content and the additional polymer binder content combined depending on requirements.

The acid value of the binder may be properly selected depending on the application; preferably the acid value is 70 to 250 mgKOH/g, more preferably is 90 to 200 mgKOH/g, still more preferably is 100 to 180 mgKOH/g.

When the acid value is less than 70 mgKOH/g, the developing ability of the pattern forming material may be insufficient, the resolving property may be poor, or the permanent pattern such as wiring patterns cannot be formed precisely, and when the acid value is more than 250 mgKOH/g, the durability of pattern against the developer and/or adhesive property of pattern tends to degrade, thus the permanent pattern such as wiring patterns cannot be formed precisely.

### —Polymerizable Compound—

The polymerizable compound may be properly selected without particular limitations; preferably, the polymerizable compound is the monomer or oligomer that contains a urethane group and/or an aryl group; preferably, the polymerizable compound contains two or more types of polymerizable groups.

Examples of the polymerizable group include ethylenically unsaturated bonds such as (meth)acryloyl groups, (meth)acrylamide groups, styryl groups, vinyl groups (e.g. of vinyl esters, vinyl ethers), and allyl groups (e.g. of allyl ethers, allyl esters); and polymerizable cyclic ether groups such as epoxy groups and oxetane group. Among these, the ethylenically unsaturated bond is preferable.

### —Monomer Containing Urethane Group—

The monomer containing a urethane group set forth above may be properly selected without particular limitations; examples thereof include those described in Japanese Patent Application Publication (JP-B) No. 48-41708, Japanese Patent Application Laid-Open (JP-A) No. 51-37193, JP-B Nos. 5-50737, 7-7208, and JP-A Nos. 2001-154346, 2001-356476; specifically, the adducts may be exemplified between polyisocyanate compounds having two or more isocyanate groups in the molecule and vinyl monomers having a hydroxyl group in the molecule.

Examples of the polyisocyanate compounds having two or more isocyanate groups in the molecule set forth above include diisocyanates such as hexamethylene diisocyanate, trimethyl hexamethylene diisocyanate, isophorone diisocyanate, xylene diisocyanate, toluene diisocyanate, phenylene diisocyanate, norbornene diisocyanate, diphenyl diisocyanate, diphenylmethane diisocyanate, and 3,3′-dimethyl-4,4′-diphenyl diisocyanate; polyaddition products of these diisocyanates and two-functional alcohols wherein each of both ends of the polyaddition product is an isocyanate group; trimers such as buret of the diisocyanates or isocyanurates; adducts obtained from the diisocyanate of diisocyanates and polyfunctional alcohols such as trimethylolpropane, pentaerythritol, and glycerin or polyfunctional alcohols of adducts with ethylene oxide.

Examples of vinyl monomers having a hydroxyl group in the molecule set forth above include 2-hydroxyethyl (meth)acrylate, 2-hydroxypropyl (meth)acrylate, 4-hydroxybutyl (meth)acrylate, diethyleneglycol mono(meth)acrylate, triethyleneglycol mono(meth)acrylate, tetraethyleneglycol mono(meth)acrylate, octaethyleneglycol mono(meth)acrylate, polyethyleneglycol mono(meth)acrylate, dipropyleneglycol mono(meth)acrylate, tripropyleneglycol mono(meth)acrylate, tetrapropyleneglycol mono(meth)acrylate, octapropyleneglycol mono(meth)acrylate, polypropyleneglycol mono(meth)acrylate, dibutyleneglycol mono(meth)acrylate, tributyleneglycol mono(meth)acrylate, tetrabutyleneglycol mono(meth)acrylate, octabutyleneglycol mono(meth)acrylate, polybutyleneglycol mono(meth)acrylate, trimethylolpropane (meth)acrylate, and pentaerythritol (meth)acrylate. Further, such a vinyl monomer may be exemplified that has a (meth)acrylate component at one end of diol molecule having different alkylene oxides such as of random or block copolymer of ethylene oxide and propylene oxide for example.

Examples of the monomers containing a urethane group set forth above include the compounds having an isocyanurate ring such as tri(meth)acryloyloxyethyl isocyanurate, di(meth)acrylated isocyanurate, and tri(meth)acrylate of ethylene oxide modified isocyanuric acid. Among these, the compounds expressed by formula (14) or formula (15) are preferable; at least the compounds expressed by formula (15) are preferably included in particular from the view point of tenting property. These compounds may be used alone or in combination.

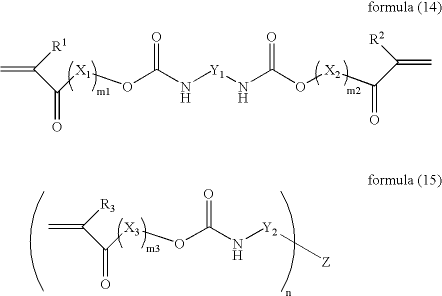

In the formulas (14) and (15), R¹ to R³ represent a hydrogen atom or a methyl group respectively; X₁ to X₃ represent alkylene oxide groups respectively, which may be identical or different each other.

Examples of the alkylene oxide group include ethylene oxide group, propylene oxide group, butylene oxide group, pentylene oxide group, hexylene oxide group, and combined groups thereof in random or block. Among these, ethylene oxide group, propylene oxide group, butylene oxide group, and combined groups thereof are preferable; and ethylene oxide group and propylene oxide group are more preferable.

In the formulas (14) and (15), m1 to m3 represent integers of 1 to 60 respectively, preferably is 2 to 30, and more preferably is 4 to 15.

In the formulas (14) and (15), each of Y₁ and Y₂ represents a divalent organic group having 2 to 30 carbon atoms such as alkylene group, arylene group, alkenylene group, alkynylene group, carbonyl group (—CO—), oxygen atom, sulfur atom, imino group (—NH—), substituted imino group wherein the hydrogen atom on the imino group is substituted by a monovalent hydrocarbon group, sulfonyl group (—SO₂—), and combination thereof; among these, an alkylene group, arylene group, and combination thereof are preferable.

The alkylene group set forth above may be of branched or cyclic structure; examples of the alkylene group include methylene group, ethylene group, propylene group, isopropylene group, butylene group, isobutylene group, pentylene group, neopentylene group, hexylene group, trimethylhexylene group, cyclohexylene group, heptylene group, octylene group, 2-ethylhexylene group, nonylene group, decylene group, dodecylene group, octadecylene group, and the groups expressed by the following formulas.

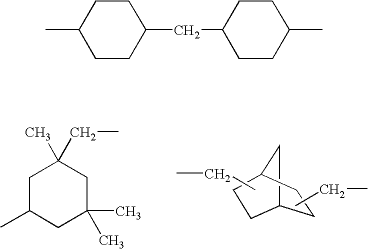

The arylene group may be substituted by a hydrocarbon group; examples of the arylene group include phenylene group, thrylene group, diphenylene group, naphthylele group, and the following group.

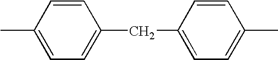

The group of combination thereof set forth above is exemplified by xylylene group.

The alkylene group, arylene group, and combination thereof set forth above may contain a substituted group additionally; examples of the substituted group include halogen atoms such as fluorine atom, chlorine atom, bromine atom, and iodine atom; aryl groups; alkoxy groups such as methoxy group, ethoxy group, and 2-ethoxyethoxy group; aryloxy groups such as phenoxy group; acyl groups such as acetyl group and propionyl group; acyloxy groups such as acetoxy group and butylyloxy group; alkoxycarbonyl groups such as methoxycarbonyl group and ethoxycarbonyl group; and aryloxycarbonyl groups such as phenoxycarbonyl group.

In the formulas (14) and (15), “n” represents an integer of 3 to 6, preferably, “n” is 3, 4, or 6 from the viewpoint of the available feedstock for synthesizing the polymerizable monomer.

In the formulas (14) and (15), “n” represents an integer of 3 to 6; Z represents a connecting group of “n” valences (n=3 to 6), examples of Z include the following groups.

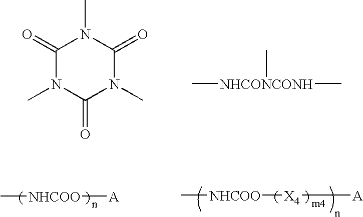

In the above formulas, X₄ represents an alkylene oxide; m4 represents an integer of 1 to 20; “n” represents an integer of 3 to 6; and A represents an organic group having “n” valences (n=3 to 6).

Example of A of the organic group set forth above include n-valence aliphatic groups, n-valence aromatic groups, and combinations of these groups and alkylene groups, arylene groups, alkenylene groups, alkynylene groups, carbonyl group, oxygen atom, sulfur atom, imino group, substituted imino groups wherein a hydrogen atom on the imino group is substituted by a monovalent hydrocarbon group, and sulfonyl group (—SO₂—); more preferably are n-valence aliphatic groups, n-valence aromatic groups, and combinations of these groups and alkylene groups, arylene groups, or an oxygen atom; particularly preferable are n-valence aliphatic groups, and combinations of n-valence aliphatic groups and alkylene groups or an oxygen atom.

The number of carbon atoms in the A of the organic group set forth above is preferably 1 to 100, more preferably is 1 to 50, and most preferably is 3 to 30.

The n-valence aliphatic group set forth above may be of branched or cyclic structure. The number of carbon atoms in the aliphatic group is preferably 1 to 30, more preferably is 1 to 20, and most preferably is 3 to 10.

The number of carbon atoms in the aromatic group set forth above is preferably 6 to 100, more preferably is 6 to 50, and most preferably is 6 to 30. The n-valence aliphatic group and the n-valence aromatic group may contain a substituted group additionally; examples of the substituted group include hydroxyl group, halogen atoms such as fluorine atom, chlorine atom, bromine atom, and iodine atom; aryl groups; alkoxy groups such as methoxy group, ethoxy group, and 2-ethoxyethoxy group; aryloxy groups such as phenoxy group; acyl groups such as is acetyl group and propionyl group; acyloxy groups such as acetoxy group and butylyloxy group; alkoxycarbonyl groups such as methoxycarbonyl group and ethoxycarbonyl group; and aryloxycarbonyl groups such as phenoxycarbonyl group.

The alkylene group set forth above may be of branched or cyclic structure.

The number of carbon atoms in the alkylene group is preferably 1 to 18, and more preferably is 1 to 10.

The arylene group set forth above may be further substituted by a hydrocarbon group. The number of carbon atoms in the arylene group is preferably 6 to 18, and more preferably is 6 to 10.

The number of carbon atoms in the hydrocarbon group of the substituted imino group set forth above is preferably 1 to 18, and more preferably is 1 to 10.

Preferable examples of A of the organic group set forth above are as follows.

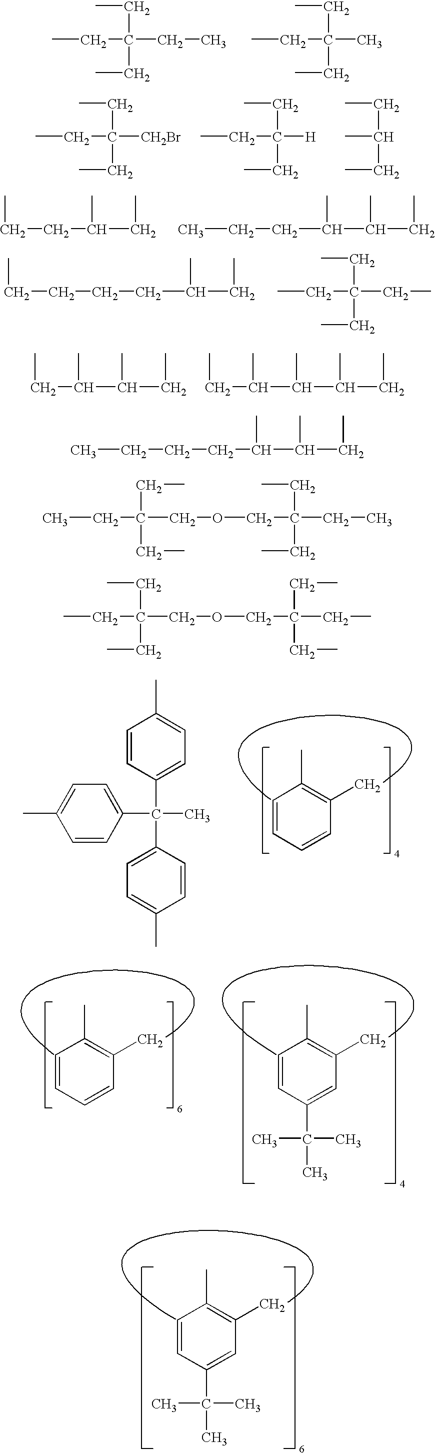

The compounds expressed by the formulas (14) and (15) are exemplified specifically by the following formulas (16) to (36).

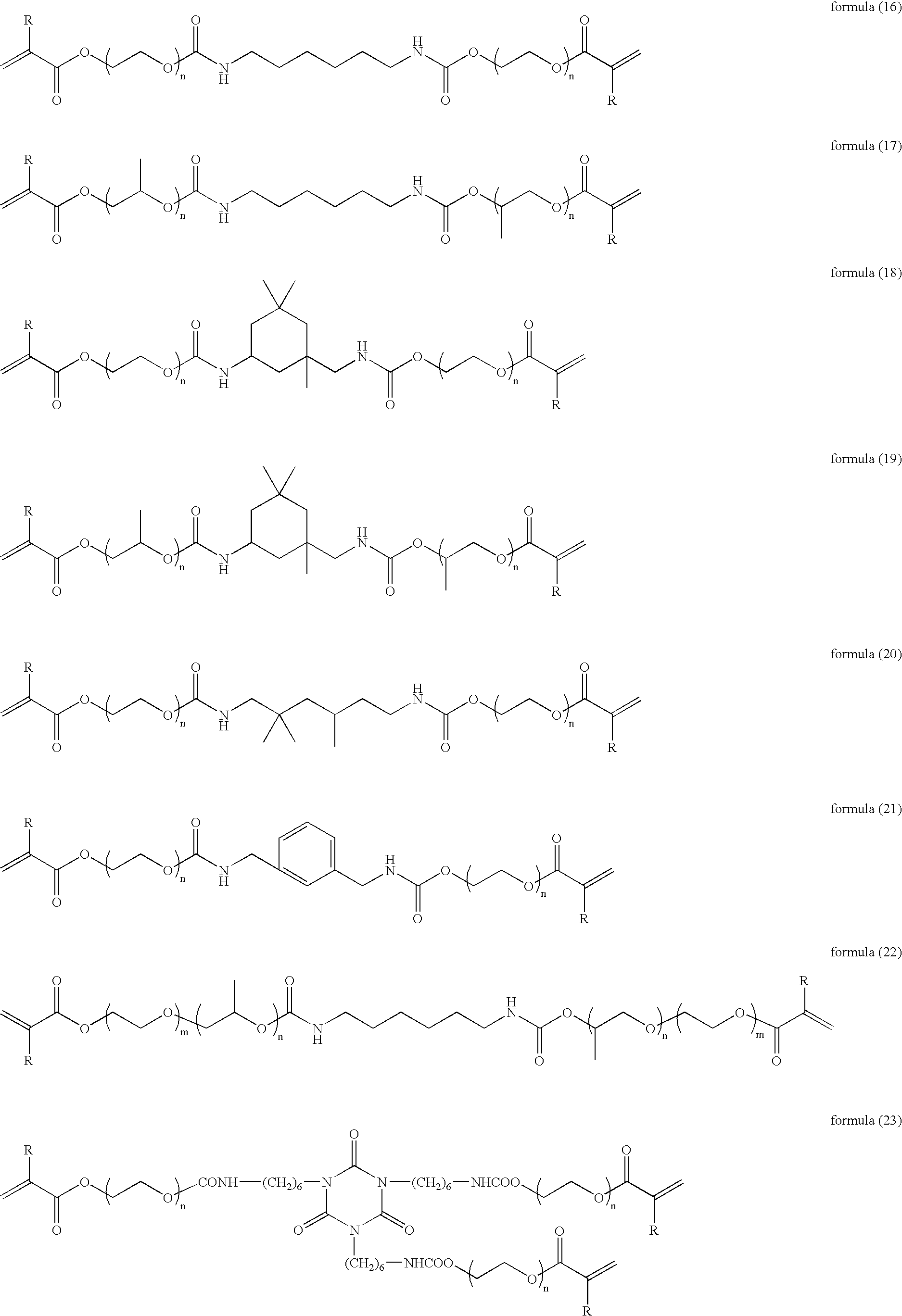

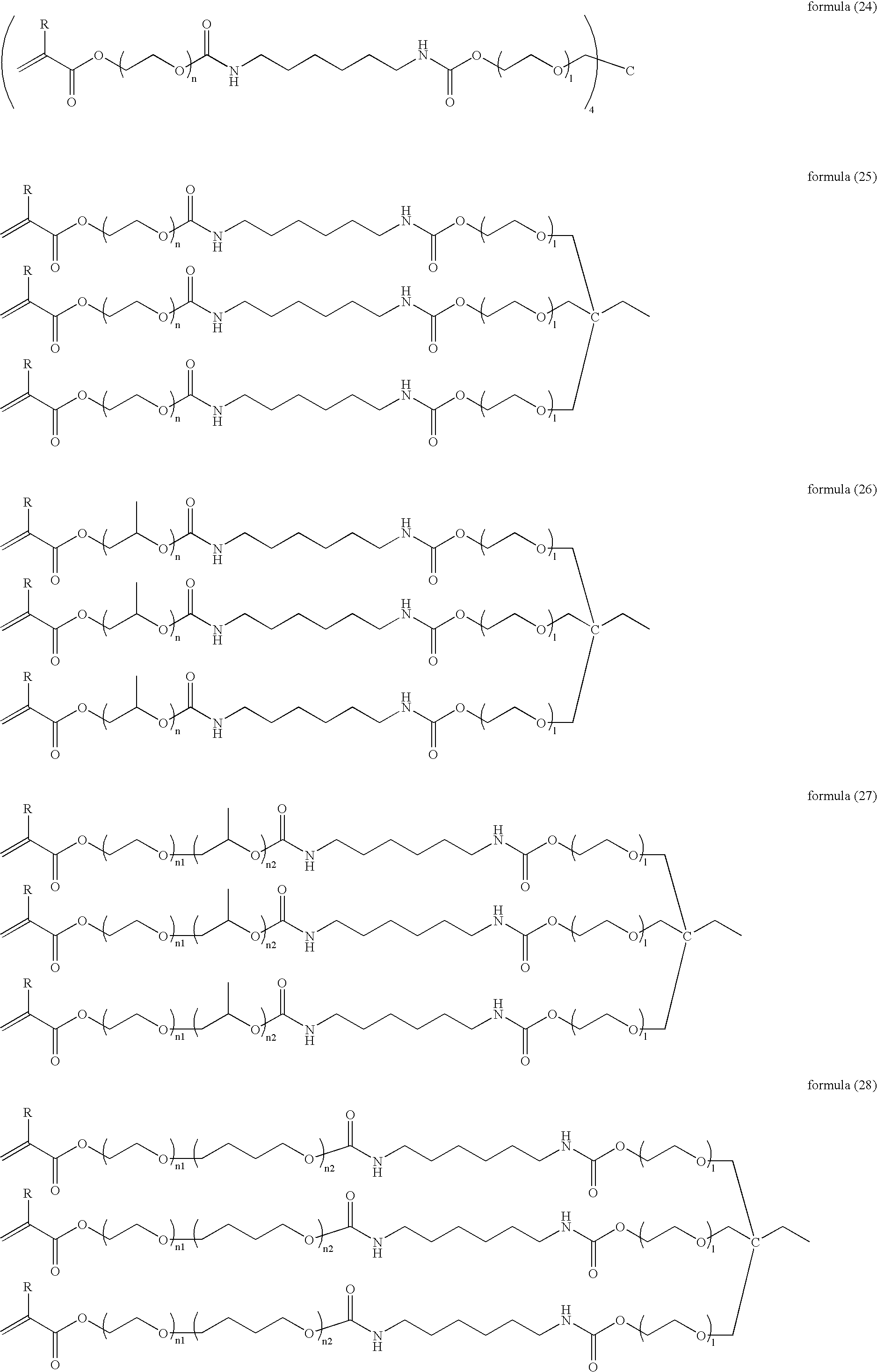

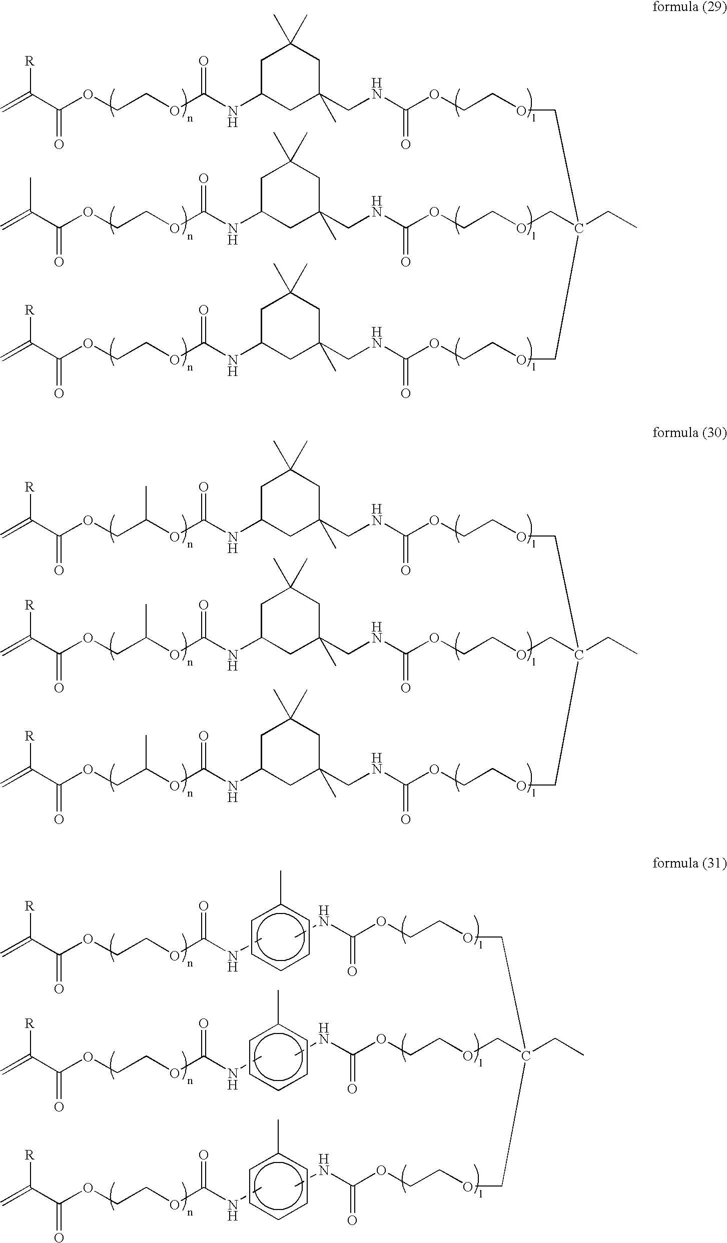

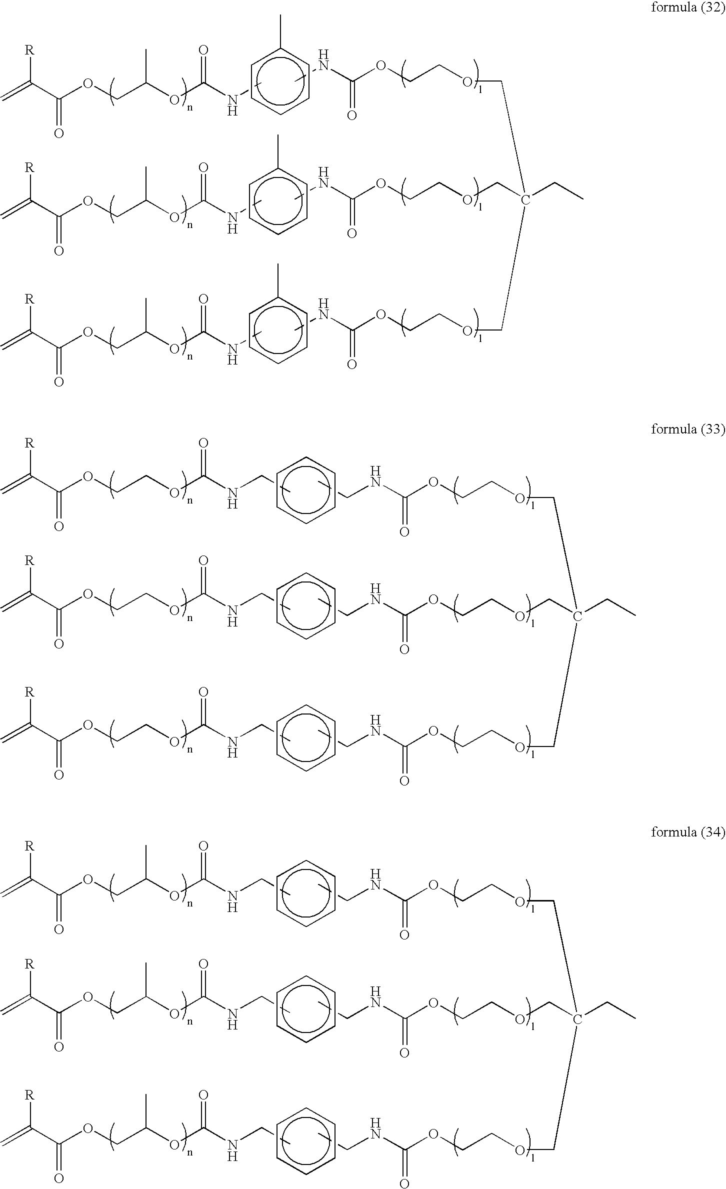

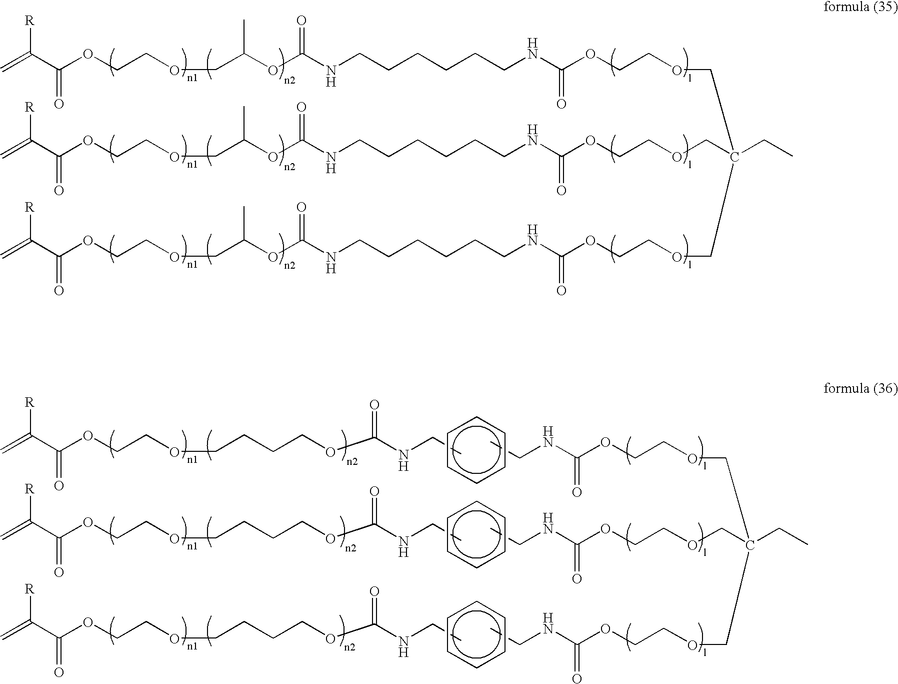

In the above formulas (16) to (36), each of “n”, n1, n2, and “m” represents an integer of 1 to 60; “1” represents an integer of 1 to 20; and R represents a hydrogen atom or a methyl group.

### —Monomer Containing Aryl Group—

The monomers containing an aryl group set forth above may be properly selected as long as the monomer contains an aryl group; examples of the monomers containing an aryl group include esters and amides between at least one of polyvalent alcohol compounds, polyvalent amine compounds, and polyvalent amino alcohol compounds containing an aryl group and at least one of unsaturated carboxylic acids.

Examples of the polyvalent alcohol compounds, polyvalent amine compounds, and polyvalent amino alcohol compounds containing an aryl group include polystyrene oxide, xylylenediol, di(β-hydroxyethoxy)benzene, 1,5-dihydroxy-1,2,3,4-tetrahydronaphthalene, 2,2-diphenyl-1,3-propanediol, hydroxybenzyl alcohol, hydroxyethyl resorcinol, 1-phenyl-1,2-ethanediol, 2,3,5,6-tetramethyl-p-xylene-α,α′-diol, 1,1,4,4-tetraphenyl-1,4-butanediol, 1,1,4,4-tetraphenyl-2-butane-1,4-diol, 1,1′-bi-2-naphthol, dihydroxynaphthalene, 1,1′-methylene-di-2-naphthol, 1,2,4-benzenetriol, biphenol, 2,2′-bis(4-hydroxyphenyl)butane, 1,1-bis(4-hydroxyphenyl)cyclohexane, bis(hydroxyphenyl)methane, catechol, 4-chlororesorcinol, hydroquinone, hydroxybenzyl alcohol, methylhydroquinone, methylene-2,4,6-trihydroxybenzoate, fluoroglucinol, pyrogallol, resorcinol, α-(1-aminoethyl)-p-hydroxybenzyl alcohol, and 3-amino-4-hydroxyphenyl sulfone.

In addition, xylylene-bis-(meth)acrylamide; adducts of novolac epoxy resins or glycidyl compounds such as bisphenol A diglycidylether and α,β-unsaturated carboxylic acids; ester compounds from acids such as phthalic acid and trimellitic acids and vinyl monomers containing a hydroxide group; diallyl phthalate, triallyl trimellitate, diallyl benzene sulfonate, cationic polymerizable divinylethers as a polymerizable monomer such as bisphenol A divinylether; epoxy compounds such as novolac epoxy resins and bisphenol A diglycidylethers; vinyl esters such as divinyl phthalate, divinyl terephthalate, and divinylbenzene-1,3-disulfonate; and styrene compounds such as divinyl benzene, p-allyl styrene, and p-isopropene styrene. Among these, the compounds expressed by the following formula (37) are preferable.

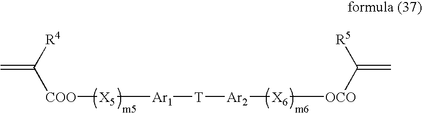

In the above formula (37), R⁴ and R⁵ represent respectively a hydrogen atom or an alkyl group.

In the above formula (37), X₅ and X₆ represent an alkylene oxide group respectively, the alkylene oxide group may be one species or two or more species. Examples of the alkylene oxide group include ethylene oxide group, propylene oxide group, butylene oxide group, pentylene oxide group, hexylene oxide group, and combined groups in random or block thereof. Among these, ethylene oxide group, propylene oxide group, butylene oxide group, and combined groups thereof are preferable; and ethylene oxide group and propylene oxide group are more preferable.

In the formula (37), m5 and m6 represent respectively an integer of 1 to 60, preferably is 2 to 30, and more preferably is 4 to 15.

In the formula (37), T represents a divalent connecting group such as methylene group, ethylene group, MeCMe, CF₃CCF₃, CO, and SO₂.

In the formula (37), Ar₁ and Ar₂ represent respectively an aryl group that may contain a substituted group; examples of Ar₁ and Ar₂ include phenylene and naphthyene; and examples of the substituted group include alkyl groups, aryl groups, aralkyl groups, halogen groups, alkoxy groups, and combinations thereof.

Specific examples of the monomer containing an aryl group set forth above include 2,2-bis[4-(3-(meth)acryloxy-2-hydroxypropoxy)phenyl]propane, 2,2-bis[4-((meth)acryloxyethoxy)phenyl]propane; 2,2-bis[4-((meth)acryloyloxypolyethoxy)phenyl]propane in which the number of ethoxy groups substituted for one phenolic OH group is 2 to 20 such as 2,2-bis[4-((meth)acryloyloxydiethoxy)phenyl]propane, 2,2-bis[4-((meth)acryloyloxytetraethoxy)phenyl]propane, 2,2-bis[4-((meth)acryloyloxypentaethoxy)phenyl]propane, 2,2-bis[4-((meth)acryloyloxydecaethoxy)phenyl]propane, and 2,2-bis[4-((meth)acryloyloxypentadecaethoxy)phenyl]propane; 2,2-bis[4-((meth)acryloxypropoxy)phenyl]propane, 2,2-bis[4-((meth)acryloyloxypolypropoxy)phenyl]propane in which the number of ethoxy groups substituted for one phenolic OH group is 2 to 20 such as 2,2-bis[4-((meth)acryloyloxydipropoxy)phenyl]propane, 2,2-bis[4-((meth)acryloyloxytetrapropoxy)phenyl]propane, 2,2-bis[4-((meth)acryloyloxypentapropoxy)phenyl]propane, 2,2-bis[4-((meth)acryloyloxydecapropoxy)phenyl]propane, 2,2-bis[4-((meth)acryloyloxypentadecapropoxy)phenyl]propane; compounds having a polyethylene oxide skeleton as well as a polypropylene skeleton in one molecule as the ether site of these compounds such as described in International Publication No. WO 01/98832 and commercial products of BPE-200, BPE-500, and BPE-1000 (by Shin-nakamura Chemical Co.); and polymerizable compounds having a polyethylene oxide skeleton as well as a polypropylene skeleton. In these compounds, the site resultant from bisphenol A may be changed into the site resultant from bisphenol F, bisphenol S, or the like.

Examples of the polymerizable compounds having a polyethylene oxide skeleton as well as a polypropylene skeleton include the adducts of bisphenols and ethylene oxides or propylene oxides, and the compounds having a hydroxyl group at the end wherein the compound is formed as a polyaddition product and the compound has an isocyanate group and a polymerizable group such as 2-isocyanate ethyl(meth)acrylate and α,α-dimethylviny benzilisocyanate, and the like.

### —Other Polymerizable Monomer—

In the pattern forming process according to the present invention, the polymerizable monomers other than the monomers having a urethane group or an aryl group set forth above may be employed together within a range that the properties of the pattern forming material are not deteriorated.

Examples of monomers other than the monomers having a urethane group or an aromatic ring include the esters between unsaturated carboxylic acids such as acrylic acid, methacrylic acid, itaconic acid, crotonic acid, and isocrotonic acid and aliphatic polyvalent alcohols, and amides between unsaturated carboxylic acids and polyvalent amines.

Examples of the ester monomers between unsaturated carboxylic acids and aliphatic polyvalent alcohols set forth above include, as (meth)acrylate esters, ethylene glycol di(meth)acrylate, polyethylene glycol di(meth)acrylate having 2 to 18 ethylene groups such as diethylene glycol di(meth)acrylate, triethylene glycol di(meth)acrylate, tetraethylene glycol di(meth)acrylate, nonaethylene glycol di(meth)acrylate, dodecaethylene glycol di(meth)acrylate, and tetradecaethylene glycol di(meth)acrylate; propylene glycol di(meth)acrylate having 2 to 18 propylene groups such as dipropylene glycol di(meth)acrylate, tripropylene glycol di(meth)acrylate, tetrapropylene glycol di(meth)acrylate, and dodecapropylene glycol di(meth)acrylate; neopentyl glycol di(meth)acrylate, ethyleneoxide modified neopentyl glycol di(meth)acrylate, propyleneoxide modified neopentyl glycol di(meth)acrylate, trimethylolpropane tri(meth)acrylate, trimethylolpropane di(meth)acrylate, trimethylolpropane tri(meth)acryloyloxypropyl ether, trimethylolethane tri(meth)acrylate, 1,3-propanediol di(meth)acrylate, 1,3-butanediol di(meth)acrylate, 1,4-butanediol di(meth)acrylate, 1,6-hexanediol di(meth)acrylate, tetramethylene glycol di(meth)acrylate, 1,4-cyclohexanediol di(meth)acrylate, 1,2,4-butanetriol tri(meth)acrylate, 1,5-pentanediol (meth)acrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, sorbitol tri(meth)acrylate, sorbitol tetra(meth)acrylate, sorbitol penta(meth)acrylate, sorbitol hexa(meth)acrylate, dimethylol dicyclopentane di(meth)acrylate, tricyclodecan di(meth)acrylate, neopentylglycol modified trimethylolpropane di(meth)acrylate; di(meth)acrylates of alkyleneglycol chains having at least each one of ethyleneglycol chain and propyleneglycol chain such as those compounds described in International Publication No. WO 01/98832; tri(meth)acrylate of trimethylolpropane added by at least one of ethylene oxide and propylene oxide; polybutylene glycol di(meth)acrylate, glycerin di(meth)acrylate, glycerin tri(meth)acrylate, and xylenol di(meth)acrylate.

Among the (meth)acrylates set forth above, preferable in light of easy availability are ethylene glycol di(meth)acrylate, polyethylene glycol di(meth)acrylate, propylene glycol di(meth)acrylate, polypropylene glycol di(meth)acrylate, di(meth)acrylates of alkyleneglycol chains having at least each one of ethyleneglycol chain and propyleneglycol chain, trimethylolpropane tri(meth)acrylate, pentaerythritol tetra(meth)acrylate, pentaerythritol triacrylate, pentaerythritol di(meth)acrylate, dipentaerythritol penta(meth)acrylate, dipentaerythritol hexa(meth)acrylate, glycerin tri(meth)acrylate, glycerin di(meth)acrylate, 1,3-propanediol di(meth)acrylate, 1,2,4-butanetriol tri(meth)acrylate, 1,4-cyclohexanediol di(meth)acrylate, 1,5-pentanediol (meth)acrylate, neopentyl glycol di(meth)acrylate, and tri(meth)acrylate of trimethylolpropane added by ethylene oxide.

Examples of the esters between the itaconic acid and the aliphatic polyvalent alcohol compounds i.e. itaconate set forth above include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of the esters between the crotonic acid and the aliphatic polyvalent alcohol compounds, i.e. crotonate set forth above, include ethylene glycol dicrotonate, tetramethylene glycol dicrotonate, pentaerythritol dicrotonate, and sorbitol tetradicrotonate.

Examples of the esters between the isocrotonic acid and the aliphatic polyvalent alcohol compounds, i.e. isocrotonate set forth above, include ethylene glycol diisocrotonate, pentaerythritol diisocrotonate, and sorbitol tetraisocrotonate.

Examples of the esters between the maleic acid and the aliphatic polyvalent alcohol compounds, i.e. maleate set forth above, include ethylene glycol dimaleate, triethylene glycol dimaleate, pentaerythritol dimaleate, and sorbitol tetramaleate.

Examples of the amides derived from the polyvalent amine compounds and the unsaturated carboxylic acids set forth above include methylenebis(meth)acrylamide, ethylenebis(meth)acrylamide, 1,6-hexamethylenebis(meth)acrylamide, octamethylenebis(meth)acrylamide, diethylenetriamine tris(meth)acrylamide, and diethylenetriamine bis(meth)acrylamide.

As for the polymerizable monomers set forth above, the following compounds may be exemplified additionally: compounds that are obtained by adding α,β-unsaturated carboxylic acids to compounds containing a glycidyl group such as butanediol-1,4-diglycidylether, cyclohexane dimethanol glycidylether, ethyleneglycol diglycidylether, diethyleneglycol diglycidylether, dipropyleneglycol diglycidylether, hexanediol diglycidylether, trimethylolpropane triglycidylether, pentaerythritol tetraglycidylether, and glycerin triglycidylether; polyester acrylates and polyester (meth)acrylate oligomers described in JP-A No. 48-64183, and JP-B Nos. 49-43191 and 52-30490; multifunctional acrylate or methacrylate such as epoxy acrylates obtained from the reaction between methacrylic acid epoxy compounds such as butanediol-1,4-diglycidylether, cyclohexane dimethanol glycidylether, diethyleneglycol diglycidylether, dipropyleneglycol diglycidylether, hexanediol diglycidylether, trimethylolpropane triglycidylether, pentaerythritol tetraglycidylether, and glycerin triglycidylether; photocurable monomers and oligomers described in Journal of Adhesion Society of Japan, Vol. 20, No. 7, pp. 300-308 (1984); allyl esters such as diallyl phthalate, diallyl adipate, and diallyl malonate; diallyl amides such as diallyl acetamide; cationic polymerizable divinylethers such as butanediol-1,4-divinylether, cyclohexane dimethanol divinylether, ethyleneglycol divinylether, diethyleneglycol divinylether, dipropyleneglycol divinylether, hexanediol divinylether, trimethylolpropane trivinylether, pentaerythritol tetravinylether, and glycerin vinylether; epoxy compounds such as butanediol-1,4-diglycidylether, cyclohexane dimethanol glycidylether, ethyleneglycol diglycidylether, diethyleneglycol diglycidylether, dipropyleneglycol diglycidylether, hexanediol diglycidylether, trimethylolpropane triglycidylether, pentaerythritol tetraglycidylether, and glycerin triglycidylether; oxetanes such as 1,4-bis[(3-ethyl-3-oxetanylmethoxy)methyl]benzene and those described in International Publication No. WO 01/22165; compounds having two or more of ethylenically unsaturated double bonds of different types such as N-β-hydroxyethyl-β-methacrylamide ethylacrylate, N,N-bis(β-methacryloxyethyl)acrylamide, acrylmetahcrylate.

Examples of vinyl esters set forth above include divinyl succinate and divinyl adipate.

These polyfunctional monomers or oligomers may be used alone or in combination.

The polymerizable monomers set forth above may be combined with a polymerizable compound having one polymerizable group in the molecule, i.e. monofunctional monomer.

Examples of the mono functional monomers include the compounds exemplified as the raw materials for the binder set forth above, dibasic monofunctional monomer such as mono-(meth)acryloyloxyalkylester, mono-hydroxyalkylester, and γ-chloro-β-hydroxypropyl-β′-methacryloyloxyethyl-o-phthalate, and the compounds described in JP-A No. 06-236031, JP-B Nos. 2744643 and 2548016, and International Publication No. WO 00/52529.

Preferably, the content of the polymerizable compound in the photosensitive layer is 5 to 60% by mass, more preferably is 15 to 60% by mass, and still more preferably is 20 to 50% by mass.

When the content is less than 5% by mass, the strength of the tent film may be lower, and when the content is more than 90% by mass, the edge fusion at storage period is insufficient and bleeding trouble may be induced.

The content of the polyfunctional monomer having two or more polymerizable groups set forth above in the molecule is preferably 5 to 100% by mass, more preferably is 20 to 100% by mass, still more preferably is 40 to 100% by mass.

### —Photopolymerization Initiator—

The photopolymerization initiator may be properly selected from conventional ones without particular limitations as long as having the property to initiate polymerization; preferably is the initiator that exhibits photosensitivity from ultraviolet rays to visual lights. The initiator may be an active substance that generates a radical due to an effect with a photo-exited photosensitizer, or a substance that initiates cation polymerization depending on the monomer species.

Preferably, the photopolymerization initiator contains at least one component that has a molecular extinction coefficient of about 50 M⁻¹cm⁻¹ in a range is of about 300 to 800 nm, more preferably about 330 to 500 nm.

Examples of the photopolymerization initiator include halogenated hydrocarbon derivatives such as having a triazine skeleton or an oxadiazole skeleton, hexaaryl-biimidazols, oxime derivatives, organic peroxides, thio compounds, ketone compounds, aromatic onium salts, acylphosphine oxides, and metallocenes. Among these compounds, halogenated hydrocarbon compounds having a triazine skeleton, oxime derivatives, ketone compounds, and hexaaryl-biimidazol compounds are preferable from the view points of sensitivity of photosensitive layers, self stability, adhesive ability between the photosensitive layers and substrates for printed wiring boards.

Examples of the hexaaryl-biimidazol compounds include 2,2′-bis(2-chlorophenyl)-4,4′,5,5′-tetraphenyl-biimidazole, 2,2′-bis(o-fluorophenyl)-4,4′,5,5′-tetraphenyl-biimidazole, 2,2′-bis(o-bromophenyl)-4,4′,5,5′-tetraphenyl-biimidazole, 2,2′-bis(2,4-dichlorophenyl)-4,4′,5,5′-tetraphenyl-biimidazole, 2,2′-bis(2-chlorophenyl)-4,4′,5,5′-tetra(3-methoxyphenyl)biimidazole, 2,2′-bis(2-chlorophenyl)-4,4′,5,5′-tetra(4-methoxyphenyl)biimidazole, 2,2′-bis(4-emthoxyphenyl)-4,4′, 5,5′-tetraphenyl-biimidazole, 2,2′-bis(2,4-dichlorophenyl)-4,4′, 5,5′-tetraphenyl-biimidazole, 2,2′-bis(2-nitrophenyl)-4,4′, 5,5′-tetraphenyl-biimidazole, 2,2′-bis(2-methylphenyl)-4,4′, 5,5′-tetraphenyl-biimidazole, 2,2′-bis(2-trifluoromethylphenyl)-4,4′, 5,5′-tetraphenyl-biimidazole, and the compounds described in International Publication No. WO 00/52529.

The biimidazoles set forth above can be easily prepared by the methods described, for example, in Bulletin of the Chemical Society of Japan, 33, 565 (1960) and Journal of Organic Chemistry, 36, [16], 2262 (1971).

Examples of the halogenated hydrocarbon compounds having a triazine skeleton include the compounds described in Bulletin of the Chemical Society of Japan, by Wakabayasi, 42, 2924 (1969); GB Pat. No. 1388492; JP-A No. 53-133428; DE Pat. No. 3337024; Journal of Organic Chemistry, by F. C. Schaefer et. al. 29, 1527 (1964); JP-A Nos. 62-58241, 5-281728, and 5-34920; and U.S. Pat. No. 4,212,976.

Examples of the compounds described in Bulletin of the Chemical Society of Japan, by Wakabayasi, 42, 2924 (1969) set forth above include 2-phenyl-4,6-bis(trichloromethyl)-1,3,5-triazine, 2-(4-chlorophenyl)-4,6-bis(trichloromethyl)-1,3,5-triazine, 2-(4-tolyl)-4,6-bis(trichloromethyl)-1,3,5-triazine, 2-(4-methoxyphenyl)-4,6-bis(trichloromethyl)-1,3,5-triazine, 2-(2,4-dichlorophenyl)-4,6-bis(trichloromethyl)-1,3,5-triazine, 2,4,6-tris(trichloromethyl)-1,3,5-triazine, 2-methyl-4,6-bis(trichloromethyl)-1,3,5-triazine, 2-n-nonyl-4,6-bis(trichloromethyl)-1,3,5-triazine, and 2-(α,α,β-trichloroethyl)-4,6-bis(trichloromethyl)-1,3,5-triazine.

Examples of the compounds described in GB Pat. No. 1388492 set forth above include 2-styryl-4,6-bis(trichloromethyl)-1,3,5-triazine, 2-(4-methylstyryl)-4,6-bis(trichloromethyl)-1,3,5-triazine, 2-(4-methoxystyryl)-4,6-bis(trichloromethyl)-1,3,5-triazine, and 2-(4-methoxystyryl)-4-amino-6-trichloromethyl-1,3,5-triazine.

Examples of the compounds described in JP-A No. 53-133428 set forth above include 2-(4-methoxynaphtho-1-yl)-4,6-bistrichloromethyl-1,3,5-triazine, 2-(4-ethoxynaphtho-1-yl)-4,6-bistrichloromethyl-1,3,5-triazine, 2-[4-(2-ethoxyethyl)-naphtho-1-yl]-4,6-bistrichloromethyl-1,3,5-triazine, 2-(4,7-dimethoxynaptho-1-yl)-4,6-bistrichloromethyl-1,3,5-triazine, and 2-(acenaphtho-5-yl)-4,6-bistrichloromethyl-1,3,5-triazine.

Examples of the compounds described in DE Pat. No. 3337024 set forth above include 2-(4-styrylphenyl)-4,6-bis(trichloromethyl)-1,3,5-triazine, 2-(4-(4-methoxystyryl)phenyl)-4,6-bis(trichloromethyl)-1,3,5-triazine, 2-(1-naphthylvinylenephenyl)-4,6-bis(trichloromethyl)-1,3,5-triazine, 2-chlorostyrylphenyl-4,6-bis(trichloromethyl)-1,3,5-triazine, 2-(4-thiophene-2-vinylenephenyl)-4,6-bis(trichloromethyl)-1,3,5-triazine, 2-(4-thiophene-3-vinylenephenyl)-4,6-bis(trichloromethyl)-1,3,5-triazine, 2-(4-furan-2-vinylenephenyl)-4,6-bis(trichloromethyl)-1,3,5-triazine, and 2-(4-benzofuran-2-vinylenephenyl)-4,6-bis(trichloromethyl)-1,3,5-triazine.

Examples of the compounds described in Journal of Organic Chemistry, by F. C. Schaefer et. al. 29, 1527 (1964) set forth above include 2-methyl-4,6-bis(tribromomethyl)-1,3,5-triazine, 2,4,6-tris(tribromomethyl)-1,3,5-triazine, 2,4,6-tris(dibromomethyl)-1,3,5-triazine, 2-amino-4-methyl-6-tribromomethyl-1,3,5-triazine and 2-methoxy-4-methyl-6-trichloromethyl-1,3,5-triazine.

Examples of the compounds described in JP-A No. 62-58241 set forth above include 2-(4-phenylethylphenyl)-4,6-bis(trichloromethyl)-1,3,5-triazine, 2-(4-naphthyl-1-ethynylphenyl)-4,6-bis(trichloromethyl)-1,3,5-triazine, 2-(4-(4-triethynyl)phenyl)-4,6-bis(trichloromethyl)-1,3,5-triazine, 2-(4-(4-methoxyphenyl)ethynylphenyl)-4,6-bis(trichloromethyl)-1,3,5-triazine, 2-(4-(4-isopropylphenylethynyl)phenyl)-4,6-bis(trichloromethyl)-1,3,5-triazine, and 2-(4-(4-ethylphenylethynyl)phenyl)-4,6-bis(trichloromethyl)-1,3,5-triazine.

Examples of the compounds described in JP-A No. 5-281728 set forth above include 2-(4-trifluoromethylphenyl)-4,6-bis(trichloromethyl)-1,3,5-triazine, 2-(2,6-difluorophenyl)-4,6-bis(trichloromethyl)-1,3,5-triazine, 2-(2,6-dichlorophenyl)-4,6-bis(trichloromethyl)-1,3,5-triazine, and 2-(2,6-dibromophenyl)-4,6-bis(trichloromethyl)-1,3,5-triazine.

Examples of the compounds described in JP-A No. 5-34920 set forth above include 2,4-bis(trichloromethyl)-6-[4-(N,N-diethoxycarbonylmethylamino)-3-bromophenyl]-1,3,5-triazine, trihalomethyl-s-triazine compounds described in U.S. Pat. No. 4,239,850, and also 2,4,6-tris(trichloromethyl)-s-triazine, and 2-(4-chlorophenyl)-4,6-bis(tribromomethyl)-s-triazine.

Examples of the compounds described in U.S. Pat. No. 4,212,976 set forth above include the compounds having an oxadiazole skeleton such as 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole, 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxystyryl)-1,3,4-oxadiazole, and 2-tribromomethyl-5-styryl-1,3,4-oxadiazole.

Examples of the oxime derivatives set forth above include the compounds expressed by the following formulas (38) to (71).

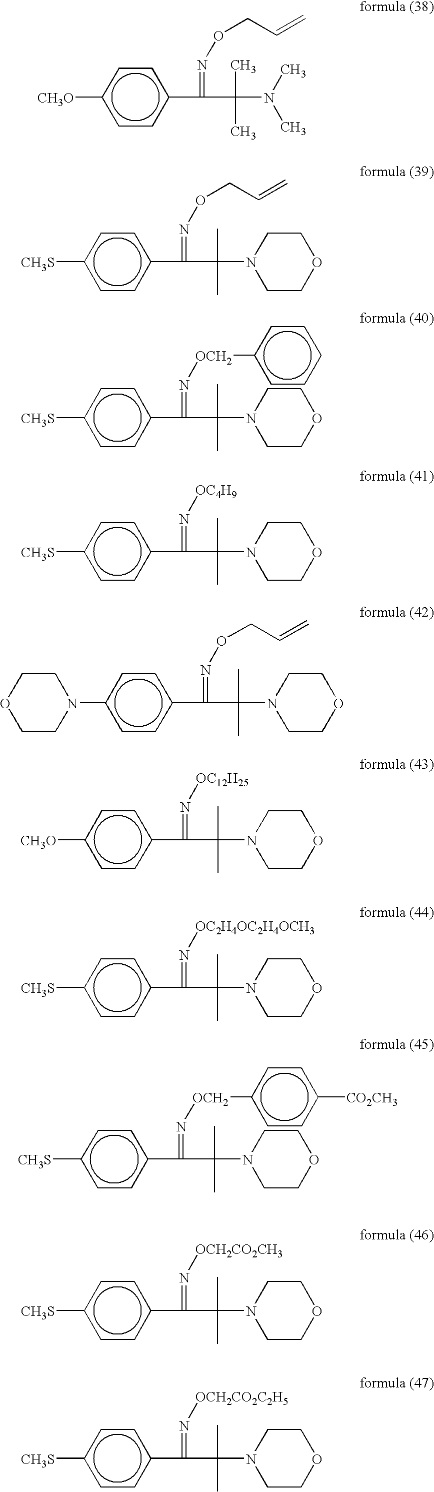

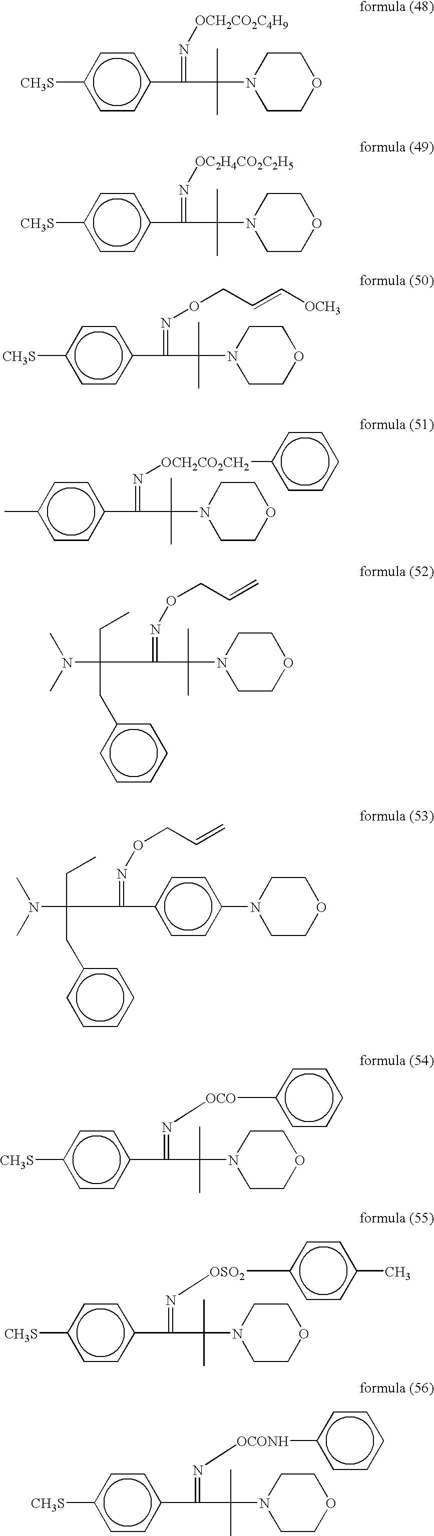

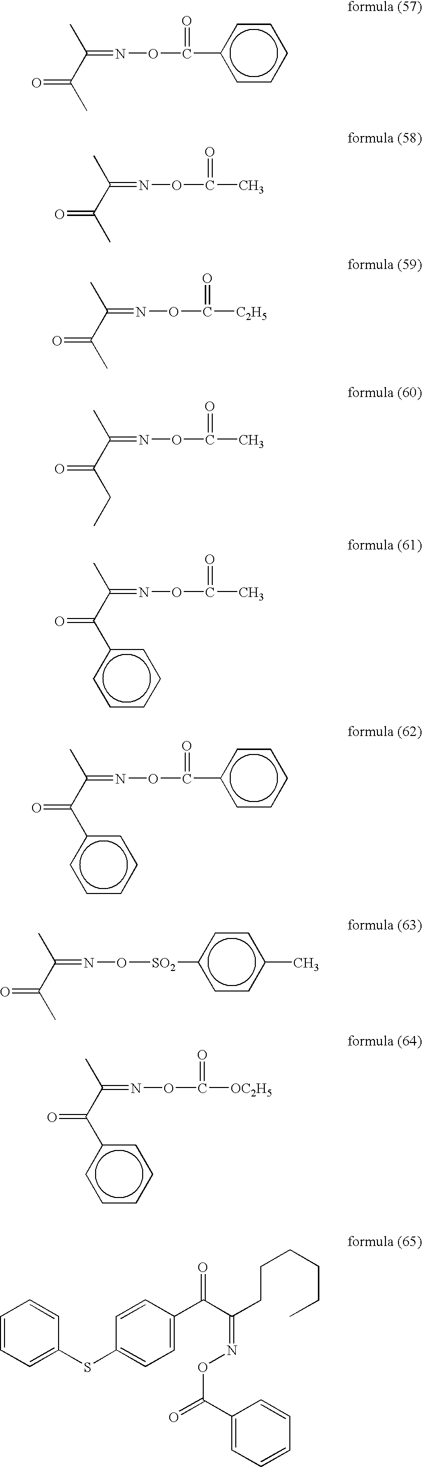

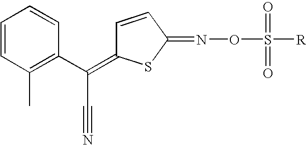

| | R |
|---|---|
| formula (66) | n-C₃H₇ |
| formula (67) | n-C₈H₁₇ |
| formula (68) | camphor |
| formula (69) | p-CH₃C₆H₄ |

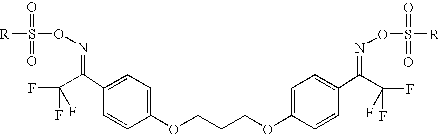

| | R |
|---|---|
| formula (70) | n-C₃H₇ |
| formula (71) | p-CH₃C₆H₄ |

Examples of the ketone compounds set forth above include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone-tetracarboxylic acid and its tetramethyl ester; 4,4′-bis(dialkylamino)benzophenones such as 4,4′-bis(dimethylamino)benzophenone, 4,4′-bis(cyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, and 4-dimethylaminobenzophenone; 4-dimethylaminoacetophenone, benzyl, anthraquinone, 2-tert-butylanthraquinone, 2-methylanthraquinone, phenanthraquinone, xanthone, thioxanthone, 2-chlorothioxanthone, 2,4-diethylthioxanthone, fluorene, 2-benzyl-dimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin; benzoin ethers such as benzoin methylether, benzoin ethylether, benzoin propylether, benzoin isopropylether, benzoin phenylether, and benzyl dimethyl ketal; acridone, chloroacridone, N-methylacridone, N-butylacridone, and N-butyl-chloroacridone.

Examples of the metallocenes include bis(η5-2,4-cyclopentadiene-1-yl)-bis(2,6-difluoro-3-(1H-pyrrole-1-yl)-phenyl)titanium, η5-cyclopentadienyl-η6-cumenyl-iron(1+)-hexafluorophosphate(1−), and the compounds described in JP-A No. 53-133428, JP-B Nos. 57-1819 and 57-6096, and U.S. Pat. No. 3,615,455.

As for photopolymerization initiators other than set forth above, the following substances are further exemplified: acridine derivatives such as 9-phenyl acridine and 1,7-bis(9,9′-acridinyl)heptane; polyhalogenated compounds such as carbon tetrabromide, phenyltribromosulfone, and phenyltrichloromethylketone; coumarins such as 3-(2-benzofuroyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and 7-benzotriazol-2-ylcoumarin, and also the coumarin compounds described in JP-A Nos. 5-19475, 7-271028, 2002-363206, 2002-363207, 2002-363208, and 2002-363209; amines such as ethyl 4-dimethylamibenzoate, n-butyl 4-dimethylamibenzoate, phenethyl 4-dimethylamibenzoate, 2-phthalimide 4-dimethylamibenzoate, 2-methacryloyloxyethyl 4-dimethylamibenzoate, pentamethylene-bis(4-dimethylaminobenzoate), phenethyl 3-dimethylamibenzoate, pentamethylene esters, 4-dimethylamino benzaldehyde, 2-chloro-4-dimethylamino benzaldehyde, 4-dimethylaminobenzyl alcohol, ethyl(4-dimethylaminobenzoyl)acetate, 4-piperidine acetophenone, 4-dimethyamino benzoin, N,N-dimethyl-4-toluidine, N,N-diethyl-3-phenetidine, tribenzylamine, dibenzylphenylamine, N-methyl-N-phenylbenzylamine, 4-bromo-N,N-diethylaniline, and tridodecyl amine; amino fluorans such as ODB and ODBII; leucocrystal violet; acylphosphine oxides such as bis(2,4,6-trimethylbenzoyl)phenylphosphine oxide, bis(2,6-dimethylbenzoyl)-2,4,4-trimethyl-pentylphenylphosphine oxide, and Lucirin TPO.

In addition, as for still other photopolymerization initiator, the following substances are exemplified: vicinal polyketaldonyl compounds as described in U.S. Pat. No. 2,367,660; acyloin ether compounds as described in U.S. Pat. No. 2,448,828; aromatic acyloin compounds substituted with an α-hydrocarbon as described in U.S. Pat. No. 2,722,512; polynucleic quinone compounds as described in U.S. Pat. Nos. 3,046,127 and 2,951,758; various substances described in JP-A No. 2002-229194 such as organic boron compounds, radical generators, triarylsulfonium salts e.g. salts with hexafluoroantimony or hexafluorophosphate, phosphonium salts e.g. (phenylthiophenyl)diphenylsulfonium (effective as cation polymerization initiator), and onium salt compounds described in International Publication No. WO 01/71428.

These photopolymerization initiators may be used alone or in combination. The combination of two or more photopolymerization initiators may be for example the combination of hexaaryl-biimidazol compounds and 4-amino ketones described in U.S. Pat. No. 3,549,367; combination of benzothiazole compounds and trihalomethyl-s-triazine compounds as described in JP-B No. 51-48516; combination of aromatic ketone compounds such as thioxanthone and hydrogen donating substance such as dialkylamino-containing compounds or phenol compounds; combination of hexaaryl-biimidazol compounds and titanocens; and combination of coumarins, tinanocens, and phenyl glycines.

The content of the photopolymerization initiator in the photosensitive layer is preferably 0.1 to 30% by mass, more preferably is 0.5 to 20% by mass, and still more preferably is 0.5 to 15% by mass.

### —Photosensitizer—

It is particularly preferable that a photosensitizer is incorporated into the pattern forming material according to the present invention in order to enhance the sensitivity or minimum energy of the laser beam, which is required to yield substantially the same thickness of photosensitive layer subsequent to the developing as the thickness of the photosensitive layer prior to the exposing. The sensitivity or minimum energy of the laser beam can be easily adjusted to, for example, 0.1 to 10 mJ/cm² by use of the photosensitizer.

The photosensitizer may be properly selected depending on the laser source such as UV or visible laser beam. The maximum absorption wavelength of the photosensitizer is preferably 380 to 450 nm, when the wavelength of the laser beam is 380 to 420 nm.

The photosensitizer may be exited by irradiating active laser beam, and may generate a radical, an available acidic group, and the like through interacting with other substances such as radical generators and acid generators by way of transferring energy or electrons.

The photosensitizer may be properly selected without particular limitations from conventional substances; examples of the photosensitizer include polynuclear aromatics such as pyrene, perylene, and triphenylene; xanthenes such as fluorescein, Eosine, erythrosine, rhodamine B, and Rose Bengal; cyanines such as indocarbocianine, thiacarbocianine, and oxacarbocianine; merocianines such as merocianine and carbomerocianine; thiazins such as thionine, methylene blue, and toluidine blue; acridines such as acridine orange, chloroflavine, acriflavine, 9-phenylacridine, and 1,7-bis(9,9′-acridine)heptane; anthraquinones such as anthraquinone; scariums such as scarium; acridones such as acridone, chloroacridone, N-methylacridone, N-butylacridone, N-butyl-chloroacridone, and 10-butyl-2-chloroacridone; coumarins such as 3-(2-benzofuroyl)-7-diethylaminocoumarin, 3-(2-benzofuroyl)-7-(1-pyrrolidinyl)coumarin, 3-benzofuroyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and also the coumarin compounds described in JP-A Nos. 5-19475, 7-271028, 2002-363206, 2002-363207, 2002-363208, and 2002-363209. Among them, fused ring compounds synthesized from aromatic compounds and heterocyclic compounds are more preferable, and fused ring ketone compounds such as acridones and coumarins, and acridines are still more preferable.

As for the combination of the photopolymerization initiator and the photosensitizer, the initiating mechanism that involves electron transfer may be represented by such combinations as (1) an electron donating initiator and a photosensitizer dye; (2) an electron accepting initiator and a photosensitizer dye; and (3) an electron donating initiator, an electron accepting initiator, and a photosensitizer dye (ternary mechanism); as illustrated in JP-A No. 2001-305734.

The content of the photosensitizer is preferably 0.01 to 4% by mass, more preferably is 0.2 to 2% by mass, and still more preferably is 0.05 to 1% by mass based on the entire composition of the photosensitive resin.

When the content is less than 0.01% by mass, the sensitivity of the pattern forming material may decrease, and when the content is more than 4% by mass, the pattern geometry may be inferior.

### —Other Components—

As for the other components, plasticizer, coloring agent, colorant, dye, and surfactant are exemplified; in addition, the other auxiliaries such as adhesion promoter on substrate surface, pigment, conductive particles, filler, defoamer, fire retardant, leveling agent, peeling promoter, antioxidant, perfume, thermocrosslinker, adjustor of surface tension, chain transfer agent, and the like may be utilized together with. By means of incorporating these components properly, desirable properties of the pattern forming material such as stability with time, photographic property, developing property, film property, and the like may be tailored.

### —Plasticizer—

The plasticizer set forth above may be incorporated into in order to adjust the film property such as flexibility of the photosensitive layer.

Examples of the plasticizer include phthalic acid esters such as dimethylphthalate, dibutylphthalate, diisobutylphthalate, diheptylphthalate, dioctylphthalate, dicyclohexylphthalate, ditridecylphthalate, butylbenzylphthalate, diisodecylphthalate, diphenylphthalate, diallylphthalate, and octylcaprylphthalate; glycol esters such as triethyleneglycol diacetate, tetraethyleneglycol diacetate, dimethylglycose phthalate, ethylphthalyl ethylglycolate, methylphthalyl ethylglycolate, buthylphthalyl buthylglycolate, triethylene glycol dicaprylate; phosphoric acid esters such as tricresylphosphate and triphenylphosphate; amides such as 4-toluenesulfone amide, benzenesulfone amide, N-n-butylsulfone amide, and N-n-aceto amide; aliphatic dibasic acid esters such as diisobutyl adipate, dioctyl adipate, dimethyl sebacate, dibutyl sebacate, dioctyl sebacate, and dibutyl maleate; triethyl citrate, tributyl citrate, glycerin triacetyl ester, butyl laurate, 4,5-diepoxy-cyclohexane-1,2-dicarboxylic acid dioctyl; and glycols such as polyethylene glycol and polypropylene glycol.

The content of the plasticizer set forth above is preferably 0.1 to 50% by mass, more preferably is 0.5 to 40% by mass, and still more preferably is 1 to 30% by mass based on the entire composition of the photosensitive layer.

### —Coloring Agent—

The coloring agent may be utilized to provide visible images or to afford developing property on the photosensitive layer set forth above after exposure.

Examples of the coloring agent include aminotriarylmethanes such as tris(4-dimethylaminophenyl)methane (leucocrystal violet), tris(4-diethylaminophenyl)methane, tris(4-dimethylamino-2-methylphenyl)methane, tris(4-diethylamino-2-methylphenyl)methane, bis(4-dibutylaminophenyl)-[4-(2-cyanoethyl)methylaminophenyl]methane, bis(4-dimethylaminophenyl)-2-quinolylmethane, and tris(4-dipropylaminophenyl)methane; aminoxanthenes such as 3,6-bis(diethylamino)-9-phenylxanthene and 3-amino-6-dimethylamino-2-methyl-9-(o-chlorophenyl)xanthene; aminothioxanthenes such as 3,6-bis(diethylamino)-9-(2-ethoxycarbonylphenyl)thioxanthene and 3,6-bis(dimethylamino)thioxanthene; amino-9,10-dihydroacridines such as 3,6-bis(diethylamino)-9,10-dihydro-9-phenylacridine and 3,6-bis(benzylamino)-9,10-dihydro-9-methylacridine; aminophenoxazines such as 3,7-bis(diethylamino)phenoxazines; aminophenothiazines such as 3,7-bis(ethylamino)phenothiazine; aminodihydrophenazines such as 3,7-bis(diethylamino)-5-hexyl-5,10-dihydrophenazine; aminophenylmethanes such as bis(4-dimethylaminophenyl)anilinomethane; aminohydrocinnamic acids such as 4-amino-4′-dimethylaminodiphenylamine and 4-amino-α,β-dicyanohydrocinnamate methyl ester; hydrazines such as 1-(2-naphthyl)-2-phenylhydrazine; amino-2,3-dihydroanthraquinones such as 1,4-bis(ethylamino)-2,3-dihydroanthraquinone; phenethylanilines such as N,N-diethyl-p-phenethylaniline; acyl derivatives of leuco dyes containing a basic NH group such as 10-acetyl-3,7-bis(dimethylamino)phenothiazine; leuco-like compounds with no oxidizable hydrogen and capable of being oxidized into colored compounds such as tris(4-diethylamino-2-tolyl)ethoxycarbonylmethane; leucoindigoid dyes; organic amines capable of being oxidized to colored forms as described in U.S. Pat. Nos. 3,042,515 and 3,042,517 such as 4,4′-ethylenediamine, diphenylamine, N,N-dimethylaniline, 4,4′-methylenediaminetriphenylamine, and N-vinylcarbazole. Among these coloring agents, triarylmethanes such as leucocrystal violet are preferable in particular.

In addition, it is known that the coloring agents set forth above may be combined with halogenated compounds in order to develop a color from the leuco compounds.

Examples of the halogenated compounds include halogenated hydrocarbons such as tetrabromocarbon, iodoform, ethylene bromide, methylene bromide, amyl bromide, isoamyl bromide, amyl iodide, isobutylene bromide, butyl iodide, diphenylmethyl bromide, hexachloromethane, 1,2-dibromoethane, 1,1,2,2-tetrabromoethane, 1,2-dibromo-1,1,2-trichloroethane, 1,2,3-tribromopropane, 1-bromo-4-chlorobutane, 1,2,3,4-tetrabromobutane, tetrachlorocyclopropene, hexachlorocyclopentadiene, dibromocyclohexane, and 1,1,1-trichloro-2,2-bis(4-chlorophenyl)ethane; halogenated alcohol compounds such as 2,2,2,-trichloroethanol, tribromoethanol, 1,3-dichloro-2-propanol, 1,1,1-trichloro-2-propanol, di(iodohexamethylene)aminoisopropanol, tribromo-tert-butyl alcohol, and 2,2,3-trichlorobutane-1,4-diol; halogenated carbonyl compounds such as 1,1-dichloroacetone, 1,3-dichloroacetone, hexachloroacetone, hexabromoacetone, 1,1,3,3-tetrachloroacetone, 1,1,1-trichloroacetone, 3,4-dibromo-2-butanone, and 1,4-dichloro-2-butanone-dibromocyclohexanone; halogenated ether compounds such as 2-bromoethyl methylether, 2-bromoethyl ethylether, di(2-bromoethyl)ether, and 1,2-dichloroethyl ethylether; halogenated ester compounds such as bromoethyl acetate, ethyl trichloroacetate, trichloroethyl trichloroacetate, homo- and co-polymers of 2,3-dibromopropyl acrylate, trichloroethyl dibromopropionate, and ethyl α,β-dichloroacrylate; halogenated amide compounds such as chloroacetamide, bromoacetamide, dichloroacetamide, trichloroacetamide, tribromoacetamide, trichloroethyltrichloroacetamide, 2-bromoisopropionamide, 2,2,2-trichloropropionamide, N-chlorosuccinimide, and N-bromosuccinimide; compounds containing a sulfur and/or phosphorus atom such as tribromomethyl phenylsulfone, 4-nitrophenyltribromo methylsulfone, 4-chlorophenyltribromo methylsulfone, tris(2,3-dibromopropyl)phosphate, and 2,4-bis(trichloromethyl)-6-phenyltriazole.

In the organic halogenated compounds, preferably are those containing two or more halogen atoms that are attached to one carbon atom, more preferably are those containing three halogen atoms that are attached to one carbon atom. The organic halogenated compounds may be used alone or in combination. Among these halogenated compounds, tribromomethyl phenylsulfone and 2,4-bis(trichloromethyl)-6-phenyltriazole are preferable.

The content of the coloring agent is preferably 0.01 to 20% by mass, more preferably is 0.05 to 10% by mass, and still more preferably is 0.1 to 5% by mass based on the entire composition of the photosensitive layer. The content of the halogenated compound is preferably 0.001 to 5% by mass, more preferably is 0.005 to 1% by mass based on the entire composition of the photosensitive layer.

### —Colorant—

The colorant may be properly selected depending on the application; the colorant may be exemplified by publicly known pigments and dyes of red, green, blue, yellow, violet, magenta, cyan, black, and the like; more specifically, examples of the colorant include Victoria Pure Blue BO (C.I. 42595), Auramine (C.I. 41000), Fat Black HB (C.I. 26150), Monolite Yellow GT (C.I. Pigment Yellow 12), Permanent Yellow GR (C.I. Pigment Yellow 17), Permanent Yellow HR(C.I. Pigment Yellow 83), Permanent Carmine FBB (C.I. Pigment Red 146), Permred ESB (C.I. Pigment Violet 19), Permanent Ruby FBH (C.I. Pigment Red 11), Fastel Pink B Spra (C.I. Pigment Red 81), Monastral Fast Blue (C.I. Pigment Blue 15), Monolite Fast Black B (C.I. Pigment Black 1), and carbon black.

Examples of the colorants suited to prepare color filters include C.I. Pigment Red 97, C.I. Pigment Red 122, C.I. Pigment Red 149, C.I. Pigment Red 168, C.I. Pigment Red 177, C.I. Pigment Red 180, C.I. Pigment Red 192, C.I. Pigment Red 215, C.I. Pigment Green 7, C.I. Pigment Green 36, C.I. Pigment Blue 15:1, C.I. Pigment Blue 15:4, C.I. Pigment Blue 15:6, C.I. Pigment Blue 22, C.I. Pigment Blue 60, C.I. Pigment Blue 64, C.I. Pigment Yellow 139, C.I. Pigment Yellow 83, C.I. Pigment Violet 23, and those illustrated in [0138] to [0141] of JP-A No. 2002-162752. The average particle size of the colorant may be properly selected depending on the application; preferably, the average particle size is 5 μm or less, more preferably is 1 μm or less. When the colorant is applied to color filters, the average particle size is preferably 0.5 μm or less.

### —Dye—

To the photosensitive layer set forth above, a dye may be incorporated into in order to add a color so as to make easy the handling or to enhance the storage stability.

Examples of the dye include Brilliant Green, Eosin, Ethyl Violet, Erythrosine B, Methyl Green, Crystal Violet, Basic Fuchsine, phenolphthalein, 1,3-diphenyltriazine, Alizarin Red S, Thymolphthalein, Methyl Violet 2B, Quinaldine Red, Rose Bengale, Metanil-Yellow, Thymolsulfophthalein, Xylenol Blue, Methyl Orange, Orange IV, diphenyl thiocarbazone, 2,7-dichlorofluorescein, Para Methyl Red, Congo Red, Benzopurpurine 4B, α-Naphthyl Red, Nile Blue 2B, Nile Blue A, phenacetarin, Methyl Violet, Malachite Green, Para Fuchsine, Oil Blue #603 (produced by Orient Chemical Industry Co., Ltd.), Rhodamine B, Rhodamine 6G, and Victoria Pure Blue BOH. Among these dyes, preferably are cation dyes such as oxalate of Malachite Green and sulfate of Malachite Green. The pair anion of the cation dyes may be residues of organic acid or inorganic acid such as bromic acid, iodic acid, sulfuric acid, phosphoric acid, oxalic acid, methane sulfonic acid, and toluene sulfonic acid.

The content of the dye is preferably 0.001 to 10% by mass, more preferably is 0.01 to 5% by mass, and still more preferably is 0.1 to 2% by mass based on the entire composition of the photosensitive layer.

### —Adhesion Promoter—

In order to enhance the adhesion between layers of the pattern forming material or between the pattern forming material and the substrate, so-called adhesion promoters may be employed.

Examples of the adhesion promoters set forth above include those described in JP-A Nos. 5-11439, 5-341532, and 6-43638; specific examples of adhesion promoters include benzimidazole, benzoxazole, benzthiazole, 2-mercaptobenzimidazole, 2-mercaptobenzoxazole, 2-mercaptobenzthiazole, 3-morpholinomethyl-1-phenyl-triazole-2-thion, 3-morpholinomethyl-5-phenyl-oxadiazole-2-thion, 5-amino-3-morpholinomethyl-thiadiazole-2-thion, 2-mercapto-5-methylthio-thiadiazole, triazole, tetrazole, benzotriazole, carboxybenzotriazole, benzotriazole containing an amino group, and silane coupling agents.

The content of the adhesion promoter is preferably 0.001 to 20% by mass, more preferably is 0.01 to 10% by mass, and still more preferably is 0.1 to 5% by mass based on the entire composition of the photosensitive layer.

The photosensitive layer may contain, as described in “Light Sensitive Systems, chapter 5th, by J. Curser”, organic sulfur compounds, peroxides, redox compounds, azo or diazo compounds, photoreductive dyes, or organic halogen compounds.

Examples of the organic sulfur compounds include di-n-butyldisulfide, dibenzyldisulfide, 2-mercaptobenzthiazole, 2-mercaptobenzoxazole, thiophenol, ethyl trichloromethane sulfonate, and 2-mercaptobenzimidazole.

Examples of the peroxides include di-t-butyl peroxide, benzoyl peroxide, and methyethylketone peroxide.

The redox compounds set forth above mean a combination of a peroxide and a reducer; examples thereof include the combination of persulfate ion and ferrous ion, peroxide and ferric ion, and the like.

Examples of azo or diazo compounds set forth above include diazoniums such as α,α′-azobis-isobutylonitrile, 2-azobis-2-methylbutylonitrile, and 4-aminodiphenylamine.

Examples of the photoreductive dyes set forth above include Rose Bengale, Erythrosine, Eosine, acriflavine, riboflavin, and thionine.

### —Surfactant—

In order to improve surface nonuniformity generated while producing the pattern forming material according to the present invention, conventional surfactants may be employed.

The surfactant may be properly selected from anionic surfactants, cationic surfactants, nonionic surfactants, ampholytic surfactants, fluorine-containing surfactants, and the like.

The content of the surfactant is preferably 0.001 to 10% by mass based on the solid content of the photosensitive resin composition. When the content is less than 0.001% by mass, the effect to improve the nonuniformity may be insufficient, and when the content is more than 10% by mass, the adhesion ability may be deteriorated.

In addition, as for the surfactants, such polymer surfactants containing fluorine may be preferably exemplified as those containing 40% by mass or more of fluorine atoms, having a carbon chain of 3 to 20 carbon atoms, and having a copolymerized component of acrylate or methacrylate containing an aliphatic group of which the hydrogen atoms bonded on the terminal carbon atom to the third of the carbon atom are substituted by fluorine atoms.

The thickness of the photosensitive layer may be properly selected without particular limitations; preferably, the thickness is 0.1 to 10 μm, more preferably is 2 to 50 μm, and still more preferably is 4 to 30 μm.

### <Support>

The support may be properly selected without particular limitations as long as the haze is 5.0% or less. Preferably, the photosensitive layer can be peeled away from the support, the support exhibits higher transmittance, and the surface of the support is relatively smooth.

### —Haze—

The haze of the support is preferably 5.0% or less, more preferably is 3.0% or less, and still more preferably is 1.0% or less in terms of the light having a wavelength 405 nm. When the haze is more than 5.0%, the light tends to scatter within the photosensitive layer, resulting possibly in inferior resolution for achieving fine pitch.

The total light transmittance of the support is preferably 86% or more in terms of the light having a wavelength 405 nm, more preferably is 87% or more.

The haze and the total light transmittance may be properly measured depending on the application; for example, the following method is recommended.

Initially, (1) the total light transmittance is measured, for example, by means of an integrating sphere and a spectrophotometer equipped with a light source of 405 nm (e.g. UV-2400, by Shimadzu Co.); (2) parallel light transmittance is determined in the same manner as the total light transmittance except that the integrating sphere is not utilized; then, (3) diffused light transmittance is determined from the following calculation:

(total light transmittance)−(parallel light transmittance)

and, (4) haze is determined from the following calculation:

(diffused light transmittance)÷(total light transmittance)×100(%)

The thickness of the sample is adjusted to 16 μm for determining the total light transmittance and the haze of the support.

Further, so-called inert fine particles may be coated on at least one surface of the support. Preferably, the inert fine particles are coated on the opposite side to which the photosensitive layer is formed.

Examples of the inert fine particles include crosslinked polymer particles; inorganic particles such as of calcium carbonate, calcium phosphate, silica, kaolin, talc, titanium dioxide, alumina, barium sulfate, calcium fluoride, lithium fluoride, zeolite, and molybdenum sulfide; organic particles such as of hexamethylene bis-behenamide, hexamethylene bis-stearylamide, N,N′-distearyl terephthalamide, silicone, and calcium oxalate; and precipitated particles through polyester polymerization process. Among them, more preferable are silica, calcium carbonate, and hexamethylene bis-behenamide.

The precipitated particles described above are those precipitated within a reactor in a conventional polymerization process using an alkali metal or alkaline earth metal compound as an ester exchange catalyst. The precipitated particles may be those precipitated by adding terephthalic acid during ester exchange reaction or polycondensation reaction. In the ester exchange reaction or polycondensation reaction, one or more of phosphorus compound may be present such as phosphoric acid, trimethyl phosphate, triethyl phosphate, tributyl phosphate, acidic ethylphosphate, phosphorous acid, trimethyl phosphite, triethyl phosphite, and tributyl phosphite.

The average particle diameter of the inert fine particles is preferably 0.01 to 2.0 μm, more preferably is 0.02 to 1.5 μm, still more preferably is 0.03 to 1.0 μm, especially preferably is 0.04 to 0.5 μm.

When the average particle diameter of the inert fine particles is less than 0.01 μm, the conveying ability of the pattern forming material may be inferior. Further, when the content of the inert fine particles is increased in order to improve the conveying ability, the haze of the support may also raise. When the average particle diameter of the inert fine particles is above 2.0 μm, the resolution may be deteriorated due to the scattering of exposing laser.

The method for coating the inert fine particles may be properly selected depending on the application. For example, the coating liquid that contains the inert fine particles is coated by a conventional method, after the synthetic resin film for the support is produced; the synthetic resin, into which the inert fine particles are dispersed, is melted and molded on the synthetic resin film for the support; or the method illustrated in JP-A No. 2000-221688 may be applied for coating the inert fine particles.

The thickness of the coating layer that contains the inert fine particles is preferably 0.02 to 3.0 μm, more preferably is 0.03 to 2.0 μm, and still more preferably is 0.04 to 1.0 μm.

The synthetic resin film of the support is preferably transparent; the synthetic resin film is preferably of polyester resin, more preferably is a biaxially oriented polyester film.

Examples of the polyester resin include polyethylene terephthalate, polyethylene naphthalate, poly(meth)acrylate copolymer, poly(meth)alkylacrylate, polyethylene-2,6-naphthalate, polytetramethylene terephthalate, polytetramethylene-2,6-naphthalate. These may be used alone or in combination.

Examples of the resins other than the polyester resins described above include polypropylene, polyethylene, triacetyl cellulose, diacetyl cellulose, polyvinyl chloride, polyvinyl alcohol, polycarbonate, polystyrene, cellophane, polyvinylidene chloride copolymer, polyamide, polyimide, vinylchloride-vinylacetate copolymer, polytetrafluoroethylene, polytrifluoroethylene, cellulose resins, and nylon resins. These resins may be used alone or in combination.

The synthetic resin film may be of one layer or no less than two layers. When the synthetic resin film is comprised of two or more layers, preferably, the inert fine particles are incorporated into the layer outermost from the photosensitive layer.

Preferably, the synthetic resin film is a biaxially oriented polyester film from the viewpoint of mechanical strength and optical properties.

The method to orient biaxially the polyester film may be properly selected depending on the application. For example, the polyester resin is melted and extruded into a film, and is cooled rapidly into an unoriented film, then is oriented biaxially at a temperature of 85 to 145° C. and a stretching ratio of 2.6 to 4.0 times in longitudinal and traverse directions to prepare the biaxially oriented polyester film. The biaxially oriented polyester film may be further thermally fixed at 150 to 210° C. depending on requirements.

The biaxial orientation may be performed in two steps such that the unoriented film is oriented uniaxially in longitudinal or traverse direction, then the uniaxially oriented film is further uniaxially oriented in another direction; alternatively, the biaxial orientation may be performed in one step such that the unoriented film is oriented biaxially at the same time in longitudinal and traverse directions. The biaxially oriented film may be further oriented depending on requirements.

The thickness of the support may be properly selected depending on the application; the thickness is preferably 2 to 150 μm, more preferably is 5 to 100 μm, and still more preferably is 8 to 50 μm.

The geometry of the support may be properly selected depending on the application; preferably, the geometry of the support is elongated shape. The length of the elongated support is 10 to 20000 meters, for example.

### <Protective Film>

In the pattern forming material, a protective film may be provided on the photosensitive layer. The material of the protective film may be those exemplified with respect to the support set forth above, and also may be paper, polyethylene, paper laminated with polypropylene, or the like. Among these materials, polyethylene film and polypropylene film are preferable.

The thickness of the protective film may be properly selected without particular limitations; preferably, the thickness is 5 to 100 μM, more preferably is 8 to 50 μm, and still more preferably is 10 to 30 μm.

The combinations of the support and the protective film, i.e. (support/protective film), are exemplified by (polyethylene terephthalate/polypropylene), (polyethylene terephthalate/polyethylene), (polyvinyl chloride/cellophane), (polyimide/polypropylene), and (polyethylene terephthalate/polyethylene terephthalate). Further, the surface treatment of the support and/or the protective film may result in the relation of the adhesive strength set forth above. The surface treatment of the support may be utilized for enhancing the adhesive strength with the photosensitive layer; examples of the surface treatment include deposition of under-coat layer, corona discharge treatment, flame treatment, UV-rays treatment, RF exposure treatment, glow discharge treatment, active plasma treatment, and laser beam treatment.

The static friction coefficient between the support and the protective film is preferably 0.3 to 1.4, more preferably is 0.5 to 1.2.

When the static friction coefficient is less than 0.3, winding displacement may generate in the pattern forming material having a roll configuration due to excessively high slipperiness, and when the static friction coefficient is more than 1.4, winding of the material in a roll configuration tends to be difficult.

Preferably, the pattern forming material is wound on a cylindrical winding core, and is stored in an elongated roll configuration. The length of the elongated pattern forming material may be properly selected without particular limitations, for example the length is from 10 to 20000 meters. Further, the pattern forming material may be subjected to slit processing for easy handling in the usages, and may be provided as a roll configuration for every 100 to 1000 meters. Preferably, the pattern forming material is wound such that the support exists at outer most side of the roll configuration. Further, the pattern forming material may be slit into a sheet configuration. In the storage, preferably, a separator of moistureproof with desiccant in particular is provided at the end surface of the pattern forming material, and the packaging is performed using a material of higher moistureproof for preventing edge fusion.

In order to arrange the adhesive property between the protective film and the photosensitive layer, the protective layer may be subjected to a surface treatment. The surface treatment is carried out, for example, by forming an undercoat layer of polymer such as polyorganosiloxane, polyolefin fluoride, polyfluoroethylene, and polyvinyl alcohol. Specifically, the undercoat layer may be formed by applying the coating liquid of the polymer described above on the protective film, and drying the coating liquid at 30 to 150° C. for 1 to 30 minutes, for example.

### <<Other Layers>>

The other layers may be properly selected depending on the application; examples of the other layers include a cushioning layer, barrier layer, peeling layer, adhesive layer, optical absorbing layer, surface protective layer, and the like. The pattern forming material may include one of these layers or two or more of these layers.

Preferably, the photosensitive layer of the pattern forming material according to the present invention is exposed in a condition that modulating a laser beam irradiated from a laser source by a laser modulator that comprises plural imaging portions each capable of receiving the laser beam and outputting the modulated laser beam, and exposing by the laser beam that is transmitted through a microlens array of plural microlenses each having a non-spherical surface capable of compensating the aberration due to distortion of the output surface of the imaging portions or each having an aperture configuration capable of substantially shielding incident light other than the modulated laser beam from the laser modulator. Explanations are provided later with respect to the laser source, laser modulator, imaging portion, non-spherical surface, microlens, and microlens array.

### [Production of Pattern Forming Material]

The pattern forming material according to the present invention may be produced as follows. Initially, a solution of photosensitive resin composition is prepared by dissolving, emulsifying, or dispersing the various components or materials set forth above into water or solvents.

The solvent of the solution of photosensitive resin composition may be properly selected depending on the application; examples of the solvent include water; alcohols such as ethanol, methanol, n-propanol, isopropanol, n-butanol, sec-butanol, n-hexanol; ketones such as acetone, methyl ethyl ketone, methylisobutylketone, cyclohexanone, and diisobutylketone; esters such as ethyl acetate, butyl acetate, n-amyl acetate, methyl sulfate, ethyl propionate, dimethyl phthalate, ethyl benzoate, and methoxy propyl acetate; aromatic hydrocarbons such as toluene, xylene, benzene, and ethyl benzene; halogenated hydrocarbons such as carbon tetrachloride, trichloroethylene, chloroform, 1,1,1-trichloroetahne, methylene chloride, and monochloro benzene; ethers such as tetrahydrofuran, diethylene ether, ethyleneglycol monomethyl ether, ethyleneglycol monoethyl ether, and 1-methoxy-2-propanol; dimethyl formamide, dimethyl acetamide, dimethyl sulfoxide, and sulforane. These may be used alone or in combination. Further, a conventional surfactant may be added to the solvent.

The solution of photosensitive resin composition is coated on a support and dried to form a photosensitive layer, thus a pattern forming material may be produced.

The method for coating the solution of photosensitive resin composition may be properly selected depending on the application; examples of the coating method include spraying method, roll coating method, rotary coating method, slit coating method, extrusion coating method, curtain coating method, die coating method, gravure coating method, wire bar coating method, and knife coating method.

The drying conditions at the coating methods depend on the various components, species of solvent, and the solvent amount in general; usually, the temperature is 60 to 110° C. and the period is 30 seconds to 15 minutes.

The pattern forming materials according to the present invention can suppress the sensitivity drop of the photosensitive layer, therefore, can be exposed at less energy quantity and can represent advantageously higher processing rate due to the consequent higher exposing rate.

The pattern forming materials according to the present invention can suppress the sensitivity drop and produce highly fine and precise patterns, therefore, can be widely applied to produce various patterns, to form permanent patterns such as wiring patterns, to produce liquid crystal materials such as color filters, column materials, rib materials, spacers, partitions, and the like, and to produce holograms, micromachines, proofs, and the like; and further can be applied for pattern forming processes and pattern forming apparatuses according to the present invention.

### (Pattern Forming Apparatus and Pattern Forming Process)

The pattern forming apparatus according to the present invention comprises the pattern forming material according to the present invention, a laser source, and a laser modulator.

The pattern forming process according to the present invention comprises an exposing step and properly selected other steps.

The pattern forming apparatuses according to the present invention will be apparent through the descriptions with respect to the pattern forming processes according to the present invention.

### [Exposing]

In the exposing step, the exposing is performed for the photosensitive layer in the pattern forming material according to the present invention described above. Preferably, the exposing is performed for a laminate that comprises the pattern forming material on a substrate.

The substrate may be properly selected from commercially available materials, which may be of nonuniform surface or of highly smooth surface. Preferably, the substrate is plate-like; specifically, the substrate may be selected from the materials such as printed wiring boards e.g. copper-laminated plate, glass plates e.g. soda glass plate, synthetic resin films, paper, and metal plates.

The layer configuration may be properly selected depending on the application; for example, the substrate, the photosensitive layer, and the support is laminated in this order.

The method to produce the laminate may be properly selected depending on the application; preferably, the pattern forming material is laminated on the substrate under at least one of heating and pressuring. The heating temperature and the pressure may be properly selected depending on the application; preferably, the heating temperature is 15 to 180° C., more preferably is 60 to 140° C.; preferably, the pressure is 0.1 to 1.0 MPa, more preferably is 0.2 to 0.8 MPa.

The apparatus for the heating and the pressuring may be properly selected depending on the application; examples of the apparatuses include a laminator (e.g. VP-II, by Taisei-Laminator Co.), and a vacuum laminator.

The exposing may be properly performed by way of digital exposing, analog exposing, or the like; preferably, the exposing is performed by way of digital exposing. The exposing condition may be properly selected depending on the application; preferably, the exposing is performed by generating control signals depending on pattern forming information, and using the laser modulated by the control signals.

Examples of the means or devices for digital exposing include a laser source for irradiating laser beam, laser modulator for modulating the laser beam depending on the pattern information to be formed, and the like.

### <Laser Modulator>

The laser modulator may be properly selected depending on the application as long as it comprises plural imaging portions. Preferable examples of the laser modulator include a spatial light modulator.

Specific examples of the spatial light modulator include a digital micromirror device (DMD), spatial light modulator of micro electro mechanical systems, PLZT element, and liquid crystal shatter; among them, the DMD is preferable.

Preferably, the laser modulator is equipped with a unit to generate pattern signals depending on pattern information so as to modulate laser beam based on the control signals from the unit to generate pattern signals.

The laser modulator will be specifically explained with reference to figures in the following.

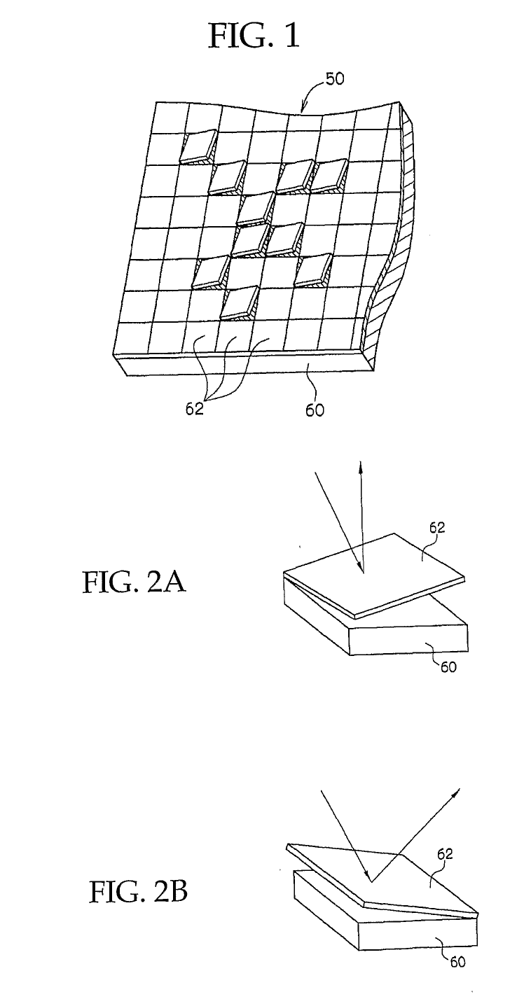

DMD 50 is a mirror device that has lattice arrays of many micromirrors 62, e.g. 1024×768, on SRAM cell or memory cell 60 as shown in FIG. 1, wherein each of the micromirrors performs as an imaging portion. At the upper most portion of the each imaging portion, micromirror 62 is supported by a pillar. A material having a higher reflectivity such as aluminum is vapor deposited on the surface of the micromirror. The reflectivity of the micromirrors 62 is 90% or more; the array pitches in longitudinal and width directions are respectively 13.7 μm, for example. Further, SRAM cell 60 of a silicon gate CMOS produced by conventional semiconductor memory producing processes is disposed just below each micromirror 62 through a pillar containing a hinge and yoke. The mirror device is entirely constructed as a monolithic body.

When a digital signal is written into SRAM cell 60 of DMD 50, micromirror 62 supported by a pillar is inclined toward the substrate, on which DMD 50 is disposed, within ±alpha degrees, e.g. 12 degrees, around the diagonal as the rotating axis. FIG. 2A indicates the condition that micromirror 62 is inclined +alpha degrees at on state, FIG. 2B indicates the condition that micromirror 62 is inclined −alpha degrees at off state. As such, each incident laser beam B on DMD 50 is reflected depending on each inclined direction of micromirrors 62 by controlling each inclined angle of micromirrors 62 in imaging portions of DMD 50 depending on pattern information as shown in FIG. 1.

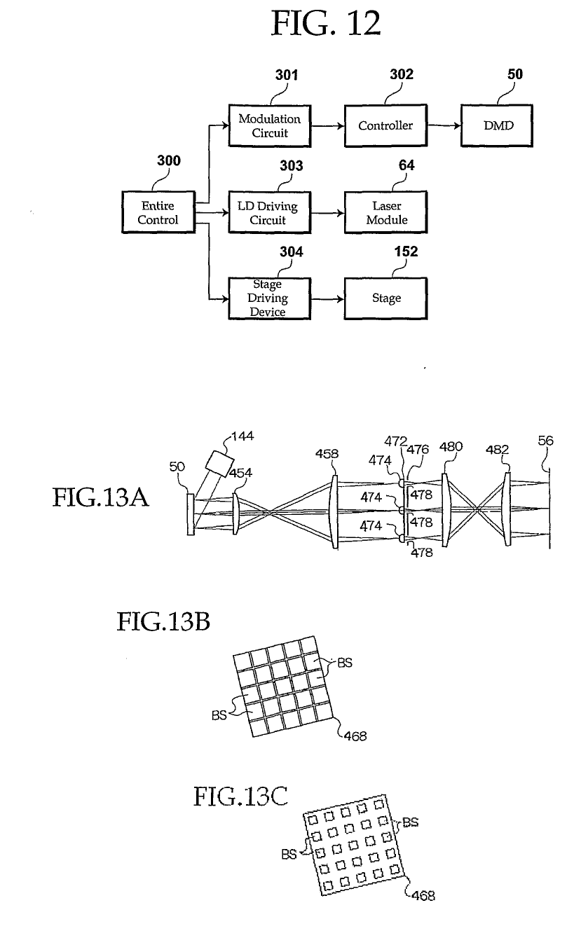

By the way, FIG. 1 exemplarily shows a magnified condition of DMD 50 partly in which micromirrors 62 are controlled at an angel of −alpha degrees or +alpha degrees. Controller 302, shown in FIG. 12, connected to DMD 50 carries out on-off controls of the respective micromirrors 62. An optical absorber (not shown) is disposed on the way of laser beam B reflected by micromirrors 62 at off state.

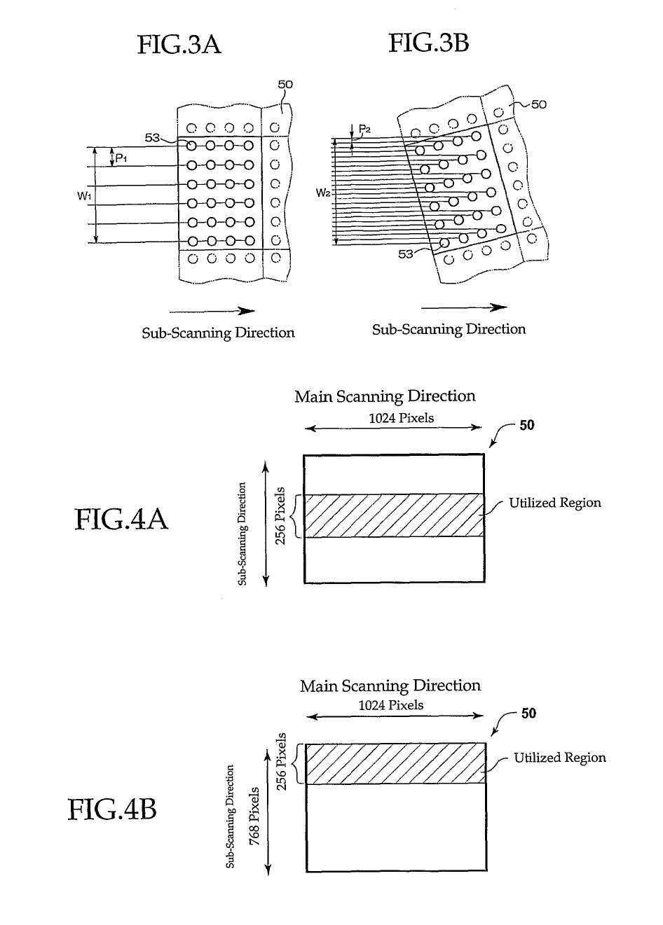

Preferably, DMD 50 is slightly inclined in the condition that the shorter side presents a pre-determined angle, e.g. 0.1 to 5 degrees, against the sub-scanning direction. FIG. 3A shows scanning traces of reflected laser image or exposing beam 53 by the respective micromirrors when DMD 50 is not inclined; FIG. 3B shows scanning traces of reflected laser image or exposing beam 53 by the respective micromirrors when DMD 50 is inclined.

In DMD 50, many micromirrors, e.g. 1024, are disposed in the longer direction to form one array, and many arrays, e.g. 756, are disposed in the shorter direction. Thus, by means of inclining DMD 50 as shown in FIG. 3B, the pitch P₁ of scanning traces or lines of exposing beam 53 from each micromirror may be more reduced than the pitch P₂ of scanning traces or lines of exposing beam 53 without inclining DMD 50, thereby the resolution may be improved remarkably. On the other hand, the inclined angle of DMD 50 is small, therefore, the scanning direction W₂ when DMD 50 is inclined and the scanning direction W₁ when DMD 50 is not inclined are approximately the same.

The process to accelerate the modulation rate of the laser modulator (hereinafter referring to as “high rate modulation”) will be explained in the following.

Preferably, the laser modulator is able to control any imaging portions of less than “n” disposed successively among the imaging portions depending on the pattern information (n: an integer of 2 or more). Since there exist a limit in the data processing rate of the laser modulator and the modulation rate per one line is defined with proportional to the utilized imaging portion number, the modulation rate per one line may be increased through only utilizing the imaging portions of less than “n” disposed successively.

The high rate modulation will be explained with reference to figures in the following.

When laser beam B is irradiated from fiber array laser source 66 to DMD 50, the reflected laser beam, at the micromirrors of DMD 50 on state, is imaged on pattern forming material 150 by lens systems 54, 58. As such, the laser beam irradiated from the fiber array laser source is turned into on or off by the respective imaging portions, and the pattern forming material 150 is exposed in approximately the same number of imaging portion units or exposing areas 168 as the imaging portions utilized in DMD 50. In addition, when pattern forming material 150 is conveyed with stage 152 at a constant rate, pattern forming material 150 is sub-scanned to the direction opposite to the stage moving direction by scanner 162, thus exposed regions 170 of band shape are formed correspondingly to the respective exposing heads 166.

In this example, micromirrors are disposed on DMD 50 as 1024 arrays in the main-scanning direction and 768 arrays in sub-scanning direction as shown in FIGS. 4A and 4B. Among these micromirrors, a part of micromirrors, e.g. 1024×256, may is be controlled and driven by controller 302 (see FIG. 12).

In such control, the micromirror arrays disposed at the central area of DMD 50 may be employed as shown in FIG. 4A; alternatively, the micromirror arrays disposed at the edge portion of DMD 50 may be employed as shown in FIG. 4B. In addition, when micromirrors are partly damaged, the utilized micromirrors may be properly altered depending on the situations such that micromirrors with no damage are utilized.

Since there exist a limit in the data processing rate of DMD 50 and the modulation rate per one line is defined with proportional to the utilized imaging portion number, partial utilization of micromirror arrays leads to higher modulation rate per one line. Further, when exposing is carried out by moving continuously the exposing head relative to the exposing surface, the entire imaging portions are not necessarily required in the sub-scanning direction.

When the sub-scanning of pattern forming material 150 is completed by scanner 162, and the rear end of pattern forming material 150 is detected by sensor 164, the stage 152 returns to the original site at the most upstream of gate 160 along guide 158, and the stage 152 is moved again from upstream to downstream of gate 160 along guide 158 at a constant rate.

For example, when 384 arrays are utilized among the 768 arrays of micromirrors, the modulation rate may be enhanced two times compared to utilizing all of 768 arrays; further, when 256 arrays are utilized among the 768 arrays of micromirrors, the modulation rate may be enhanced three times compared to utilizing all of 768 arrays

As explained above, when DMD 50 is provided with 1024 micromirror arrays in the main-scanning direction and 768 micromirror arrays in the sub-scanning direction, controlling and driving of partial micromirror arrays may lead to higher modulation rate per one line compared to controlling and driving of entire micromirror arrays.

In addition to the controlling and driving of partial micromirror arrays, elongated DMD on which many micromirrors are disposed on a substrate in planar arrays may increase similarly the modulation rate when the each angle of reflected surface is changeable depending on the various controlling signals, and the substrate is longer in a specific direction than its perpendicular direction.

Preferably, the exposing is performed while moving relatively the exposing laser and the thermosensitive layer; more preferably, the exposing is combined with the high rate modulation set forth before, thereby exposing may be carried out with higher rate in a shorter period.

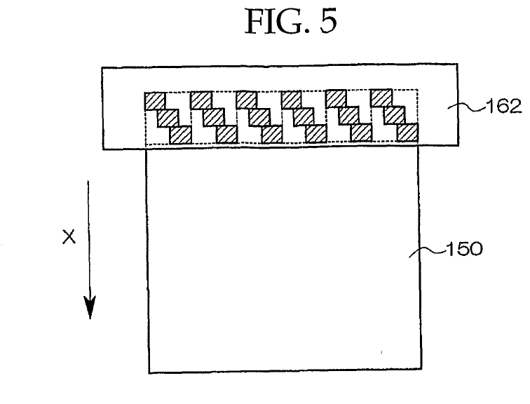

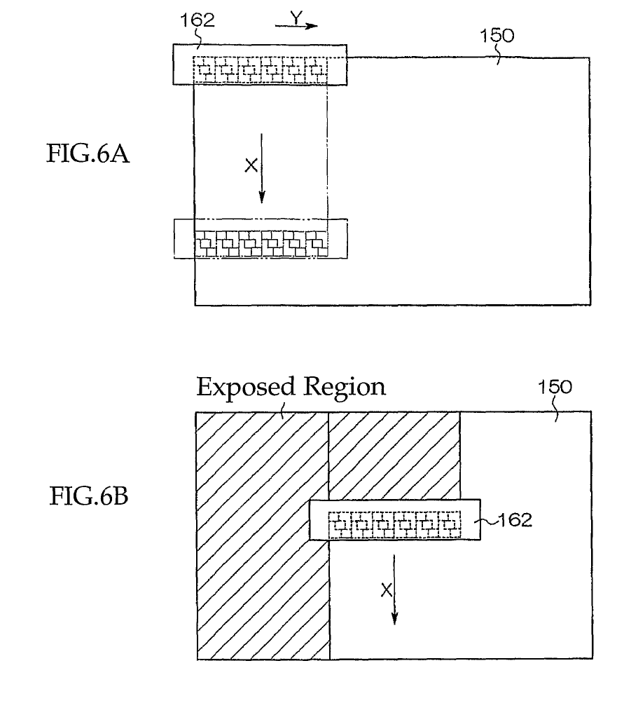

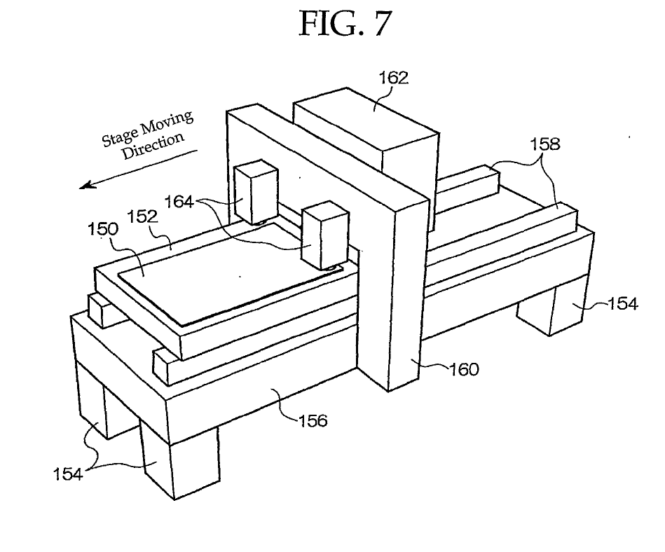

As shown in FIG. 5, pattern forming material 150 may be exposed on the entire surface by one scanning of scanner 162 in X direction; alternatively, as shown in FIGS. 6A and 6B, pattern forming material 150 may be exposed on the entire surface by repeated plural exposing such that pattern forming material 150 is scanned in X direction by scanner 162, then the scanner 162 is moved one step in Y direction, followed by scanning in X direction. In this example, scanner 162 comprises eighteen exposing heads 166; each exposing head comprises a laser source and the laser modulator.

The exposure is performed on a partial region of the photosensitive layer, thereby the partial region is hardened, followed by un-hardened region other than the partial hardened region is removed in developing step as set forth later, thus a pattern is formed.

A pattern forming apparatus comprising the laser modulator will be exemplarily explained with reference to figures in the following.

The pattern forming apparatus comprising the laser modulator is equipped with flat stage 152 that absorbs and sustains sheetlike pattern forming material 150 on the surface.

On the upper surface of thick plate table 156 supported by four legs 154, two guides 158 are disposed that extend along the stage moving direction. Stage 152 is disposed such that the elongated direction faces the stage moving direction, and supported by guide 158 in reciprocally movable manner. A driving device is equipped with the pattern forming apparatus (not shown) so as to drive stage 152 along guide 158.

At the middle of the table 156, gate 160 is provided such that the gate 160 strides the path of stage 152. The respective ends of gate 160 are fixed to both sides of table 156. Scanner 162 is provided at one side of gate 160, plural (e.g. two) detecting sensors 164 are provided at the opposite side of gate 160 in order to detect the front and rear ends of pattern forming material 150. Scanner 162 and detecting sensor 164 are mounted on gate 160 respectively, and disposed stationarily above the path of stage 152. Scanner 162 and detecting sensor 164 are connected to a controller (not shown) that controls them.

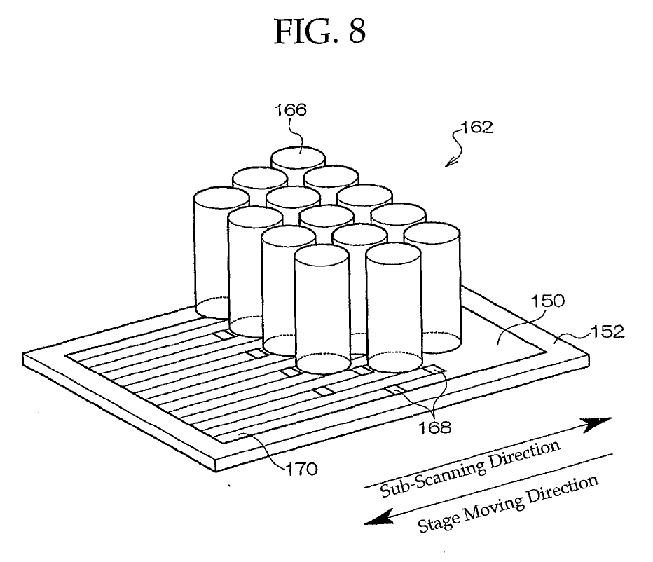

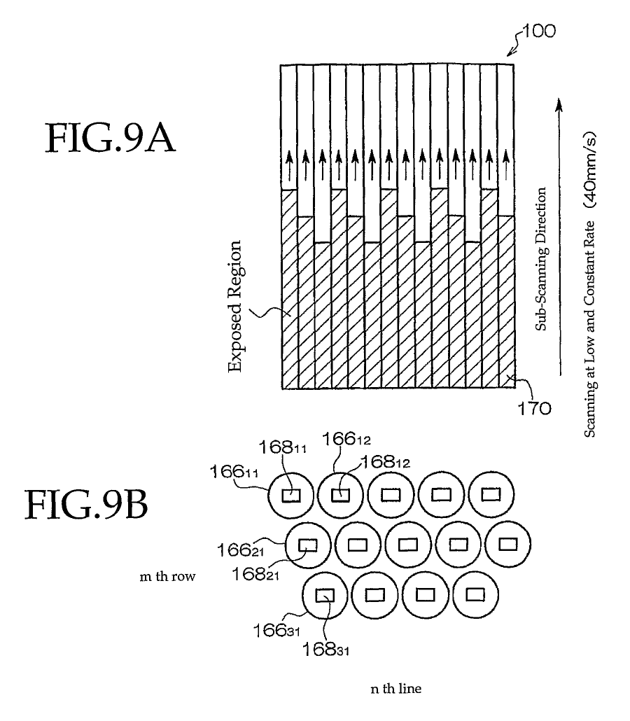

As shown in FIGS. 8 and 9B, scanner 162 comprises plural (e.g. fourteen) exposing heads 166 that are arrayed in substantially matrix of “m rows×n lines” (e.g. three×five). In this example, four exposing heads 166 are disposed at third line considering the width of pattern forming material 150. The specific exposing head at “m” th row and “n” th line is expressed as exposing head 166ₘₙ hereinafter.

The exposing area 168 formed by exposing head 166 is rectangular having the shorter side in the sub-scanning direction. Therefore, exposed areas 170 are formed on pattern forming material 150 of a band shape that corresponds to the respective exposing heads 166 along with the movement of stage 152. The specific exposing area corresponding to the exposing head at “m” th row and “n” th line is expressed as exposing area 168ₘₙ hereinafter.

As shown in FIGS. 9A and 9B, each of the exposing heads at each line is disposed with a space in the line direction so that exposed regions 170 of band shape are arranged without space in the perpendicular direction to the sub-scanning direction (space: (longer side of exposing area)×natural number; two times in this example). Therefore, the non-exposing area between exposing areas 168₁₁ and 168₁₂ at the first raw can be exposed by exposing area 168₂₁ of the second row and exposing area 168₃₁ of the third raw.

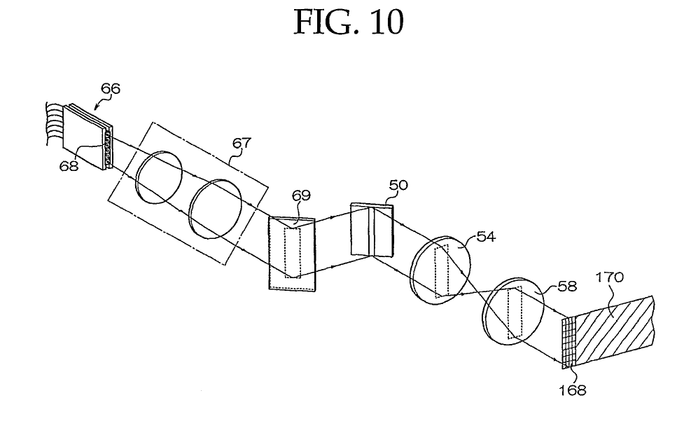

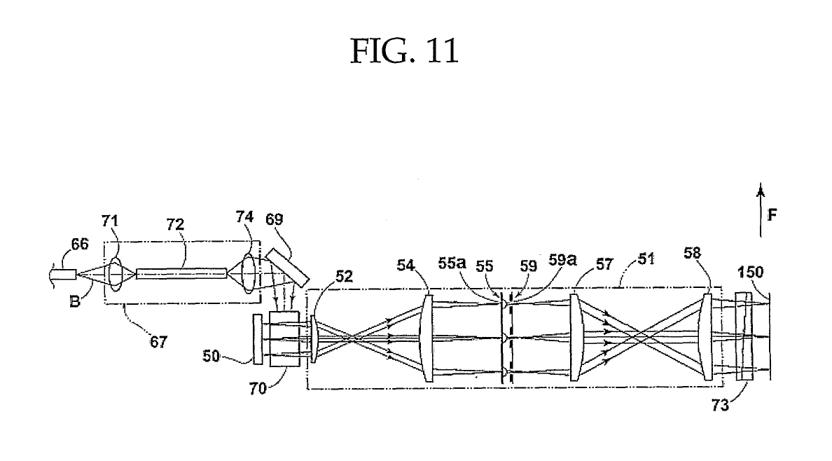

Each of exposing heads 166₁₁ to 166ₘₙ comprises a digital micromirror device (DMD) 50 (e.g., by US Texas Instruments Inc.) as a laser modulator or spatial light modulator that modulates the incident laser beam depending on the pattern information as shown in FIGS. 10 and 11. Each DMD 50 is connected to controller 302 that comprises a data processing part and a mirror controlling part as shown in FIG. 12. The data processing part of controller 302 generates controlling signals to control and drive the respective micromirrors in the areas to be controlled for the respective exposing heads 166, based on the input pattern information. The area to be controlled will be explained later. The mirror driving-controlling part controls the reflective surface angle of each micromirror of DMD 50 per each exposing head 166 based on the control signals generated at the pattern information processing part. The control of the reflective surface angle will be explained later.

At the incident laser side of DMD 50, fiber array laser source 66 that is equipped with a laser irradiating part where irradiating ends or emitting sites of optical fibers are arranged in an array along the direction corresponding with the longer side of exposing area 168, lens system 67 that compensates the laser beam from fiber array laser source 66 and collects it on the DMD, and mirrors 69 that reflect laser beam through lens system 67 toward DMD 50 are disposed in this order. FIG. 10 schematically shows lens system 67.

Lens system 67 is comprised of collective lens 71 that collects laser beam B for illumination from fiber array laser source 66, rod-like optical integrator 72 (hereinafter, referring to as “rod integrator”) inserted on the optical path of the laser passed through collective lens 71, and image lens 74 disposed in front of rod integrator 72 or the side of mirror 69, as shown FIG. 11. Collective lens 71, rod integrator 72, and image lens 74 make the laser beam irradiated from fiber array laser source 66 enter into DMD 50 as a luminous flux of approximately parallel beam with uniform intensity in the cross section. The shape and effect of the rod integrator will be explained in detail later.

Laser beam B irradiated from lens system 67 is reflected by mirror 69, and is irradiated to DMD 50 through a total internal reflection prism 70 (not shown in FIG. 10).

At the reflecting side of DMD 50, imaging system 51 is disposed that images laser beam B reflected by DMD 50 onto pattern forming material 150. The imaging system 51 is equipped with the first imaging system of lens systems 52, 54, the second imaging system of lens systems 57, 58, and microlens array 55 and aperture array 59 interposed between these imaging systems as shown in FIG. 11.

Arranging two-dimensionally many microlenses 55a each corresponding to the respective imaging portions of DMD 50 forms microlens array 55. In this example, micromirrors of 1024 rows×256 lines among 1024 rows×768 lines of DMD 50 are driven, therefore, 1024 rows×256 lines of microlenses are disposed correspondingly. The pitch of disposed microlenses 55a is 41 μm in both of raw and line directions. Microlenses 55a have a focal length of 0.19 mm and a numerical aperture (NA) of 0.11 for example, and are formed of optical glass BK7. The shape of microlenses will be explained later. The beam diameter of laser beam B is 41 μm at the site of microlens 55a.

Aperture array 59 is formed of many apertures 59a each corresponding to the respective microlenses 55a of microlens array 55. The diameter of aperture 59a is 10 μm, for example.

The first imaging system forms the image of DMD 50 on microlens array 55 as a three times magnified image. The second imaging system forms and projects the image through microlens array 55 on pattern forming material 150 as a 1.6 times magnified image. Therefore, the image by DMD 50 is formed and projected on pattern forming material 150 as a 4.8 times magnified image.

By the way, prism pair 73 is installed between the second imaging system and pattern forming material 150; through the operation to move up and down the prism pair 73, the image pint may be adjusted on the pattern forming material 150. In FIG. 11, pattern forming material 150 is fed to the direction of arrow F as sub-scanning.

The imaging portions may be properly selected depending on the application provided that the imaging portions can receive the laser beam from the laser source or irradiating means and can output the laser beam; for example, the imaging portions are pixels when the pattern formed by the pattern forming process according to the present invention is an image pattern, alternatively the imaging portions are micromirrors when the laser modulator contains a DMD.

The number of imaging portions contained in the laser modulator may be properly selected depending on the application.

The alignment of imaging portions in the laser modulator may be properly selected depending on the application; preferably, the imaging portions are arranged two dimensionally, more preferably are arranged into a lattice pattern.

### —Optical Irradiating Means or Laser Source—

The optical irradiating means or laser source may be properly selected depending on the application; examples thereof include an extremely high pressure mercury lamp, xenon lamp, carbon arc lamp, halogen lamp, fluorescent tube, LED, semiconductor laser, and the other conventional laser source, and also combination of these means. Among these means, the means capable of irradiating two or more types of lights or laser beams is preferable.

Examples of the light or laser irradiated from the optical irradiating means or laser source include UV-rays, visual light, X-ray, laser beam, and the like. Among these, laser beam is preferable, more preferably are those containing two or more types of laser beams (hereinafter, sometimes referring to as “combined laser”).

The wavelength of the UV-rays and the visual light is preferably 300 to 1500 nm, more preferably is 320 to 800 nm, most preferably is 330 to 650 nm.

The wavelength of the laser beam is preferably 200 to 1500 nm, more preferably is 300 to 800 nm, still more preferably is 330 to 500 nm, and most preferably is 400 to 450 nm.

As for the means to irradiate the combined laser beams, such a means is preferably exemplified that comprises plural laser irradiating devices, a multimode optical fiber, and a collecting optical system that collect respective laser beams and connect them to a multimode optical fiber.

The means to irradiate combined laser beams or the fiber array laser source will be explained with reference to figures in the following.

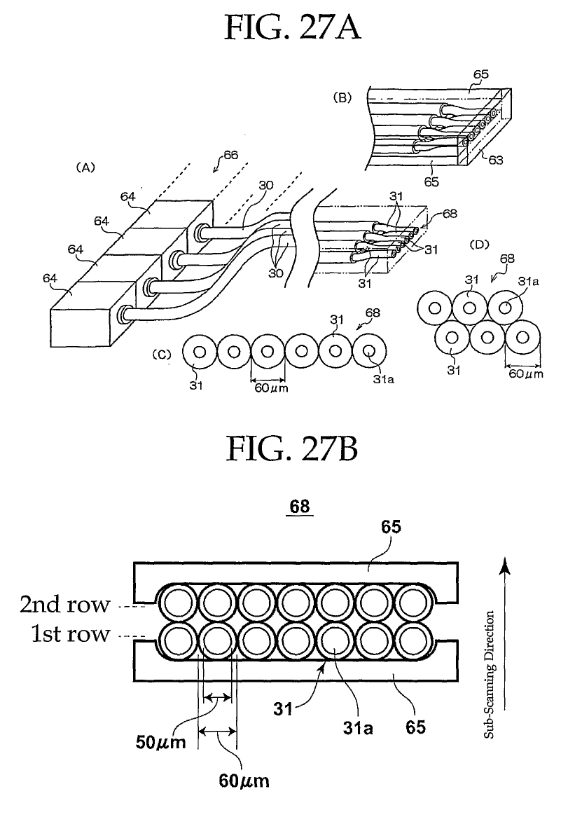

Fiber array laser source 66 is equipped with plural (e.g. fourteen) laser modules 64 as shown in FIG. 27A. One end of each multimode optical fiber 30 is connected to each laser module 64. To the other end of each multimode optical fiber 30 is connected optical fiber 31 of which the core diameter is the same as that of multimode optical fiber 30 and of which the clad diameter is smaller than that of multimode optical fiber 30. As shown in FIG. 27B specifically, the ends of multimode optical fibers 31 at the opposite end of multimode optical fiber 30 are aligned as seven ends along the main scanning direction perpendicular to the sub-scanning direction, and the seven ends are aligned as two rows, thereby laser output portion 68 is constructed.

The laser output portion 68, formed of the ends of multimode optical fibers 31, is fixed by being interposed between two flat support plates 65 as shown in FIG. 27B. Preferably, a transparent protective plate such as a glass plate is disposed on the output end surface of multimode optical fibers 31 in order to protect the output end surface. The output end surface of multimode optical fibers 31 tends to bear dust and to degrade due to its higher optical density; the protective plate set forth above may prevent the dust deposition on the end surface and may retard the degradation.

In this example, in order to align optical fibers 31 having a lower clad diameter into an array without a space, multimode optical fiber 30 is stacked between two multimode optical fibers 30 that contact at the larger clad diameter, and the output end of optical fiber 31 connected to the stacked multimode optical fiber 30 is interposed between two output ends of optical fibers 31 connected to two multimode optical fibers 30 that contact at the larger clad diameter.

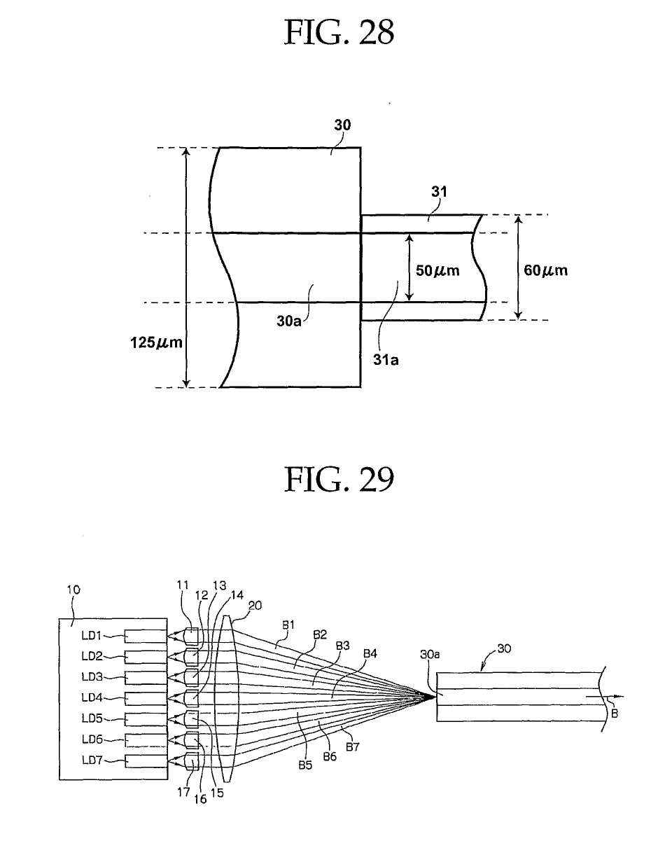

Such optical fibers may be produced by connecting concentrically optical fibers 31 having a length of 1 to 30 cm and a smaller clad diameter to the tip portions of laser beam output side of multimode optical fiber 30 having a larger clad diameter, for example, as shown in FIG. 28. Two optical fibers are connected such that the input end surface of optical fiber 31 is fused to the output end surface of multimode optical fiber 30 so as to coincide the center axes of the two optical fibers. The diameter of core 31a of optical fiber 31 is the same as the diameter of core 30a of multimode optical fiber 30 as set forth above.

Further, a shorter optical fiber produced by fusing an optical fiber having a smaller clad diameter to an optical fiber having a shorter length and a larger clad diameter may be connected to the output end of multimode optical fiber through a ferrule, optical connector, or the like. The connection through a connector and the like in an attachable and detachable manner may bring about easy exchange of the output end portion when the optical fibers having a smaller clad diameter are partially damaged for example, resulting advantageously in lower maintenance cost for the exposing head. Optical fiber 31 is sometimes referred to as “output end portion” of multimode optical fiber 30.

Multimode optical fiber 30 and optical fiber 31 may be any one of step index type optical fibers, grated index type optical fibers, and combined type optical fibers. For example, step index type optical fibers produced by Mitsubishi Cable Industries, Ltd. are available. In one of the best mode according to the present invention, multimode optical fiber 30 and optical fiber 31 are step index type optical fibers; in the multimode optical fiber 30, clad diameter=125 μm, core diameter=50 μm, NA=0.2, transmittance=99.5% or more (at coating on input end surface); and in the optical fiber 31, clad diameter=60 μm, core diameter=50 μm, NA=0.2.

Laser beams at infrared region typically increase the propagation loss while the clad diameter of optical fibers decreases. Accordingly, a proper clad diameter is defined usually depending on the wavelength region of the laser beam. However, the shorter is the wavelength, the less is the propagation loss; for example, in the laser beam of wavelength 405 nm irradiated from GaN semiconductor laser, even when the clad thickness (clad diameter−core diameter)÷2 is made into about ½ of the clad thickness at which infrared beam of wavelength 800 nm is typically propagated, or made into about ¼ of the clad thickness at which infrared beam of wavelength 1.5 μm for communication is typically propagated, the propagation loss does not increase significantly. Therefore, the clad diameter can be as small as 60 μm.

Needless to say, the clad diameter of optical fiber 31 should not be limited to 60 μm. The clad diameter of optical fiber utilized for conventional fiber array laser sources is 125 μm; the smaller is the clad diameter, the deeper is the focal depth; therefore, the clad diameter of the multimode optical fiber is preferably 80 μm or less, more preferably is 60 μm or less, still more preferably is 40 μm or less. On the other hand, since the core diameter is appropriately at least 3 to 4 μm, the clad diameter of optical fiber 31 is preferably 10 μm or more.

Laser module 64 is constructed from the combined laser source or the fiber array laser source as shown in FIG. 29. The combined laser source is constructed from plural (e.g. seven) multimode or single mode GaN semiconductor lasers LD1, LD2, LD3, LD4, LD5, LD6 and LD7 disposed and fixed on heat block 10, collimator lenses 11, 12, 13, 14, 15, 16, and 17, one collecting lens 20, and one multimode optical fiber 30. Needless to say, the number of semiconductor lasers is not limited to seven. For example, with respect to the multimode optical fiber having clad diameter=60 μm, core diameter=50 μm, NA=0.2, as much as twenty semiconductor lasers may be inputted, thus the number of optical fibers may be reduced while attaining the necessary optical quantity of the exposing head.

GaN semiconductor lasers LD1 to LD7 have a common oscillating wavelength e.g. 405 nm, and a common maximum output e.g. 100 mW as for multimode lasers and 30 mW as for single mode lasers. The GaN semiconductor lasers LD1 to LD7 may be those having an oscillating wavelength of other than 405 nm as long as within the wavelength of 350 to 450 nm.

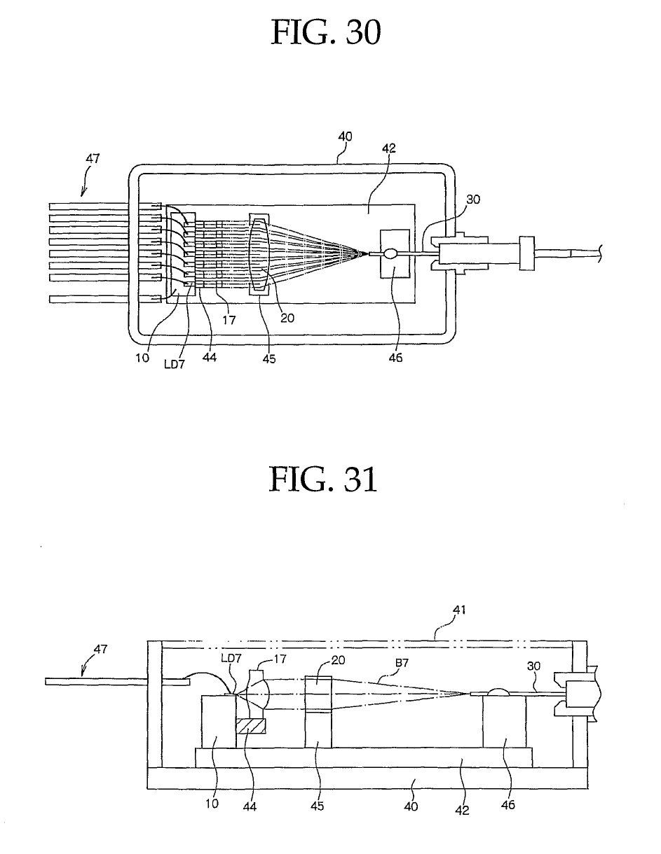

The combined laser source is housed into a box package 40 having an upper opening with other optical elements as shown in FIGS. 30 and 31. The package 40 is equipped with package lid 41 for shutting the opening. Introduction of sealing gas after evacuating procedure and shutting the opening of package 40 by means of package lid 41 presents a closed space or sealed volume constructed by package 40 and package lid 41, and the combined laser source is disposed in a sealed condition.

Base plate 42 is fixed on the bottom of package 40; the heat block 10, collective lens holder 45 to support collective lens 20, and fiber holder 46 to support the input end of multimode optical fiber 30 are mounted to the upper surface of the base plate 42. The output end of multimode optical fiber 30 is drawn out of the package from the aperture provided at the wall of package 40.

Collimator lens holder 44 is attached to the side wall of heat block 10, and collimator lenses 11 to 17 are supported thereby. An aperture is provided at the side wall of package 40, and wiring 47 that supplies driving power to GaN semiconductor lasers LD1 to LD7 is directed through the aperture out of the package.

In FIG. 31, only the GaN semiconductor laser LD7 is indicated with a reference mark among plural GaN semiconductor laser, and only the collimator lens 17 is indicated with a reference number among plural collimators, in order not to make the figure excessively complicated.

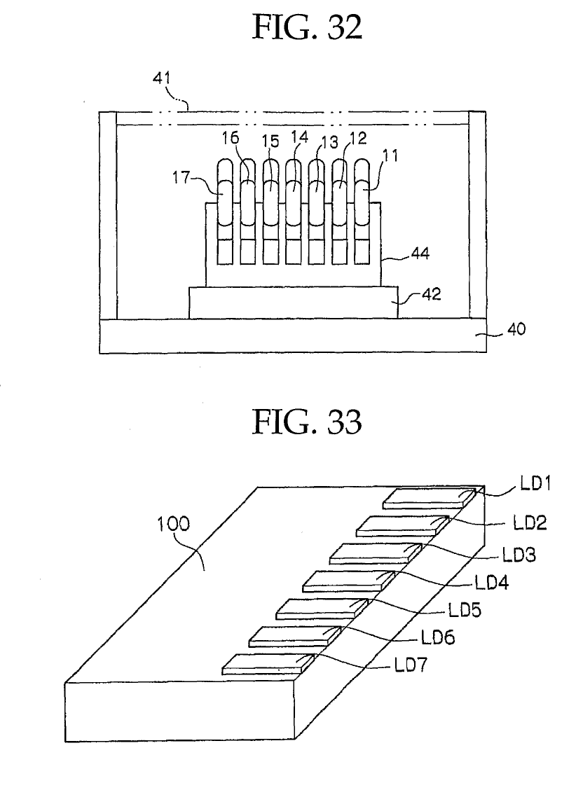

FIG. 32 shows a front shape of attaching part for collimator lenses 11 to 17. Each of collimator lenses 11 to 17 is formed into a shape that a circle lens containing a non-spherical surface is cut into an elongated piece with parallel planes at the region containing the optical axis. The collimator lens with the elongated shape may be produced by a molding process. The collimator lenses 11 to 17 are closely disposed in the aligning direction of emitting points such that the elongated direction is perpendicular to the alignment of the emitting points of GaN semiconductor lasers LD1 to LD7.

On the other hand, as for GaN semiconductor lasers LD1 to LD7, the following laser may be employed that comprises an active layer having an emitting width of 2 μm and emits the respective laser beams B1 to B7 at a condition that the divergence angle is 10 degrees and 30 degrees for the parallel and perpendicular directions against the active layer. The GaN semiconductor lasers LD1 to LD7 are disposed such that the emitting sites align as one line in parallel to the active layer.

Accordingly, laser beams B1 to B7 emitted from the respective emitting sites enter into the elongated collimator lenses 11 to 17 in a condition that the direction having a larger divergence angle coincides with the length direction of each collimator lens and the direction having a less divergence angle coincides with the width direction of each collimator lens. Namely, the width is 1.1 mm and the length is 4.6 mm with respect to respective collimator lenses 11 to 17, and the beam diameter is 0.9 mm in the horizontal direction and is 2.6 mm in the vertical direction with respect to laser beams B1 to B7 that enter into the collimator lenses. As for the respective collimator lenses 11 to 17, focal length f1=3 mm, NA=0.6, pitch of disposed lenses=1.25 mm.

Collective lens 20 formed into a shape that a part of circle lens containing the optical axis and non-spherical surface is cut into an elongated piece with parallel planes and is arranged such that the elongated piece is longer in the direction of disposing collimator lens 11 to 17 i.e. horizontal direction, and is shorter in the perpendicular direction. As for the collective lens, focal length f2=23 mm, NA=0.2. The collective lens 20 may be produced by molding a resin or optical glass, for example.

Further, since a high luminous fiber array laser source is employed that is arrayed at the output ends of optical fibers in the combined laser source for the illumination means to illuminate the DMD, a pattern forming apparatus may be attained that exhibits a higher output and a deeper focal depth. In addition, the higher output of the respective fiber array laser sources may lead to less number of fiber array laser sources required to take a necessary output as well as a lower cost of the pattern forming apparatus.

In addition, the clad diameter at the output ends of the optical fibers is smaller than the clad diameter at the input ends, therefore, the diameter at emitting sites is reduced still, resulting in higher luminance of the fiber array laser source. Consequently, pattern forming apparatuses with a deeper focal depth may be achieved. For example, a sufficient focal depth may be obtained even for the extremely high resolution exposure such that the beam diameter is 1 μm or less and the resolution is 0.1 μm or less, thereby enabling rapid and precise exposure. Accordingly, the pattern forming apparatus is appropriate for the exposure of thin film transistor (TFT) that requires high resolution.

The illumination means is not limited to the fiber array laser source that is equipped with plural combined laser sources; for example, such a fiber array laser source may be employed that is equipped with one fiber laser source, and the fiber laser source is constructed by one arrayed optical fiber that outputs a laser beam from one semiconductor laser having an emitting site.

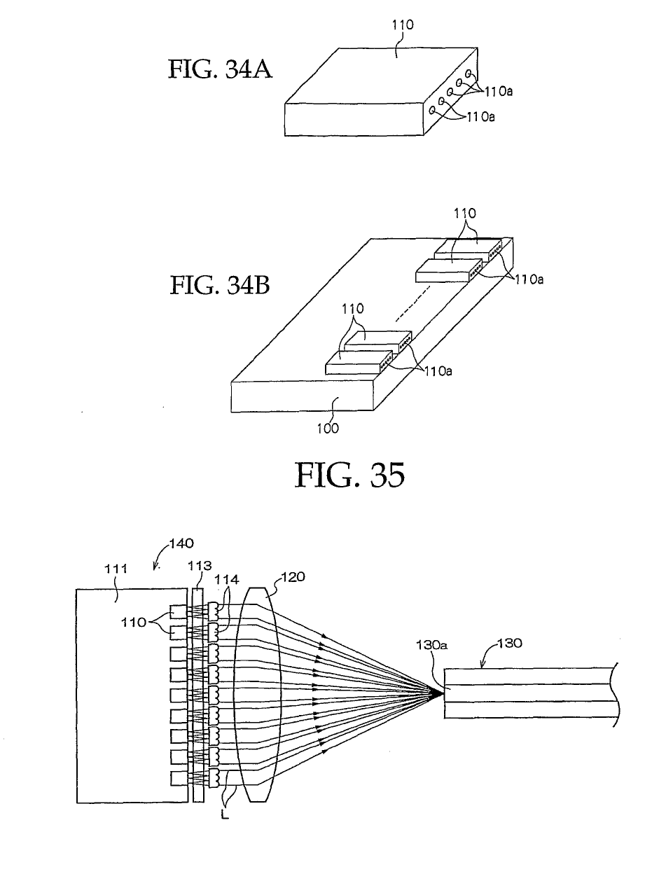

Further, as for the illumination means having plural emitting sites, such a laser array may be employed that comprises plural (e.g. seven) tip-like semiconductor lasers LD1 to LD7 disposed on heat block 100 as shown in FIG. 33. In addition, multi cavity laser 110 is known that comprises plural (e.g. five) emitting sites 110a disposed in a certain direction as shown in FIG. 34A. In the multi cavity laser 110, the emitting sites can be arrayed with higher dimensional accuracy compared to arraying tip-like semiconductor lasers, thus laser beams emitted from the respective emitting sites can be easily combined. Preferably, the number of emitting sites 110a is five or less, since deflection tends to generate on multi cavity laser 110 at the laser production process when the number increases.

Concerning the illumination means, the multi cavity laser 110 set forth above, or the multi cavity array disposed such that plural multi cavity lasers 110 are arrayed in the same direction as emitting sites 110a of each tip as shown in FIG. 34B may be employed for the laser source.

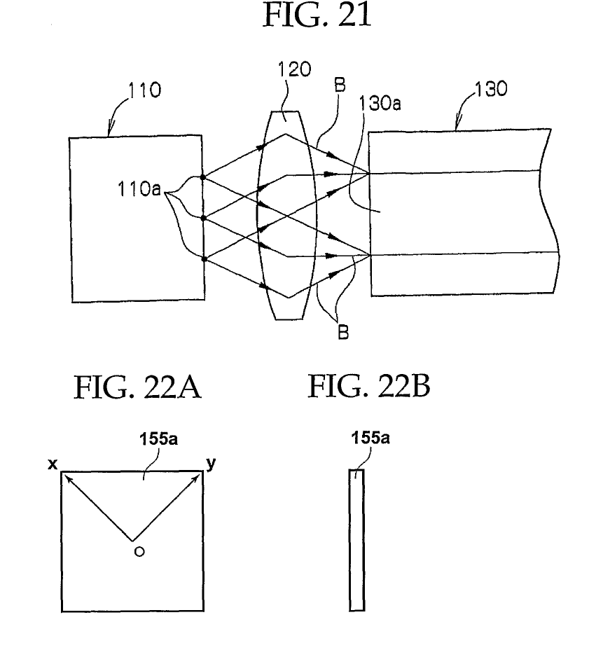

The combined laser source is not limited to the types that combine plural laser beams emitted from plural tip-like semiconductor lasers. For example, such a combined laser source is available that comprises tip-like multi cavity laser 110 having plural (e.g. three) emitting sites 110a as shown in FIG. 21. The combined laser source is equipped with multi cavity laser 110, one multimode optical fiber 130, and collecting lens 120. The multi cavity laser 110 may be constructed from GaN laser diodes having an oscillating wavelength of 405 nm, for example.

In the above noted construction, each laser beam B emitted from each of plural emitting sites 110a of multi cavity laser 110 is collected by collective lens 120 and enters into core 130a of multimode optical fiber 130. The laser beams entered into core 130a propagate inside the optical fiber and combine as one laser beam then output from the optical fiber.

The connection efficiency of laser beam B to multimode optical fiber 130 may be enhanced by way of arraying plural emitting sites 110a of multi cavity laser 110 into a width that is approximately the same as the core diameter of multimode optical fiber 130, and employing a convex lens having a focal length of approximately the same as the core diameter of multimode optical fiber 130, and also employing a rod lens that collimates the output beam from multi cavity laser 110 at only within the surface perpendicular to the active layer.

In addition, as shown in FIG. 35, a combined laser source may be employed that is equipped with laser array 140 formed by arraying on heat block 111 plural (e.g. nine) multi cavity lasers 110 with an identical space between them by employing multi cavity lasers 110 equipped with plural (e.g. three) emitting sites. The plural multi cavity lasers 110 are arrayed and fixed in the same direction as emitting sites 110a of the respective tips.

The combined laser source is equipped with laser array 140, plural lens arrays 114 that are disposed correspondingly to the respective multi cavity lasers 110, one rod lens 113 that is disposed between laser array 140 and plural lens arrays 114, one multimode optical fiber 130, and collective lens 120. Lens arrays 114 are equipped with plural micro lenses each corresponding to emitting sites of multi cavity lasers 110.

In the above noted construction, laser beams B that are emitted from plural emitting sites 110a of plural multi cavity lasers 110 are collected in a certain direction by rod lens 113, then are paralleled by the respective microlenses of microlens arrays 114. The paralleled laser beams L are collected by collective lens 120 and are inputted into core 130a of multimode optical fiber 130. The laser beams entered into core 130a propagate inside the optical fiber and combine as one beam then output from the optical fiber.

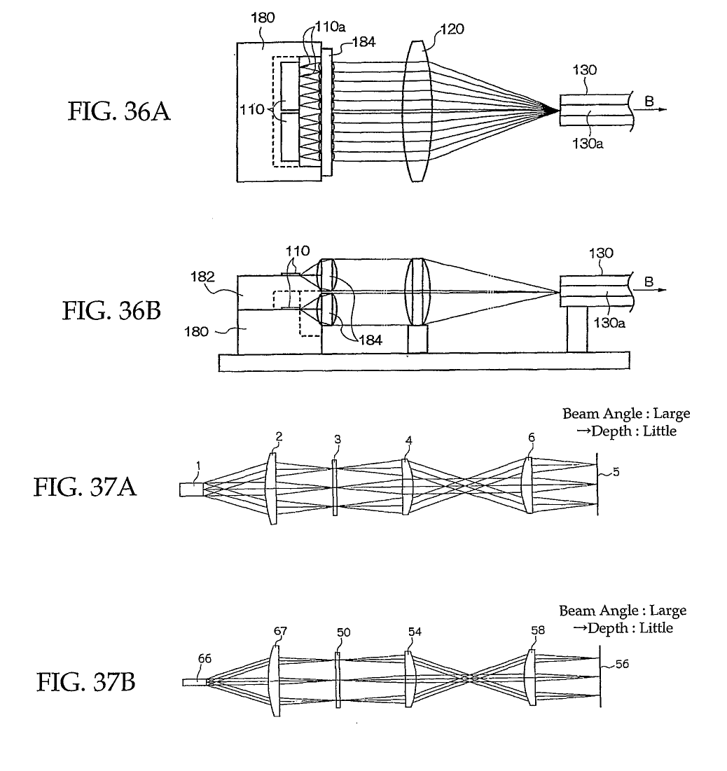

Another combined laser source will be exemplified in the following. In the combined laser source, heat block 182 having a cross section of L-shape in the optical axis direction is installed on rectangular heat block 180 as shown in FIGS. 36A and 36B, and a housing space is formed between the two heat blocks. On the upper surface of L-shape heat block 182, plural (e.g. two) multi cavity lasers 110, in which plural (e.g. five) emitting sites are arrayed, are disposed and fixed each with an identical space between them in the same direction as the aligning direction of respective tip-like emitting sites.

A concave portion is provided on the rectangular heat block 180; plural (e.g. two) multi cavity lasers 110 are disposed on the upper surface of heat block 180, plural emitting sites (e.g. five) are arrayed in each multi cavity laser 110, and the emitting sites are situated at the same vertical surface as the surface where are situated the emitting sites of the laser tip disposed on the heat block 182.

At the laser beam output side of multi cavity laser 110, collimate lens arrays 184 are disposed such that collimate lenses are arrayed correspondingly with the emitting sites 110a of the respective tips. In the collimate lens arrays 184, the length direction of each collimate lens coincides with the direction at which the laser beam represents wider divergence angle or the fast axis direction, and the width direction of each collimate lens coincides with the direction at which the laser beam represents less divergence angle or the slow axis direction. The integration by arraying the collimate lenses may increase the space efficiency of laser beam, thus the output power of the combined laser source may be enhanced, and also the number of parts may be reduced, resulting advantageously in lower production cost.

At the laser beam output side of collimate lens arrays 184, disposed are one multimode optical fiber 130 and collective lens 120 that collects laser beams at the input end of multimode optical fiber 130 and combines them.

In the above noted construction, the respective laser beams B emitted from the respective emitting sites 110a of plural multi cavity lasers 110 disposed on laser blocks 180, 182 are paralleled by collimate lens array, are collected by collective lens 120, then enter into core 130a of multimode optical fiber 130. The laser beams entered into core 130a propagate inside the optical fiber and combine as one beam then output from the optical fiber.

The combined laser source may be made into a higher output power source by multiple arrangement of the multi cavity lasers and the array of collimate lenses in particular. The combined laser source allows to construct a fiber array laser source and a bundle fiber laser source, thus is appropriate for the fiber laser source to construct the laser source of the pattern forming apparatus in the present invention.

By the way, a laser module may be constructed by housing the respective combined laser sources into a casing, and drawing out the output end of multimode optical fiber 130.

In the explanations set forth above, the higher luminance of fiber array laser source is exemplified that the output end of the multimode optical fiber of the combined laser source is connected to another optical fiber that has the same core diameter as that of the multimode optical fiber and a clad diameter smaller than that of the multimode optical fiber; alternatively a multimode optical fiber having a clad diameter of 125 μm, 80 μm, 60 μm or the like may be utilized without connecting another optical fiber at the output end, for example.

The pattern forming process according to the present invention will be explained further.

As shown in FIG. 29, in each exposing head 166 of scanner 162, the respective laser beams B1, B2, B3, B4, B5, B6, and B7, emitted from GaN semiconductor lasers LD1 to LD7 that constitute the combined laser source of fiber array laser source 66, are paralleled by the corresponding collimator lenses 11 to 17. The paralleled laser beams B1 to B7 are collected by collective lens 20, and converge at the input end surface of core 30a of multimode optical fiber 30.

In this example, the collective optical system is constructed from collimator lenses 11 to 17 and collective lens 20, and the combined optical system is constructed from the collective optical system and multimode optical fiber 30. Namely, laser beams B1 to B7 that are collected by collective lens 20 enter into core 30a of multimode optical fiber 30 and propagate inside the optical fiber, combine into one laser beam B, then output from optical fiber 31 that is connected at the output end of multimode optical fiber 30.

In each laser module, when the coupling efficiency of laser beams B1 to B7 with multimode optical fiber 30 is 0.85 and each output of GaN semiconductor lasers LD1 to LD7 is 30 mW, each optical fiber disposed in an array can take combined laser beam B of output 180 mW (=30 mW×0.85×7). Accordingly, the output is about 1 W (=180 mW×6) at laser emitting portion 68 of the array of six optical fibers 31.

Laser emitting portions 68 of fiber array source 66 are arrayed such that the higher luminous emitting sites are aligned along the main scanning direction. The conventional fiber laser source that connects laser beam from one semiconductor laser to one optical fiber is of lower output, therefore, a desirable output cannot be attained unless many lasers are arrayed; whereas the combined laser source of lower number (e.g. one) array can produce the desirable output since the combined laser source may generate a higher output.

For example, in the conventional fiber where one semiconductor laser and one optical fiber are connected, a semiconductor laser of about 30 mW output is usually employed, and a multimode optical fiber that has a core diameter of 50 μm, a clad diameter of 125 μm, and a numerical aperture of 0.2 is employed as the optical fiber. Therefore, in order to take an output of about 1 W (Watt), 48 (8×6) multimode optical fibers are necessary; since the area of emitting region is 0.62 mm² (0.675 mm×0.925 mm), the luminance at laser emitting portion 68 is 1.6×10⁶ (W/m²), and the luminance per one optical fiber is 3.2×10⁶ (W/m²).

On the contrary, when the laser emitting means is one capable of emitting the combined laser, six multimode optical fibers can produce the output of about 1 W. Since the area of the emitting region in laser emitting portion 68 is 0.0081 mm² (0.325 mm×0.025 mm), the luminance at laser emitting portion 68 is 123×10⁶ (W/m²), which corresponds to about 80 times the luminance of conventional means. The luminance per one optical fiber is 90×10⁶ (W/m²), which corresponds to about 28 times the luminance of conventional means.

The difference of focal depth between the conventional exposing head and the exposing head in the present invention will be explained with reference to FIGS. 37A and 37B. For example, the diameter of exposing head is 0.675 mm in the sub-scanning direction of the emitting region of the bundle-like fiber laser source, and the diameter of exposing head is 0.025 mm in the sub-scanning direction of the emitting region of the fiber array laser source. As shown in FIG. 37A, in the conventional exposing head, the emitting region of illuminating means or bundle-like fiber laser source 1 is larger, therefore, the angle of laser bundle that enters into DMD3 is larger, resulting in larger angle of laser bundle that enters into scanning surface 5. Therefore, the beam diameter tends to increase in the collecting direction, resulting in a deviation in focus direction.

On the other hand, as shown in FIG. 37B, the exposing head of the pattern forming apparatus in the present invention has a smaller diameter of the emitting region of fiber array laser source 66 in the sub-scanning direction, therefore, the angle of laser bundle is smaller that enters into DMD 50 through lens system 67, resulting in lower angle of laser bundle that enters into scanning surface 56, i.e. larger focal depth.

In this example, the diameter of the emitting region is about 30 times the diameter of prior art in the sub-scanning direction, thus the focal depth approximately corresponding to the limited diffraction may be obtained, which is appropriate for the exposing at extremely small spots. The effect on the focal depth is more significant as the optical quantity required at the exposing head comes to larger. In this example, the size of one imaging portion projected on the exposing surface is 10 μm×10 μm. The DMD is a spatial light modulator of reflected type; in FIGS. 37A and 3713, it is shown as developed views to explain the optical relation.

The pattern information corresponding to the exposing pattern is inputted into a controller (not shown) connected to DMD50, and is memorized once to a flame memory within the controller. The pattern information is the data that expresses the concentration of each imaging portion that constitutes the pixels by means of two-values i.e. presence or absence of the dot recording.

Stage 152 that absorbs pattern forming material 150 on the surface is conveyed from upstream to downstream of gate 160 along guide 158 at a constant velocity by a driving device (not shown). When the tip of pattern forming material 150 is detected by detecting sensor 164 installed at gate 160 while stage 152 passes under gate 160, the pattern information memorized at the flame memory is read plural lines by plural lines sequentially, and controlling signals are generated for each exposing head 166 based on the pattern information read by the data processing portion. Then, each micromirror of DMD 50 is subjected to on-off control for each exposing head 166 based on the generated controlling signals.

When a laser beam is irradiated from fiber array laser source 66 onto DMD 50, the laser beam reflected by the micromirror of DMD 50 at on-condition is imaged on exposed surface 56 of pattern forming material 150 by means of lens systems 54, 58. As such, the laser beams emitted from fiber array laser source 66 are subjected to on-off control for each imaging portion, and pattern forming material 150 is exposed by imaging portions or exposing area 168 of which the number is approximately the same as that of imaging portions employed in DMD50. Further, through moving the pattern forming material 150 at a constant velocity along with stage 152, pattern forming material 150 is subjected to sub-scanning in the direction opposite to the stage moving direction by means of scanner 162, and band-like exposed region 170 is formed for each exposing head 166.

### <Microlens Array>

Preferably, the exposing is carried out by the laser beam that is modulated and then transmitted through a microlens array and also an optional aperture array, imaging optical system, and the like.

As for the microlens array, the representative examples are an array of plural microlenses each having a non-spherical surface capable of compensating the aberration due to distortion of the output surface of the imaging portions, and an array of plural microlenses each having an aperture configuration capable of substantially shielding incident light other than the modulated laser beam from the laser modulator.

The non-spherical surface may be properly selected depending on the application; preferably, the non-spherical surface is toric surface, for example.

The microlens array, aperture array, imaging system set forth above will be explained with reference to figures.

FIG. 13A shows an exposing head that is equipped with DMD 50, laser source 144 to irradiate laser beam onto DMD 50, lens systems or imaging optical systems 454 and 458 that magnify and image the laser beam reflected by DMD 50, microlens array 472 that arranges many microlenses 474 corresponding to the respective imaging portions of DMD 50, aperture array that aligns many apertures 478 corresponding to the respective microlenses of microlens array 472, and lens systems or imaging systems 480 and 482 that image laser beam through the apertures onto exposed surface 56.

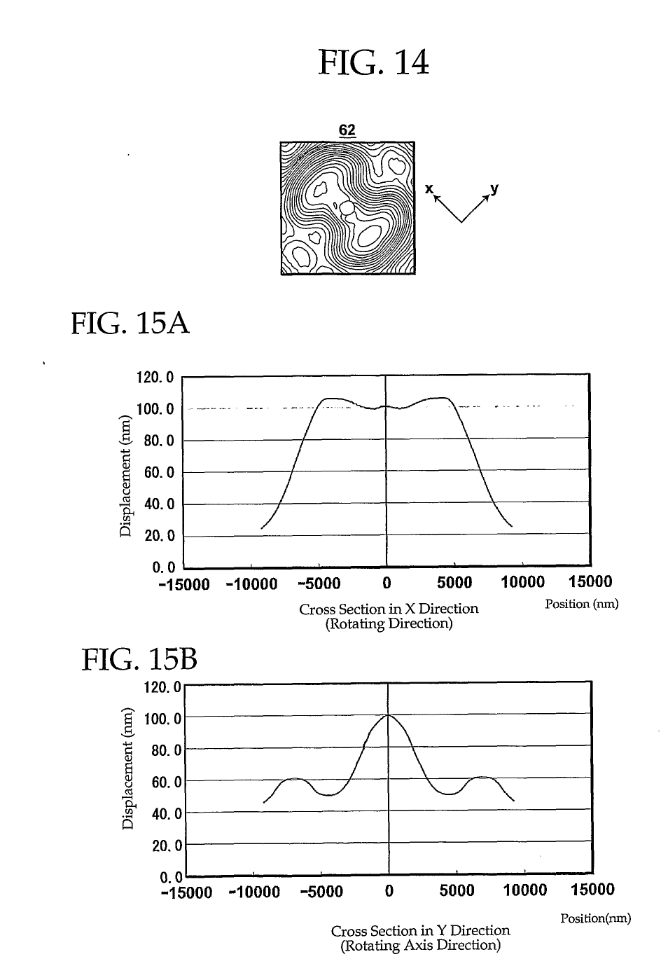

FIG. 14 shows the flatness data as to the reflective surface of micromirrors 62 of DMD 50. In FIG. 14, contour lines express the respective same heights of the reflective surface; the pitch of the contour lines is five nano meters. In FIG. 14, X direction and Y direction are two diagonal directions of micromirror 62, the micromirror 62 rotates around the rotation axis extending in Y direction. FIGS. 15A and 15B show the height displacements of micromirrors 62 along the X and Y directions respectively.

As shown in FIGS. 14, 15A and 15B, there exist strains on the reflective surface of micromirror 62, the strains of one diagonal direction (Y direction) is larger than another diagonal direction (X direction) at the central region of the mirror in particular. Accordingly, a problem may be induced that the shape is distorted at the site that collects laser beam B by microlenses 55a of microlens array 55.

In order to prevent such a problem, microlenses 55a of microlens array 55 are of special shape that is different from the prior art as explained later.

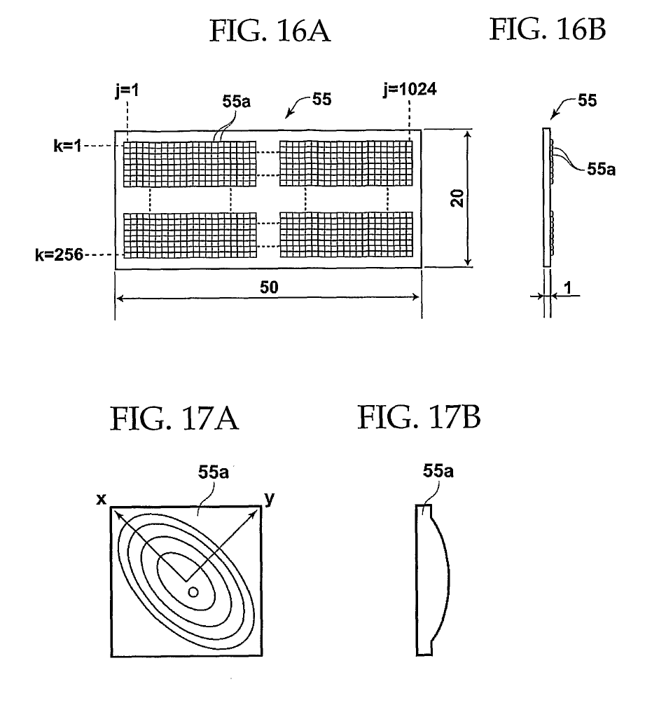

FIGS. 16A and 16B show the front shape and side shape of the entire microlens array 55 in detail. In FIGS. 16A and 16B, various parts of the microlens array are indicated as the unit of mm (millimeter). In the pattern forming process according to the present invention, micromirrors of 1024 rows×256 lines of DMD 50 are driven as explained above; microlens arrays 55 are correspondingly constructed as 1024 arrays in length direction and 256 arrays in width direction. In FIG. 16A, the site of each microlens is expressed as “j” th line and “k” th row.

FIGS. 17A and 17B show respectively the front shape and side shape of one microlens 55a of microlens array 55. FIG. 17A shows also the contour lines of microlens 55a. The end surface of each microlens 55a of irradiating side is of non-spherical shape to compensate the strain aberration of reflective surface of micromirrors 62. Specifically, microlens 55a is a toric lens; the curvature radius of optical X direction Rx is −0.125 mm, and the curvature radius of optical Y direction Ry is −0.1 mm.

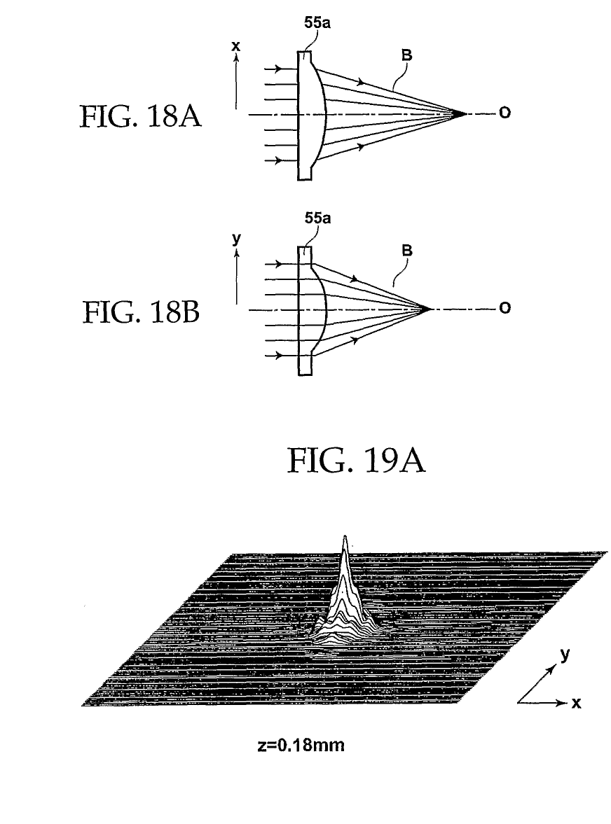

Accordingly, the collecting condition of laser beam B within the cross section parallel to the X and Y directions are approximately as shown in FIGS. 18A and 18B respectively. Namely, comparing the X and Y directions, the curvature radius of microlens 55a is shorter and the focal length is also shorter in Y direction.

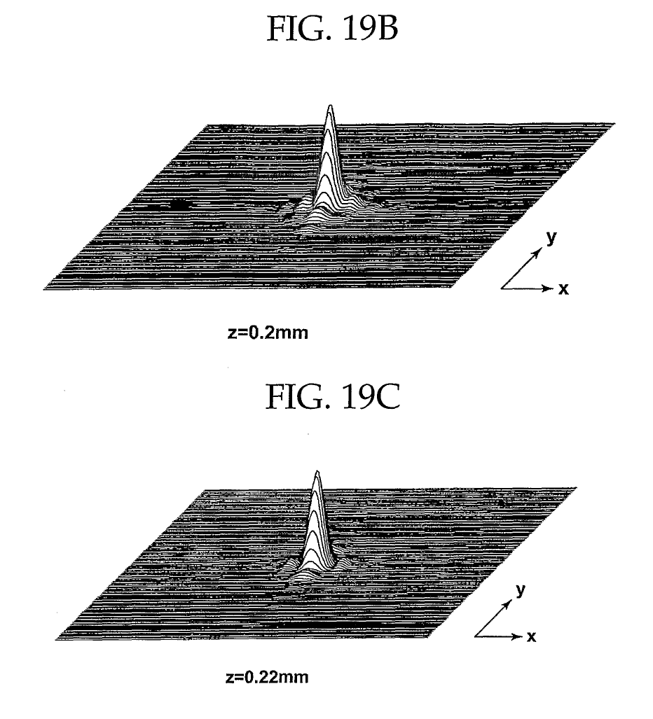

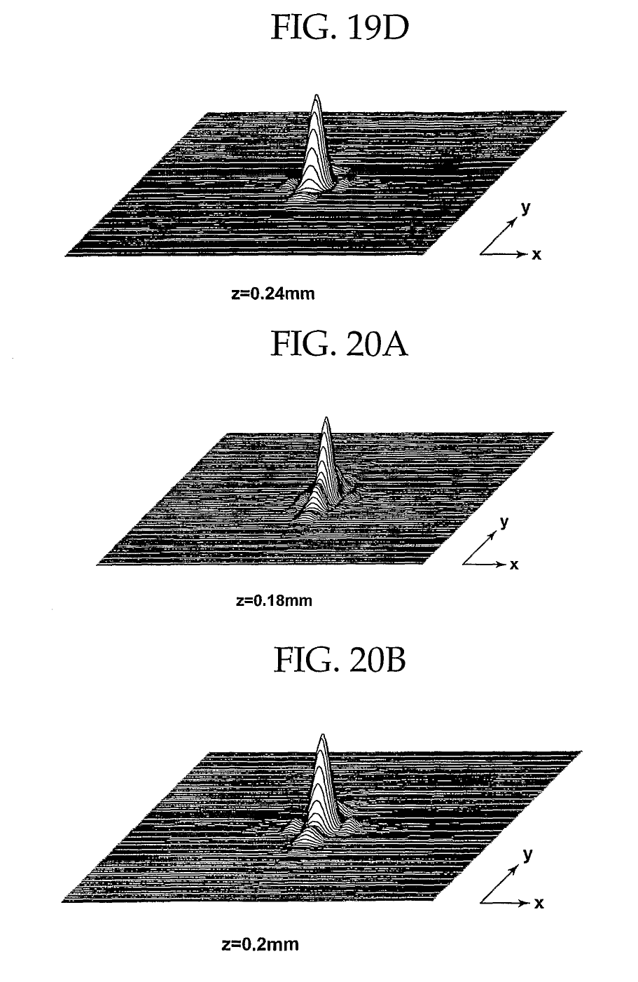

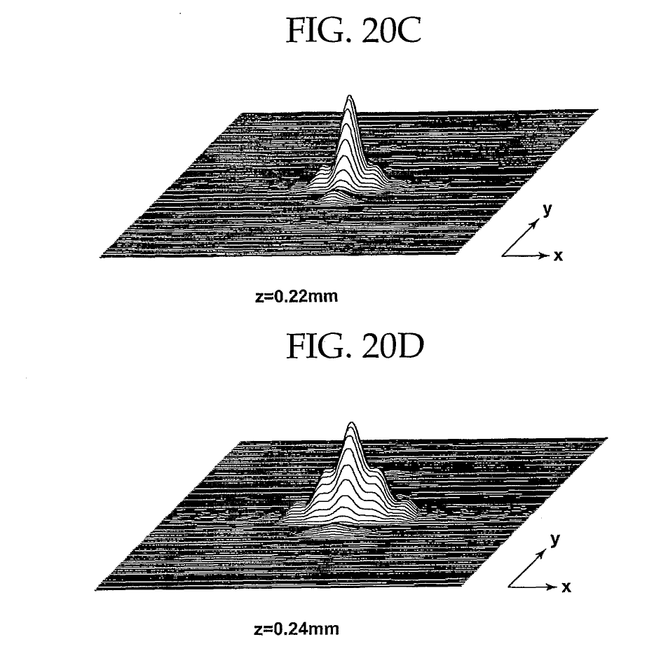

FIGS. 19A, 19B, 19C, and 19D show the simulations of beam diameter near the focal point of microlens 55a in the above noted shape by means of a computer. For the reference, FIGS. 20A, 20B, 20C, and 20D show the similar simulations for microlens of Rx=Ry=−0.1 mm. The values of “z” in the figures are expressed as the evaluation sites in the focus direction of microlens 55a by the distance from the beam irradiating surface of microlens 55a.

The surface shape of microlens 55a in the simulation may be calculated by the following equation (1).

$$Z = \frac{{C}_{x}^{2} {X}^{2} + {C}_{y}^{2} {Y}^{2}}{1 + SQRT ( 1 - {C}_{x}^{2} {X}^{2} - {C}_{y}^{2} {Y}^{2} )}$$

In the above equation, Cx means the curvature (=1/Rx) in X direction, Cy means the curvature (=1/Ry) in Y direction, X means the distance from optical axis in X direction, and Y means the distance from optical axis O in Y direction.

From the comparison of FIGS. 19A to 19D, and FIGS. 20A to 20D, it is apparent in the pattern forming process according to the present invention that the employment of the toric lens as the microlens 55a that has a shorter focal length in the cross section parallel to Y direction than the focal length in the cross section parallel to X direction may reduce the strain of the beam shape near the collecting site. Accordingly, images can be exposed on pattern forming material 150 with more clearness and without strain. In addition, it is apparent that the inventive mode shown in FIGS. 19A to 19D may bring about a wider region with smaller beam diameter, i.e. longer focal depth.

By the way, when the larger or smaller strain at the central region appears at the central region of micromirror 62 inversely with those set forth above, the employment of microlenses that has a shorter focal length in the cross section parallel to X direction than the focal length in the cross section parallel to Y direction may make possible to expose images on pattern forming material 150 with more clearness and without strain or distortion.

Aperture arrays 59 disposed near the collecting site of microlens array 55 are constructed such that each aperture 59a receives only the laser beam through the corresponding microlens 55a. Namely, aperture array 59 may afford the respective apertures with the insurance that the light incidence from the adjacent apertures 55a may be prevented and the extinction ratio may be enhanced.

Essentially, smaller diameter of apertures 59a provided for the above noted purpose may afford the effect to reduce the strain of beam shape at the collecting site of microlens 55a. However, such a construction inevitably increases the optical quantity interrupted by the aperture array 59, resulting in lower efficiency of optical quantity. On the contrary, the non-spherical shape of microlenses 55a does not bring about the light interruption, thus leading to maintain the higher efficiency of optical quantity.

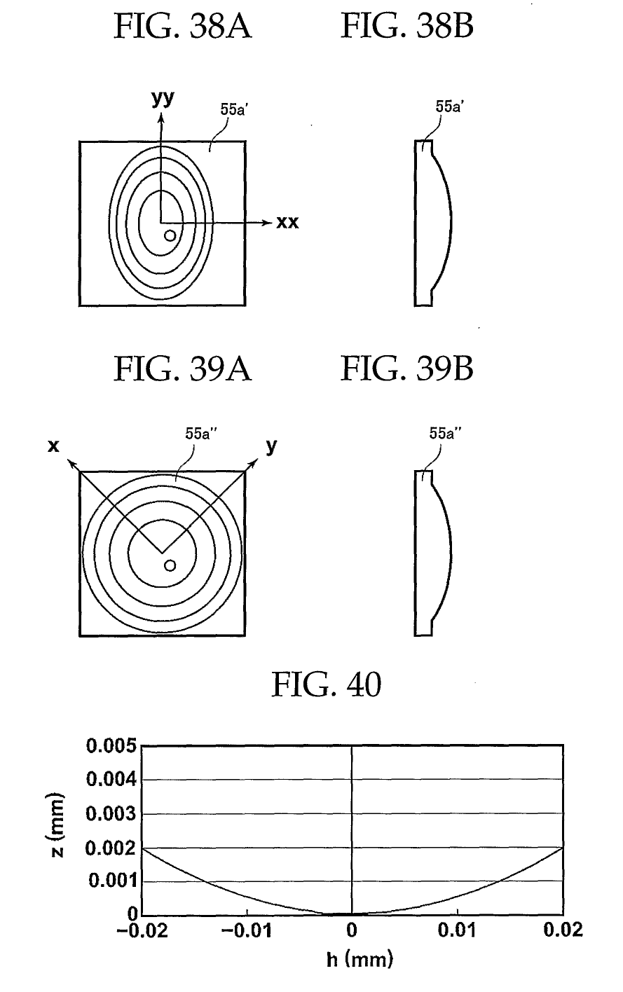

In the pattern forming process explained above, microlens 55a of toric lens is applied that has different curvature radiuses in X and Y directions that respectively correspond to two diagonal directions of micromirror 62; alternatively, another microlens 55a′ of toric lens may be applied that has different curvature radiuses in XX and YY directions that respectively correspond to two side directions of rectangular micromirror 62, as shown in FIGS. 38A and 38B that exhibit the front and side shapes with contour lines.

In the pattern forming process according to the present invention, the microlenses 55a may be non-spherical shape of secondary or higher order such as fourth or sixth. The employment of higher order non-spherical surface may lead to higher accuracy of beam shape. In addition, such lens configuration is available that has the same curvature radiuses in X and Y directions corresponding to the distoration of reflective surface of micromirrors 62. Such lens configuration will be discussed in detail.

The microlens 55a″, of which the front shape and the side shape are shown in FIGS. 39A and 39B respectively, has the same curvature radiuses in X and Y directions, and the curvature radiuses are designed such that the curvature Cy of spherical lens is compensated depending on the distance ‘h’ from the lens center. Namely, the configuration of spherical lens of microlens 55a″ is designed in terms of lens height ‘z’ (height of curved lens surface in optical axis direction) based on the following equation (2), for example.

$$Z = \frac{{C}_{y} {h}^{2}}{1 + SQRT ( 1 - {C}_{y}^{2} {h}^{2} )}$$

The relation between the lens height ‘z’ and the distance ‘h’ is expressed in FIG. 40 in the case that the curvature Cy=1/0.1 mm.

Then, the curvature radius of the spherical lens is compensated depending on the distance ‘h’ from the lens center based on the following equation (3), thereby the lens configuration of microlens 55a″ is designed.

$$Z = \frac{{C}_{y}^{2} {h}^{2}}{1 + SQRT ( 1 - {C}_{y}^{2} {h}^{2} )} + {ah}^{4} + {bh}^{6}$$

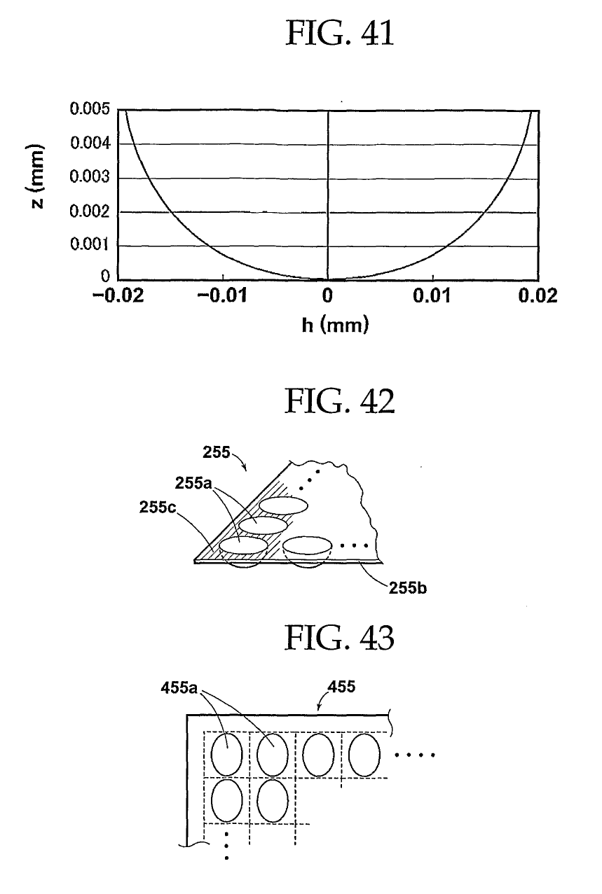

In equations (2) and (3), the respective Z mean the same concept; in equation (3), the curvature Cy is compensated using the fourth coefficient ‘a’ and sixth coefficient ‘b’. The relation between the lens height ‘z’ and the distance ‘h’ is expressed in FIG. 41 in the case that the curvature Cy=1/0.1 mm, the fourth coefficient ‘a’=1.2×10³, and the sixth coefficient ‘b’=5.5×10⁷.

In the mode set forth above, the end surface of irradiating side of microlens 55a is non-spherical or toric; alternatively, substantially the same effect may be derived by constructing one of the end surface as a spherical surface and the other surface as cylindrical surface and thus providing the microlens.

Further, in the mode set forth above, each microlens 55a of microlens array 55 is non-spherical so as to compensate the aberration due to the strain of reflective surface of micromirror 62; alternatively, substantially the same effect may be derived by providing each microlens of the microlens array with the distribution of refractive index so as to compensate the aberration due to the strain of reflective surface of micromirror 62.

FIGS. 22A and 22B show exemplarily such a microlens 155a. FIGS. 22A and 22B respectively show the front shape and side shape of microlens 155a. The entire shape of microlens 155a is a planar plate as shown in FIGS. 22A and 22B. The X and Y directions in FIGS. 22A and 22B mean the same as set forth above.

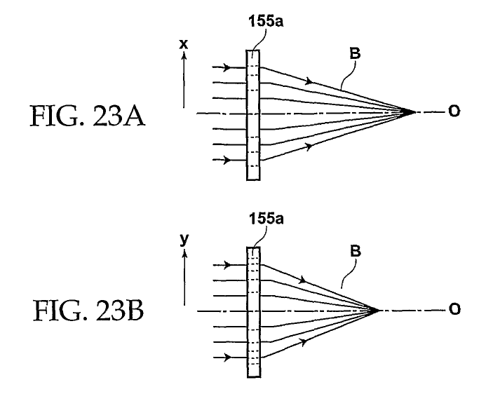

FIGS. 23A and 23B schematically show the condition to collect laser beam B by microlens 155a in the cross section parallel with X and Y directions respectively. The microlens 155a exhibits a refractive index distribution that the refractive index increases gradually from the optical axis O to outward direction; the broken lines in FIGS. 23A and 23B indicate the positions where the refractive index decreases a certain level from that of optical axis O. As shown in FIGS. 23A and 23B, comparing the cross section parallel to the X direction and the cross section parallel to the Y direction, the latter represents a rapid change in the refractive index distribution, and shorter focal length. Thus, the microlens array having such a refractive index distribution may provide the similar effect as the microlens array 55 set forth above.

In addition, the microlens having a non-spherical surface as shown in FIGS. 17A, 17B, 18A and 18B may be provided with such a refractive index distribution, and both of the surface shape and the refractive index distribution may compensate the aberration due to strain or distortion of the reflective surface of micromirror 62.

Another microlens array will be exemplarily discussed with reference to figures.

The exemplary microlens array the microlens array has an aperture configuration of the plural microlenses capable of substantially shielding incident light other than the modulated laser beam from the laser modulator, as shown in FIG. 42.

As discussed before with reference to FIGS. 14 and 15A and 15B, distortions exist on the reflective surface of micromirror 62 in DMD 50, and the distortion level tends to gradually increase from the central portion toward the peripheral portions of micromirror 62. Further, the distortion level at the peripheral portions is larger in one diagonal direction e.g. Y direction of micromirror 62 compared to in the other diagonal direction e.g. X direction, and the tendency explained above is more significant in Y direction.

The exemplary microlens array is prepared to address such problems. Each of the microlens 255a of the microlens array 255 has a circular aperture configuration; therefore, the laser beam reflected or transmitted at the periphery portions of the micromirror 62 where the distortion level is relatively large, particularly the laser beam B reflected at the four corners cannot be collected by microlens 255a, thus the distortion of laser beam B may be prevented at the collecting site. Accordingly, highly fine and precise images may be exposed on pattern forming material with reducing distortions.

Additionally, in the microlens array 255 as shown in FIG. 42, shielding mask 255c is prepared at the back side of transparent members 255b, which are usually formed monolithically with microlenses 255a, that sustains microlenses 255a; namely shielding mask 255c is provided such that outer regions of plural microlens apertures are covered at the opposite side of the plural microlenses 255a as shown in FIG. 42. The shielding mask 255c can surely reduce the distortion of collected laser beam B, since the laser beam reflected or transmitted at the periphery portions of the micromirror 62, particularly the laser beam B reflected at the four corners is absorbed or interrupted by the shielding mask 255c.

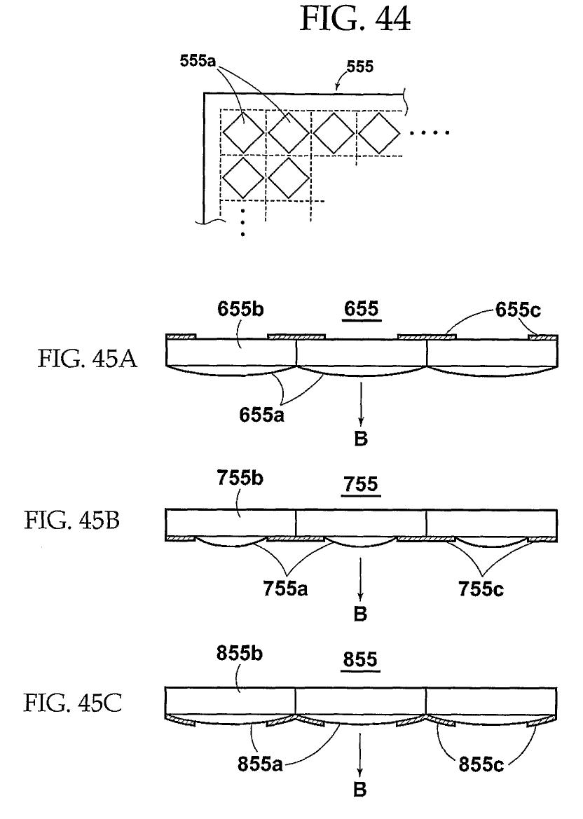

The aperture configuration of the microlens is not limited to circular in the microlens array 255, but other aperture configurations are applicable as microlens 455a with elliptic aperture configuration shown in FIG. 43, microlens 555a with polygonal aperture configuration e.g. rectangular in FIG. 44, and the like. By the way, microlenses 455a or 555a is of the configuration that symmetrical lens is cut into circular or polygonal shape, thus microlenses 455a or 555a may exhibit light-collecting performance similarly to conventional symmetrical spherical lenses.

Additionally, the aperture configurations shown in FIGS. 45A, 45B, and 45C are applicable in the present invention. Microlens array 655 shown in FIG. 45A is constructed such that plural microlenses 655a are disposed adjacently at the side of transparent member 655b from where laser beam B outputs, and mask 655c is disposed at the side of transparent member 655b to where laser beam inputs. By the way, mask 255c is provided at the outer region of the lens aperture in FIG. 42, whereas mask 655c is provided at the inner region of the lens aperture in FIG. 45A.

Microlens array 755 shown in FIG. 45B is constructed such that plural microlenses 755a are disposed adjacently at the side of transparent member 755b from where laser beam B outputs, and mask 755c is disposed between the microlenses 755a. Microlens array 855 shown in FIG. 45C is constructed such that plural microlenses 855a are disposed adjacently at the side of transparent member 855b from where laser beam B outputs, and mask 855c is disposed at the peripheral portion of each microlens 855a.

All of the exemplary masks 655c, 755c, and 855c have a circular aperture similarly to mask 255c, thereby the aperture of each microlens is defined to be circular.

The aperture configuration of plural microlenses, wherein the mask substantially shields incident light other than from micromirrors 62 of DMD 50 as shown in microlenses 255a, 455a, 555a, 655a, and 755a, may be combined with non-spherical lenses capable of compensating the aberration due to distortion of micromirror 62 as microlens 55a shown in FIGS. 17A and 17B, or lenses having a refractive index distribution capable of compensating the aberration as shown in FIGS. 22A and 22B; thereby the effect to prevent distortion of exposed images due to distortion of reflective surface of micromirror 62 may be enhanced synergistically.

Particularly, in the construction that mask 855c is provided on the lens surface of microlens 855a in microlens array 855 as shown in FIG. 45C, when microlens 855a have a non-spherical surface or a refractive index distribution and also the imaging site of the first imaging system is determined at the lens surface of microlens 855a as lens systems 52 and 54 shown in FIG. 11, the optical efficiency may be higher in particular, thus pattern forming material 150 may be exposed with more intense laser beam. Namely, although the laser beam refracts such that the stray light due to the reflective surface of micromirror 62 focuses at the imaging site by action of the first imaging system, mask 855c provided at appropriate site does not shield light other than the stray light, thereby the optical efficiency may be enhanced remarkably.

In the respective microlens array set forth above, the aberration due to strain of reflective surface of micromirror 62 in DMD 50 is compensated; similarly, in the pattern forming process according to the present invention that employs a spatial light modulator other than DMD, the possible aberration due to strain may be compensated and the strain of beam shape may be prevented when the strain appears at the surface of imaging portion of the spatial light modulator.

The imaging optical system set forth above will be explained in the following.

In the exposing head, when laser beam is irradiated from the laser source 144, the cross section of luminous flux reflected to one-direction by DMD 50 is magnified several times, e.g. two times, by lens systems 454, 458. The magnified laser beam is collected by each microlens of microlens array 472 correspondingly with each imaging portion of DMD 50, then passes through the corresponding apertures of aperture array 476. The laser beam passed through the aperture is imaged on exposed surface 56 by lens systems 480, 482.

In the imaging optical system, the laser beam reflected by DMD 50 is magnified into several times by magnifying lenses 454, 458, and is projected onto exposed surface 56, therefore, the entire image region is enlarged. When microlens array 472 and aperture array 476 are not disposed, one drawing size or spot size of each beam spot BS projected on exposed surface 56 is enlarged depending on the size of exposed area 468, thus MTF (modulation transfer function) property that is a measure of sharpness at exposing area 468 is decreased, as shown in FIG. 13B.

On the other hand, when microlens array 472 and aperture array 476 are disposed, the laser beam reflected by DMD 50 is collected correspondingly with each imaging portion of DMD 50 by each microlens of microlens array 472. Thereby, the spot size of each beam spot BS may be reduced into the desired size, e.g. 10 μm×10 μm, even when the exposing area is magnified, as shown in FIG. 13C, and the decrease of MTF property may be prevented and the exposure may be carried out with higher accuracy. By the way, inclination of exposing area 468 is caused by the DMD 50 that is disposed with inclination in order to eliminate the spaces between imaging portions.

Further, even when beam thickening exists due to aberration of microlenses, the beam shape may be arranged by the aperture array so as to form spots on exposed surface 56 with a constant size, and the crosstalk between the adjacent imaging portions may be prevented by passing the beam through the aperture array provided correspondingly to each imaging portion.

In addition, employment of higher luminance laser source as laser source 144 may lead to prevention of partial entrance of luminous flux from adjacent imaging portions, since the angle of incident luminous flux is narrowed that enters into each microlens of microlens array 472 from lens 458; namely, higher extinction ratio may be achieved.

### —Other Optical System—

In the pattern forming process according to the present invention, the other optical system may be combined that is properly selected from conventional systems, for example, an optical system to compensate the optical quantity distribution may be employed additionally.

The optical system to compensate the optical quantity distribution alters the luminous flux width at each output site such that the ratio of the luminous flux width at the periphery region to the luminous flux width at the central region near the optical axis is higher in the output side than the input side, thus the optical quantity distribution at the exposed surface is compensated to be approximately constant when the parallel luminous flux from the laser source is irradiated to DMD. The optical system to compensate the optical quantity distribution will be explained with reference to figures in the following.

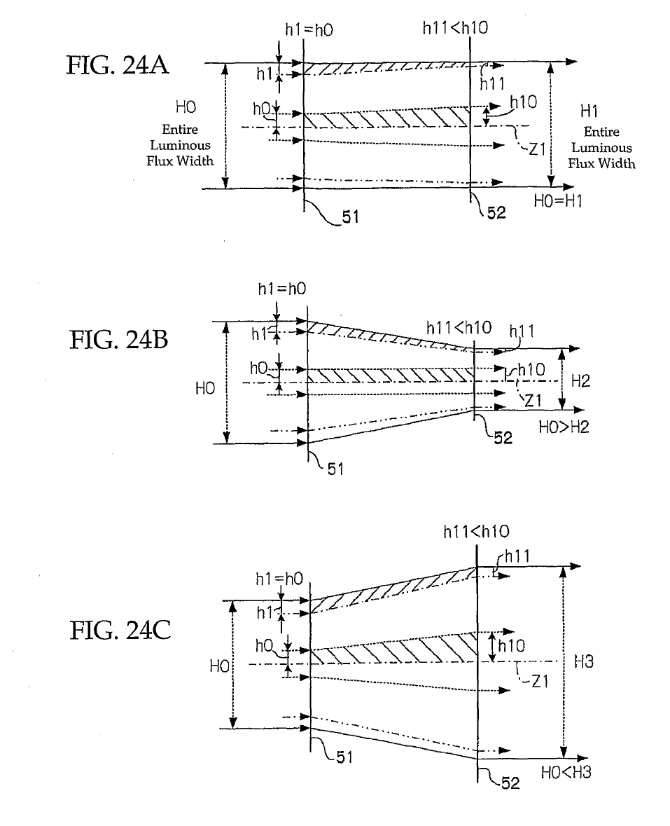

Initially, the optical system will be explained as for the case that the entire luminous flux widths H0 and H1 are the same between the input luminous flux and the output luminous flux, as shown in FIG. 24 A. The portions denoted by reference numbers 51, 52 in FIG. 24 A indicate imaginarily the input surface and output surface of the optical system to compensate the optical quantity distribution.

In the optical system to compensate the optical quantity distribution, it is assumed that the luminous flux width h0 of the luminous flux entered at central region near the optical axis Z1 and luminous flux width h1 of the luminous flux entered at peripheral region near are the same (h0=h1). The optical system to compensate the optical quantity distribution affects the laser beam that has the same luminous fluxes h0, h1 at the input side, and acts to magnify the luminous flux width h0 for the input luminous flux at the central region, and acts to reduce the luminous flux width h1 for the input luminous flux at the periphery region conversely. Namely, the optical system affects the output luminous flux width h10 at the central region and the output luminous flux width h11 at the periphery region to turn into h11<h10. In other words concerning the ratio of luminous flux width, (output luminous flux width at periphery region)/(output luminous flux width at central region) is smaller than the ratio of input, namely [h11/h10] is smaller than (h1/h0=1) or (h11/h10<1).

Owing to altering the luminous flux width, the luminous flux at the central region representing higher optical quantity may be supplied to the periphery region where the optical quantity is insufficient; thereby the optical quantity distribution is approximately uniformed at the exposed surface without decreasing the utilization efficiency. The level for uniformity is controlled such that the nonuniformity of optical quantity is 30% or less in the effective region for example, preferably is 20% or less.

When the luminous flux width is entirely altered for the input side and the output side, the operation and effect due to the optical system to compensate the optical quantity distribution are similar to those shown in FIGS. 24A, 24B, and 24C.

FIG. 24B shows the case that the entire optical flux bundle H0 is reduced and outputted as optical flux bundle H2 (H0>H2). In such a case also, the optical system to compensate the optical quantity distribution tends to process the laser beam, in which luminous flux width h0 is the same as h1 at input side, into that the luminous flux width h10 at the central region is larger than the spherical region and the luminous flux width h11 is smaller than the central region in the output side. Considering the reduction ratio of the luminous flux, the optical system affects to decrease the reduction ratio of input luminous flux at the central region compared to the peripheral region, and affects to increase the reduction ratio of input luminous flux at the peripheral region compared to the central region. In the case also, (output luminous flux width at periphery region)/(output luminous flux width at central region) is smaller than the ratio of input, namely [H11/H10] is smaller than (h1/h0=1) or (h11/h10<1).

FIG. 24C explains the case that the entire luminous flux width H0 at input side is magnified and output into width H3 (H0<H3). In such a case also, the optical system to compensate the optical quantity distribution tends to process the laser beam, in which luminous flux width h0 is the same as h1 at input side, into that the luminous flux width h10 at the central region is larger than the spherical region and the luminous flux width hill is smaller than the central region in the output side. Considering the magnification ratio of the luminous flux, the optical system affects to increase the magnification ratio of input luminous flux at the central region compared to the peripheral region, and affects to decrease the magnification ratio of input luminous flux at the peripheral region compared to the central region. In the case also, (output luminous flux width at periphery region)/(output luminous flux width at central region) is smaller than the ratio of input, namely [H11/H10] is smaller than (h1/h0=1) or (h11/h10<1).

As such, the optical system to compensate the optical quantity distribution alters the luminous flux width at each input site, and lowers the ratio (output luminous flux width at periphery region)/(output luminous flux width at central region) at output side compared to the input side; therefore, the laser beam having the same luminous flux turns into the laser beam at output side that the luminous flux width at central region is larger compared to that at the peripheral region and the luminous flux at the peripheral region is smaller compared to the central region. Owing to such effect, the luminous flux at the central region may be supplied to the periphery region, thereby the optical quantity distribution is approximately uniformed at the luminous flux cross section without decreasing the utilization efficiency of the entire optical system.

Specific lens data of a pair of combined lenses will be set forth exemplarily that is utilized for the optical system to compensate the optical quantity distribution. In this discussion, the lens data will be explained in the case that the optical quantity distribution shows Gaussian distribution at the cross section of the output luminous flux, such as the case that the laser source is a laser array as set forth above. In a case that one semiconductor laser is connected to an input end of single mode optical fiber, the optical quantity distribution of output luminous flux from the optical fiber shows Gaussian distribution. The pattern forming process according to the present invention may be applied, in addition, to such a case that the optical quantity near the central region is significantly larger than the optical quantity at the peripheral region as the case that the core diameter of multimode optical fiber is reduced and constructed similarly to a single mode optical fiber, for example.

The essential data for the lens are summarized in Table 1 below.

TABLE 1
Basic Lens Data

| Si | ri | di | Ni |
|---|---|---|---|
| (surface No.) | (curvature radius) | (surface distance) | (refractive index) |
| 01 | non-spherical | 5.000 | 1.52811 |
| 02 | ∞ | 50.000 | |
| 03 | ∞ | 7.000 | 1.52811 |
| 04 | non-spherical | | |

As demonstrated in Table 1, a pair of combined lenses is constructed from two non-spherical lenses of rotational symmetry. The surfaces of the lenses are defined that the surface of input side of the first lens disposed at the light input side is the first surface; the opposite surface at light output side is the second surface; the surface of input side of the second lens disposed at the light input side is the third surface; and the opposite surface at light output side is the fourth surface. The first and the fourth surfaces are non-spherical.

In Table 1, ‘Si (surface No.)’ indicates “i” th surface (i=1 to 4), ‘ri (curvature radius)’ indicates the curvature radius of the “i” th surface, di (surface distance) means the surface distance between “i” th surface and “i+1” surface. The unit of di (surface distance) is millimeter (mm). Ni (refractive index) means the refractive index of the optical element comprising “i” th surface for the light of wavelength 405 nm.

In Table 2 below, the non-spherical data of the first and the fourth surface are summarized.

TABLE 2
non-spherical data

| | first surface | fourth surface |
|---|---|---|
| C | −1.4098 × 10⁻² | −9.8506 × 10⁻³ |
| K | −4.2192 | −3.6253 × 10 |
| a3 | −1.0027 × 10⁻⁴ | −8.9980 × 10⁻⁵ |
| a4 | 3.0591 × 10⁻⁵ | 2.3060 × 10⁻⁵ |
| a5 | −4.5115 × 10⁻⁷ | −2.2860 × 10⁻⁶ |
| a6 | −8.2819 × 10⁻⁹ | 8.7661 × 10⁻⁸ |
| a7 | 4.1020 × 10⁻¹² | 4.4028 × 10⁻¹⁰ |
| a8 | 1.2231 × 10⁻¹³ | 1.3624 × 10⁻¹² |
| a9 | 5.3753 × 10⁻¹⁶ | 3.3965 × 10⁻¹⁵ |
| a10 | 1.6315 × 10⁻¹⁸ | 7.4823 × 10⁻¹⁸ |

The non-spherical data set forth above may be expressed by means of the coefficients of the following equation (A) that represent the non-spherical shape.

$$Z = \frac{C \cdot {ρ}^{2}}{1 + \sqrt{1 - K \cdot {( C \cdot ρ )}^{2}}} + {\sum }_{i = 3}^{10} ai \cdot {ρ}^{i} \qquad ( A )$$

In the above formula (A), the coefficients are defined as follows:
Z: length of perpendicular that extends from a point on non-spherical surface at height p from optical axis (mm) to tangent plane at vertex of non-spherical surface or plane vertical to optical axis;
ρ: distance from optical axis (mm);
K: coefficient for circular conic;
C: paraxial curvature (1/r, r: radius of paraxial curvature);
ai: “i” st non-spherical coefficient (i=3 to 10).

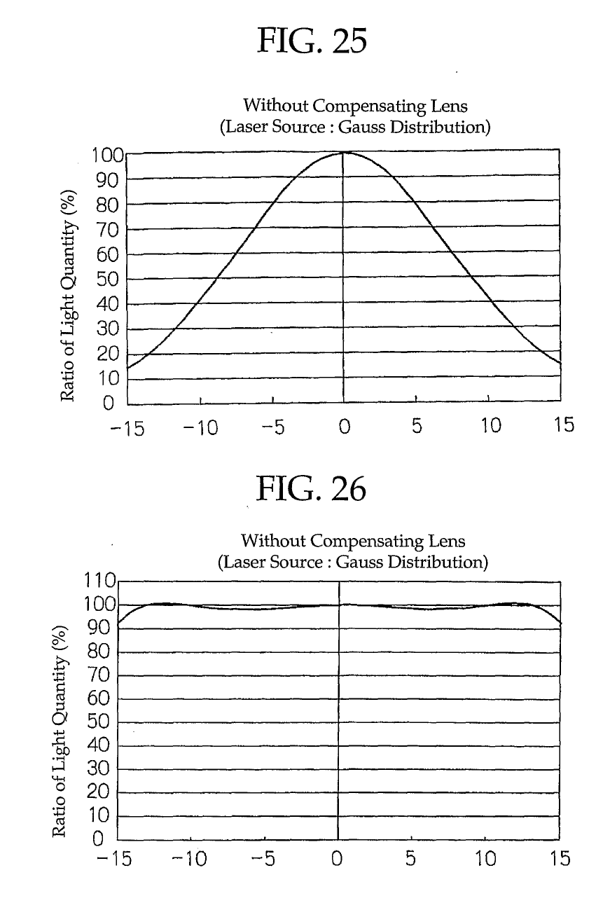

FIG. 26 shows the optical quantity distribution of illumination light obtained by a pair of combined lenses shown in Table 1 and Table 2. The abscissa axis represents the distance from the optical axis, the ordinate axis represents the proportion of optical quantity (%). FIG. 25 shows the optical quantity distribution (Gaussian distribution) of illumination light without the compensation. As is apparent from FIGS. 25 and 26, the compensation by means of the optical system to compensate the optical quantity distribution brings about an approximately uniform optical quantity distribution significantly exceeding that without the compensation, thus uniform exposing may be achieved by means of uniform laser beam without decreasing the optical utilization efficiency.

### [Other Steps]

The other steps may be properly conducted by applying the conventional steps for forming patterns such as developing step, etching step, and plating step. These steps may be employed singly or in combination.

In the developing step, the photosensitive layer of the pattern forming material is exposed, the exposed region of the photoconductive layer is hardened, then the unhardened region is removed, thereby a pattern is produced.

The developing step may be performed by a developing unit, which is properly selected depending on the application as long as a developing liquid is employed. The developing step may be performed by spraying the developing liquid, coating the developing liquid, or dipping into the developing liquid. These may be used alone or in combination. The developing unit may be equipped with a subunit for exchanging the developing liquid, a subunit for supplying the developing liquid, and the like.

The developer may be properly selected depending on the application; examples of the developers include alkaline liquid, aqueous developing liquids, and organic solvents; among these, weak alkali aqueous solutions are preferable. The basic components of the weak alkali aqueous solutions are exemplified by lithium hydroxide, sodium hydroxide, potassium hydroxide, lithium carbonate, sodium carbonate, potassium carbonate, lithium hydrogencarbonate, sodium hydrogencarbonate, potassium hydrogencarbonate, sodium phosphate, potassium phosphate, sodium pyrophosphate, potassium pyrophosphate, and borax.

Preferably, the weak alkali aqueous solution exhibits a pH of about 8 to 12, more preferably is about 9 to 11. Examples of such a solution are aqueous solutions of sodium carbonate and potassium carbonate at a concentration of 0.1 to 5% by mass. The temperature of the developer may be properly selected depending on the developing ability of the developer; for example, the temperature of the developer is about 25 to 40° C.

The developer may be combined with surfactants, defoamers; organic bases such as ethylene diamine, ethanol amine, tetramethylene ammonium hydroxide, diethylene triamine, triethylene pentamine, morpholine, and triethanol amine; organic solvents to promote developing such as alcohols, ketones, esters, ethers, amides, and lactones. The developer set forth above may be an aqueous developer is selected from aqueous solutions, aqueous alkali solutions, combined solutions of aqueous solutions and organic solvents, or an organic developer.

The etching may be carried out by a method selected properly from conventional etching method.

The etching liquid in the etching method may be properly selected depending on the application; when the metal layer set forth above is formed of copper, exemplified are cupric chloride solution, ferric chloride solution, alkali etching solution, and hydrogen peroxide solution for the etching liquid; among these, ferric chloride solution is preferred in light of the etching factor.

The etching treatment and the removal of the pattern forming material may form a permanent pattern on the substrate. The permanent pattern may be properly selected depending on the application; for example, the pattern is of wiring.

The plating step may be performed by a method selected from conventional plating treatment methods.

Examples of the plating treatment include copper plating such as copper sulfate plating and copper pyrophosphate plating, solder plating such as high flow solder plating, nickel plating such as watt bath (nickel sulfate-nickel chloride) plating and nickel sulfamate plating, and gold plating such as hard gold plating and soft gold plating.

A permanent pattern may be formed by performing a plating treatment in the plating step, followed by removing the pattern forming material and optional etching treatment on unnecessary portions.

### [Process for Producing Printed Wiring Board and Color Filter]

The pattern forming process according to the present invention may be successfully applied to the production of printed wiring boards, in particular the printed wiring boards having through holes or via holes, and to the production of color filters. The processes for producing printed wiring boards and color filters based on the pattern forming process according to the present invention will be exemplarily explained in the following.

### —Process for Producing Printed Wiring Board—

In process for producing printed wiring boards having through holes and/or via holes, a pattern may be formed by (i) laminating the pattern forming material on a substrate of a printed wiring board having holes such that the photosensitive layer faces the substrate thereby to form a laminated body, (ii) irradiating a light onto the regions for forming wiring patterns and holes from the opposite side of the substrate of the laminated body thereby to harden the photosensitive layer, (iii) removing the support of the pattern forming material from the laminated body, and (iv) developing the photosensitive layer of the laminated body to remove unhardened portions in the laminated body.

By the way, removing the support of (iii) may be carried out between the (i) and (ii) instead of between (ii) and (iv) set forth above.

Then, using the formed pattern, etching treatment or plating treatment of the substrate of the printed wiring board by means of conventional subtractive or additive method e.g. semi-additive or full-additive method may produce the printed wiring board. Among these methods, the subtractive method is preferable in order to form printed wiring boards by industrially advantageous tenting. After the treatment, the hardened resin remaining on the substrate of the printed wiring board is peeled, or copper thin film is etched after the peeling in the case of semi-additive process, thereafter the intended printed wiring board is obtained. In the case of multi-layer printed wiring board, the similar process with the printed wiring board may be applicable.

The process for producing printed wiring boards having through holes by means of the pattern forming material will be explained in the following.

Initially, the substrate of printed wiring board is prepared in which the surface of the substrate is covered with a metal plating layer. The substrate of printed wiring board may be a copper-laminated layer substrate, a substrate that is produced by forming a copper plating layer on a insulating substrate such as glass or epoxy resin, or a substrate that is laminated on these substrate and formed into a copper plating layer.

In a case that a protective layer exists on the pattern forming material, the protective film is peeled, and the photosensitive layer of the pattern forming material is contact bonded to the surface of the printed wiring board by means a pressure roller as a laminating process, thereby a laminated body may be obtained that contains the substrate of the printed wiring board and the laminated body set forth above.

The laminating temperature of the pattern forming material may be properly selected without particular limitations; the temperature may be about room temperature such as 15 to 30° C., or higher temperature such as 30 to 180° C., preferably it is substantially warm temperature such as 60 to 140° C.

The roll pressure of the contact bonding roll may be properly selected without particular limitations; preferably the pressure is 0.1 to 1 MPa; the velocity of the contact bonding may be properly selected without particular limitations, preferably, the velocity is 1 to 3 meter/minute.

The substrate of the printed wiring board may be pre-heated before the contact bonding; and the substrate may be laminated under a reduced pressure.

The laminated body may be formed by laminating the pattern forming material on the substrate of the printed wiring board; alternatively by coating the solution of the photosensitive resin composition for pattern forming material directly on the substrate of the printed wiring board, followed by drying the solution, thereby laminating the photosensitive layer and the support on the substrate of the printed wiring board.

Then, a laser beam is irradiated onto the photosensitive layer from the opposite side of the substrate of the laminated body thereby to harden the photosensitive layer. In such a case, the irradiation is performed after the support is peeled, depending on the requirement such that the transparency of the support is lower.

In the case that the support exists on the substrate after the laser irradiation, the support is peeled from the laminated body as the support peeling step.

The un-hardened region of the photosensitive layer on the substrate of the printed wiring board is dissolved away by means of an appropriate developer, a pattern is formed that contains a hardened layer for forming a wiring pattern and a hardened layer for protecting a metal layer of through holes, and the metal layer is exposed at the substrate surface of the printed wiring board as the developing step.

Additional treatment to promote the hardening reaction, for example, may be performed by means of post-heating or post-exposing optionally. The developing may be of a wet method set forth above or a dry developing method.

Then, the metal layer exposed on the substrate surface of the printed wiring board is dissolved away by an etching liquid as an etching process. The apertures of the through holes are covered by cured resin or tent film, therefore, the etching liquid does not infiltrate into the through holes to corrode the metal plating within the through holes, and the metal plating may maintain the specific shape, thus a wiring pattern may be formed on the substrate of the printed wiring board.

The etching liquid may be properly selected depending on the application; cupric chloride solution, ferric chloride solution, alkali etching solution, and hydrogen peroxide solution are exemplified for the etching liquid when the metal layer set forth above is formed of copper; among these, ferric chloride solution is preferred in light of the etching factor.

Then, the hardened layer is removed from the substrate of the printed wiring board by means of a strong alkali aqueous solution for example as the removing step of hardened material.

The basic component of the strong alkali aqueous solution may be properly selected without particular limitations, examples of the basic component include sodium hydroxide and potassium hydroxide. The pH of the strong alkali aqueous solution may be about 12 to 14 for example, preferably is about 13 to 14. The strong alkali aqueous solution may be an aqueous solution of sodium hydroxide or potassium hydroxide at a concentration of 1 to 10% by mass.

The printed wiring board may be of multi-layer construction. By the way, the pattern forming material set forth above may be applied to plating processes instead of the etching process set forth above. The plating method may be copper plating such as copper sulfate plating and copper pyrophosphate plating, solder plating such as high flow solder plating, nickel plating such as watt bath (nickel sulfate-nickel chloride) plating and nickel sulfamate plating, and gold plating such as hard gold plating and soft gold plating.

### —Process for Producing Color Filter—

When a support is peeled away from a pattern forming material after laminating a photosensitive layer of a pattern forming material on a substrate such as glass substrate, there exist problems that the charged support or film and an operator may feel an unpleasant electric shock and dust may deposit on the charged support. Accordingly, it is preferred that a conductive layer is provided on the support or the support is treated to take conductivity. Further, when the conductive layer is provided on the support opposite to the photosensitive layer, it is preferred that a hydrophobic polymer layer is provided on the support to improve scratch resistance.

Then a pattern forming material having a red photosensitive layer, a pattern forming material having a green photosensitive layer, a pattern forming material having a blue photosensitive layer, and a pattern forming material having a black photosensitive layer are prepared. Using the pattern forming material having the red photosensitive layer for red pixels, the red photosensitive layer is laminated to the substrate to form a laminated body, followed by exposing and developing image-wise to form red pixels. After forming the red pixels, the laminated body is heated to harden the un-hardened regions. These procedures are conducted similarly in terms of the green pixels and blue pixels to form the respective pixels.

The laminated body may be formed by laminating the pattern forming material on the glass substrate, alternatively, by a way that a solution of photosensitive resin composition for pattern forming material is directly coated on the glass substrate and the solution is dried. When three types of red, green, and blue pixels are disposed, the pattern may be mosaic type, triangle type, four pixel type, or the like.

The pattern forming material having the black photosensitive layer is laminated on the disposed pixels, then exposure is conducted from the side without the pixels and development is conducted to form a black matrix. The laminate having the black matrix is heated to harden the un-hardened regions to produce a color filter.

The pattern forming processes and the pattern forming materials according to the present invention can suppress the sensitivity drop of the photosensitive layer, and employ a pattern forming material capable of forming highly fine and precise patterns, therefore, the exposing can be performed at less energy quantity and at higher rate, which resulting in advantageously higher processing rate.

The pattern forming processes according to the present invention can be properly applied, owing to the pattern forming material according to the present invention, to produce various patterns, to form patterns such as wiring patterns, to produce liquid crystal materials such as color filters, column materials, rib materials, spacers, partitions, and the like, and to produce holograms, micromachines, proofs, and the like; in particular, the pattern forming processes can be properly applied to form highly fine and precise wiring patterns. Further, the pattern forming apparatuses according to the present invention can be properly applied, owing to the pattern forming material according to the present invention, to produce various patterns, to form patterns such as wiring patterns, to produce liquid crystal materials such as color filters, column materials, rib materials, spacers, partitions, and the like, and to produce holograms, micromachines, proofs, and the like; in particular, the pattern forming apparatuses can be properly applied to form highly fine and precise wiring patterns.

The present invention will be illustrated in more detailed with reference to examples given below, but these are not to be construed as limiting the present invention. All parts are by mass unless indicated otherwise.

### EXAMPLE 1

### Production of Pattern Forming Material

The solution of photosensitive resin composition containing the ingredients described below was coated on a polyethylene terephthalate film (16FB50, 16 μm thick, by Toray Industries Inc.) as the support and the coating was dried to form a photosensitive layer of 15 μm thick on the support, thereby to prepare a pattern forming material according to the present invention.

[Ingredients of Solution of photosensitive Resin Composition]

| | | |
|---|---|---|
| Phenothiazine | 0.0049 | part |
| Copolymer of methyl methacrylate/styrene/benzyl | 16 | parts |
| methacrylate/methacrylic acid (mass ratio: 8/30/37/25, | | |
| mass-averaged molecular mass: 60000, acid value: 163) | | |
| Polymerizable monomer expressed by the formula (72) | 7.0 | parts |
| below | | |
| Adduct of hexamethylene diisocyanate and tetraethylene | 7.0 | parts |
| oxide | | |
| monomethacrylate (mole ratio: 1/2) | | |
| 2,2-bis(o-chlorophenyl)-4,4′,5,5′-tetraphenylbiimidazole | 2.17 | parts |
| N-methylacridone | 0.11 | part |
| 2-mercaptobenzimidazole | 0.23 | part |
| Oxalate of Malachite Green | 0.02 | part |
| Leucocrystal violet | 0.26 | part |
| Methyl ethyl ketone | 40 | parts |
| 1-methoxy-2-propanol | 20 | parts |
| Fluorine-containing surfactant (F780F, by Dainippon Ink | 0.0027 | part |
| and Chemicals, Inc.) | | |

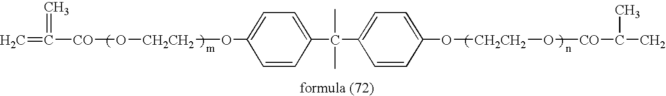

wherein, m+n=10 in formula (72).

The phenothiazine indicated above is a polymerization inhibitor that contains an aromatic ring, heterocyclic ring, and imino group in the molecule.

A polypropylene film of 20 μm thick (E-200C, by Oji Paper Co.) as the protective film was laminated on the photosensitive layer of the pattern forming material. Then, a copper laminated plate (without through holes, copper thickness: 12 μm), which had been polished, rinsed, and dried, was prepared as a substrate. To the copper laminated plate, the photosensitive layer was contact bonded while the protective film of the pattern forming material was peeled away by means of Laminator (Model 8B-720-PH, by Taisei-Laminator Co.) so as to contact the photosensitive layer with the copper laminated plate, thereby a laminated body was obtained which comprised the copper laminated plate, the photosensitive layer, and the polyethylene terephthalate as the support in this order.

The conditions of the contact bonding were as follows, i.e. temperature of contact bonding roll: 105° C., pressure of contact bonding roll: 0.3 MPa, and laminating rate: 1 meter/minute (m/min).

The resulting laminated body was evaluated as to the shortest developing period, sensitivity or minimum energy, and resolution. The results are shown in Table 3.

### <Shortest Developing Period>

The polyethylene terephthalate film as the support was peeled away from the laminated body, then an aqueous solution of sodium carbonate at 1% by mass concentration was sprayed on the entire surface of the photosensitive layer on the copper laminated plate at 30° C. and 0.15 MPa. The period from the initial spraying to the dissolving away of the photosensitive layer on the copper laminated plate was measured, and the period was defined as the shortest developing period. As the result, the shortest developing period was about 10 seconds.

### <Sensitivity or Minimum Energy>

Laser beam was irradiated to the photosensitive layer of the pattern forming material in the laminated body, in which the laser beam was varied as to the optical energy quantity from 0.1 mJ/cm² to 100 mJ/cm² in every increments of 2½ times, the laser beam was irradiated from the side of the polyethylene terephthalate film by means of a pattern forming apparatus that was equipped with a laser source of 405 nm, thereby a part of the photosensitive layer was hardened.

After allowing to stand for 10 minutes at room temperature, the polyethylene terephthalate film as the support was peeled away from the laminated body, then an aqueous solution of sodium carbonate at 1% by mass concentration was sprayed on the entire surface of the photosensitive layer on the copper laminated plate at 30° C. and 0.15 MPa for the period of two times the shortest developing period set forth above, thereby the un-hardened portion was removed away, and the thickness of the remaining hardened layer was measured. Then, a sensitivity curve was prepared by plotting the relation between irradiated optical quantity and the thicknesses of the hardened layers. From the resulting sensitivity curve, the energy of the laser beam at which the thickness of the hardened region corresponded to 15 μm was determined, and the energy of the laser beam corresponding to 15 μm, which was the thickness of the photosensitive layer prior to the exposing, was defined as the minimum energy of the laser beam that was required to yield substantially the same thickness of photosensitive layer subsequent to the developing as the thickness of the photosensitive layer prior to the exposing.

Consequently, the minimum energy of the laser beam was 4.0 mJ/cm². The pattern forming apparatus described above was equipped with a laser modulator of DMD.

A laminated body was prepared in the same way as the Shortest Developing Period set forth above, and was allowed to stand in an ambient condition of 23° C. and 55% relative humidity for 10 minutes. From above the polyethylene terephthalate film as the support of the resulting laminated body, a line pattern was exposed by means of the pattern forming apparatus described above in a condition, i.e. line/space=1/1, line widths: 5 to 20 μm, increment of line: 1 μm/line, and line widths: 20 to 50 μm, increment of line: 5 μm/line. The optical quantity in the exposure was adjusted to the minimum energy of the laser beam necessary to cure the photosensitive layer set forth above. After allowing to stand in an ambient condition for 10 minutes, the polyethylene terephthalate film as the support was peeled away from the laminated body, then an aqueous solution of sodium carbonate at 1% by mass concentration was sprayed on the entire surface of the photosensitive layer on the copper laminated plate at 30° C. and 0.15 MPa for the period of two times the shortest developing period set forth above, thereby the un-hardened portion was removed away. The resultant copper laminated plate with hardened resin pattern was observed by means of an optical microscope; and the narrowest line width, at which abnormality of lines such as clogging, deformation, or the like does not exist, was determined, then the narrowest width was defined as the resolution. Namely, the smaller value means the better resolution.

### EXAMPLE 2

A pattern forming material was produced in the same manner as Example 1, except that phenothiazine in the solution of the photosensitive resin composition was changed into catechol.

The shortest developing period, sensitivity, and resolution were evaluated for the resulting pattern forming material as shown in Table 3. The shortest developing period was about 10 seconds; and the minimum energy of the laser beam required to yield substantially the same thickness of photosensitive layer subsequent to the developing was 4.0 mJ/cm². The catechol is a polymerization inhibitor that contains an aromatic ring and two phenolic hydroxide groups.

### EXAMPLE 3

A pattern forming material was produced in the same manner as Example 1, except that phenothiazine in the solution of the photosensitive resin composition was changed into 4-t-butylcatechol.

The shortest developing period, sensitivity, and resolution were evaluated for the resulting pattern forming material as shown in Table 3. The shortest developing period was about 10 seconds; and the minimum energy of the laser beam required to yield substantially the same thickness of photosensitive layer subsequent to the developing was 4.0 mJ/cm². The 4-t-butylcatechol is a polymerization inhibitor that contains an aromatic ring and two phenolic hydroxide groups.

### EXAMPLE 4

A pattern forming material was produced in the same manner as Example 1, except that phenothiazine in the solution of the photosensitive resin composition was changed into phenoxazine.

The shortest developing period, sensitivity, and resolution were evaluated for the resulting pattern forming material as shown in Table 3. The shortest developing period was about 10 seconds; and the minimum energy of the laser beam was 4.0 mJ/cm². The phenoxazine is a polymerization inhibitor that contains an aromatic ring, heterocyclic ring, and imino group.

### EXAMPLE 5

A pattern forming material was produced in the same manner as Example 1, except that N-methylacridone in the solution of the photosensitive resin composition was changed into 10-butyl-2-chloroacridone.

The shortest developing period, sensitivity, and resolution were evaluated for the resulting pattern forming material as shown in Table 3. The shortest developing period was about 10 seconds; and the minimum energy of the laser beam was 6.0 mJ/cm².

### EXAMPLE 6

A pattern forming material was produced in the same manner as Example 1, except that N-methylacridone in the solution of the photosensitive resin composition was changed into 7-diethylamino-4-methylcoumarine.

The shortest developing period, sensitivity, and resolution were evaluated for the resulting pattern forming material as shown in Table 3. The shortest developing period was about 10 seconds; and the minimum energy of the laser beam was 8.0 mJ/cm².

### EXAMPLE 7

A pattern forming material was produced in the same manner as Example 1, except that the copolymer of methylmethacrylate/styrene/benzylmethacrylate/methacrylic acid (mass ratio: 8/30/37/25, mass-averaged molecular mass: 60000, acid value: 163) in the solution of the photosensitive resin composition was changed into the copolymer of methylmethacrylate/styrene/methacrylic acid (mass ratio: 61/15/24, mass-averaged molecular mass: 100000, acid value: 144).

The shortest developing period, sensitivity, and resolution were evaluated for the resulting pattern forming material as shown in Table 3. The shortest developing period was about 10 seconds; and the minimum energy of the laser beam was 4.0 mJ/cm².

### EXAMPLE 8

A pattern forming material was produced in the same manner as Example 1, except that the support was changed into the polyethylene terephthalate film (R310, 16 μm thick, by Mitsubishi Chemical Polyester Co.).

The shortest developing period, sensitivity, and resolution were evaluated for the resulting pattern forming material as shown in Table 3. The shortest developing period was about 10 seconds; and the minimum energy of the laser beam was 4.0 mJ/cm².

### EXAMPLE 9

A pattern forming material was produced in the same manner as Example 1, except that the protective film was changed into the polypropylene film (E-501, 12 μm thick, by Oji Paper Co.).

The shortest developing period, sensitivity, and resolution were evaluated for the resulting pattern forming material as shown in Table 3. The shortest developing period was about 10 seconds; and the minimum energy of the laser beam was 4.0 mJ/cm².

### EXAMPLE 10

A pattern forming material was produced in the same manner as Example 1, except that the content of the phenothiazine in the solution of the photosensitive resin composition was changed into 0.0098 part.

The shortest developing period, sensitivity, and resolution were evaluated for the resulting pattern forming material as shown in Table 3. The shortest developing period was about 10 seconds; and the minimum energy of the laser beam was 8.0 mJ/cm².

### EXAMPLE 11

A pattern forming material was produced in the same manner as Example 1, except that the content of the phenothiazine in the solution of the photosensitive resin composition was changed into 0.0126 part, and the content of the N-methylacridone was changed into 0.22 part.

The shortest developing period, sensitivity, and resolution were evaluated for the resulting pattern forming material as shown in Table 3. The shortest developing period was about 10 seconds; and the minimum energy of the laser beam was 9.5 mJ/cm².

### EXAMPLE 12

A pattern forming material was produced in the same manner as Example 1, except that the content of the phenothiazine in the solution of the photosensitive resin composition was changed into 0.0025 part, and 0.0025 part of 4-t-butylcatechol was further added to the solution of the photosensitive resin composition.

The shortest developing period, sensitivity, and resolution were evaluated for the resulting pattern forming material as shown in Table 3. The shortest developing period was about 10 seconds; and the minimum energy of the laser beam was 5.0 mJ/cm².

### COMPARATIVE EXAMPLE 1

A pattern forming material was produced in the same manner as Example 1, except that N-methylacridone as the photosensitizer was not added into the solution of the photosensitive resin composition.

The shortest developing period, sensitivity, and resolution were evaluated for the resulting pattern forming material as shown in Table 3. The shortest developing period was about 10 seconds; and the minimum energy of the laser beam was 60 mJ/cm².

### COMPARATIVE EXAMPLE 2

A pattern forming material was produced in the same manner as Example 1, except that phenothiazine as the polymerization inhibitor was not added into the solution of the photosensitive resin composition.

The shortest developing period, sensitivity, and resolution were evaluated for the resulting pattern forming material as shown in Table 3. The shortest developing period was about 10 seconds; and the minimum energy of the laser beam was 3.0 mJ/cm².

### COMPARATIVE EXAMPLE 3

A pattern forming material was produced in the same manner as Example 1, except that N-methylacridone as the photosensitizer and phenothiazine as the polymerization inhibitor were not added into the solution of the photosensitive resin composition.

The shortest developing period, sensitivity, and resolution were evaluated for the resulting pattern forming material as shown in Table 3. The shortest developing period was about 10 seconds; and the minimum energy of the laser beam was 20 mJ/cm².

### EXAMPLE 13

A pattern forming material was produced in the same manner as Example 1, except that the exposing apparatus was changed into the pattern forming apparatus explained following.

The shortest developing period, sensitivity, and resolution were evaluated for the resulting pattern forming material as shown in Table 3. The shortest developing period was about 10 seconds; and the minimum energy of the laser beam was 5.0 mJ/cm².

### <<Pattern Forming Apparatus>>

A pattern forming apparatus was employed that comprised the combined laser source shown in FIGS. 27A to 32 as a laser source; DMD 50 as the laser modulator, in which 1024 micromirrors are arrayed as one array in the main scanning direction shown in FIGS. 4A and 4B, 768 sets of the arrays are arranged in the sub-scanning direction, and 1024 rows×256 lines among these micromirrors can be driven; microlens array 472 in which microlenses 474, of which one surface is toric surface as shown in FIG. 13A, are arrayed; and optical systems 480, 482 that images the laser through the microlens array onto the pattern forming material.

The toric surface of the microlens was as follows. In order to compensate the distortion of the output surface of microlenses 474 as the imaging portions of DMD 50, the distortion at the output surface was measured, and the results were shown in FIG. 14. In FIG. 14, contour lines indicate the identical heights of the reflective surface, the pitch of the contour lines is 5 nm. In FIG. 14, X and Y directions are two diagonals of micromirror 62, the micromirror 62 may rotate around the rotating axis extending to Y direction. In FIGS. 15A and 15B, the height displacements of micromirrors 62 are shown along the X and Y directions respectively.

As shown in FIGS. 14, 15A, and 15B, there exists distortion at the reflective surface of micromirror 62. With respect to the central portion of the micromirror, the distortion in one diagonal direction i.e. Y direction is larger than the other diagonal direction. Therefore, the shape of laser beam B should be distorted at the collected site through microlenses 55a of microlens array 55.

In FIGS. 16A and 16B, the front shape and side shape of the entire microlens array 55 are shown in detail, and also shown the sizes of various portions in the unit of millimeter (mm). As explained before referring to FIGS. 4A and 4B, 1024 lines×256 rows of micromirrors 62 in DMD 50 are driven; correspondingly, microlens array 55 is constructed such that 1024 of microlenses 55a are aligned in width direction to form one row and the 256 rows are arrayed in length direction. In FIG. 16A, each of the sites of microlenses 55a is expressed by “j” in the width direction and “k” in the length direction.

In FIGS. 17A and 17B, the front shape and the side shape of microlens 55a of microlens array 55 are shown respectively. In FIG. 17A, contour lines of microlens 55a are also shown. Each of the end surfaces of the microlenses 55a is non-spherical surface in order to compensate the aberration due to the distortion of the reflective surface of micromirror 62. Specifically, microlens 55a is a toric lens; the curvature radius of optical X direction Rx is −0.125 mm, and the curvature radius of optical Y direction Ry is −0.1 mm.

Accordingly, the collecting condition of laser beam B within the cross section parallel to the X and Y directions are approximately as shown in FIGS. 18A and 18B respectively. Namely, comparing the X and Y directions, the curvature radius of microlens 55a is shorter and the focal length is also shorter in Y direction.

FIGS. 19A, 19B, 19C, and 19D show the simulations of beam diameter near the focal point of microlens 55a in the above noted shape. For the reference, FIGS. 20A, 20B, 20C, and 20D show the simulations for microlens of Rx=Ry=−0.1 mm. The values of “z” in the figures are expressed as the evaluation sites in focus direction of microlens 55a by the distance from the laser beam irradiating surface of microlens 55a.

The surface shape of microlens 55a in the simulation may be calculated by the following equation.

$$Z = \frac{{C}_{x}^{2} {X}^{2} + {C}_{y}^{2} {Y}^{2}}{1 + SQRT ( 1 - {C}_{x}^{2} {X}^{2} - {C}_{y}^{2} {Y}^{2} )}$$

In the above equation, Cx means the curvature (=1/Rx) in X direction, Cy means the curvature (=1/Ry) in Y direction, X means the distance from optical axis in X direction, and Y means the distance from optical axis O in Y direction.

From the comparison of FIGS. 19A to 19D, and FIGS. 20A to 20D, it is apparent in the pattern forming process according to the present invention that the employment of the toric lens as the microlens 55a that has a shorter focal length in the cross section parallel to Y direction than the focal length in the cross section parallel to X direction may reduce the strain of the beam shape near the collecting site. Consequently, images can be exposed on pattern forming material 150 with more clearness and without distortion or strain. In addition, it is apparent that the inventive mode shown in FIGS. 19A to 19D may bring about a wider region with smaller beam diameter, i.e. longer focal depth.

Further, aperture arrays 59 disposed near the collecting site of microlens array 55 are constricted such that each aperture 59a receives only the light through the corresponding microlens 55a. Namely, aperture array 59 may afford the respective apertures with the insurance that the light incidence from the adjacent apertures 59a may be prevented and the extinction ratio may be enhanced.

TABLE 3

| | Polymerization | | Sensitivity¹⁾ | Resolution |
|---|---|---|---|---|
| | Inhibitor | Photosensitizer | mJ/cm² | μm |
| Ex. 1 | phenothiazine | N-methylacridone | 4 | 15 |
| Ex. 2 | catechol | N-methylacridone | 4 | 15 |
| Ex. 3 | 4-t-butylcatechol | N-methylacridone | 4 | 15 |
| Ex. 4 | phenoxazine | N-methylacridone | 4 | 15 |
| Ex. 5 | phenothiazine | 10-butyl-2-chloroacridone | 6 | 15 |
| Ex. 6 | phenothiazine | 7-diethylamino-4- | 8 | 15 |
| | | methylcoumarine | | |
| Ex. 7 | phenothiazine | N-methylacridone | 4 | 15 |
| Ex. 8 | phenothiazine | N-methylacridone | 4 | 15 |
| Ex. 9 | phenothiazine | N-methylacridone | 4 | 15 |
| Ex. 10 | phenothiazine | N-methylacridone | 8 | 15 |
| Ex. 11 | phenothiazine | N-methylacridone | 9.5 | 15 |
| Ex. 12 | phenothiazine + 4- | N-methylacridone | 5 | 15 |
| | t-butylcatechol | | | |
| Ex. 13 | phenothiazine | N-methylacridone | 4 | 12 |
| Com. Ex. 1 | phenothiazine | — | 60 | 15 |
| Com. Ex. 2 | — | N-methylacridone | 3 | 18 |
| Com. Ex. 3 | — | — | 20 | 18 |

¹⁾minimum energy of laser beam

The results of Table 3 demonstrate that the sensitivity drop can be suppressed in the pattern forming materials of Examples 1 to 13, i.e. all of the sensitivities or minimum energies were less than 10 mJ/cm², and also all of pattern forming materials exhibited superior resolution. Further, the results of Example 13, in which a pattern forming apparatus with a toric surface was employed, demonstrates that higher resolution can be obtained. On the other hand, the results of Comparative Example 1 exhibited poor sensitivity, and sensitivity and/or resolution was inferior in Comparative Examples 2 and 3.

### EXAMPLE 14

### Production of Pattern Forming Material

The solution of photosensitive resin composition containing the ingredients described below was coated on a polyethylene terephthalate film (16QS52, 16 μm thick, by Toray Industries Inc.) as the support and the coating was dried to form a photosensitive layer of 15 μm thick on the support, thereby to prepare a pattern forming material according to the present invention.

[Ingredients of Solution of photosensitive Resin Composition]

| | | |
|---|---|---|
| Phenothiazine | 0.0049 | part |
| Copolymer of methacrylic acid/methyl methacrylate/ | 11.8 | parts |
| styrene (mass ratio: 29/19/52, mass-averaged | | |
| molecular mass: 60000, acid value: 189) | | |
| Polymerizable monomer expressed by the formula (72) | 5.6 | parts |
| described above | | |
| Adduct of hexamethylene diisocyanate and | 5.0 | parts |
| tetraethylene oxide monomethacrylate (mole ratio: 1/2) | | |
| Dodecapropyleneglycol diacrylate | 0.56 | part |
| 2,2-bis(o-chlorophenyl)-4,4′,5,5′-tetraphenylbiimidazole | 1.7 | parts |
| 10-butyl-2-chloroacridone | 0.09 | part |
| Oxalate of Malachite Green | 0.016 | part |
| Leucocrystal violet | 0.1 | part |
| Methyl ethyl ketone | 40 | parts |
| 1-methoxy-2-propanol | 20 | parts |
| Fluorine-containing surfactant (F780F, by Dainippon Ink | 0.021 | part |
| and Chemicals, Inc.) | | |

A polypropylene film (Alfan E-501, 12 μm thick, by Oji Paper Co.) as the protective film was laminated on the photosensitive layer of the pattern forming material. Then, a copper laminated plate (without through holes, copper thickness: 12 μm), which had been polished, rinsed, and dried, was prepared as a substrate. To the copper laminated plate, the photosensitive layer was contact bonded while the protective film of the pattern forming material was peeled away by means of Laminator (Model 8B-720-PH, by Taisei-Laminator Co.) so as to contact the photosensitive layer with the copper laminated plate, thereby a laminated body was obtained which comprised the copper laminated plate, the photosensitive layer, and the polyethylene terephthalate as the support in this order.

The conditions of the contact bonding were as follows, i.e. temperature of contact bonding roll: 105° C., pressure of contact bonding roll: 0.3 MPa, and laminating rate: 1 meter/minute.

The support was evaluated as to the total light transmittance and haze. The results are shown in Table 4. The resulting laminated body was evaluated as to the shortest developing period, sensitivity, and resolution in the same manner as Example 1, and also appearance of resist surface. The results are shown in Table 4.

### <Total Light Transmittance>

The total light transmittance was determined by irradiating laser beam of 405 nm wavelength onto the support, using the spectrophotometer (UV-2400, by Shimadzu Co.) equipped with an integrating sphere.

### <Haze>

Parallel light transmittance was determined in the same manner as the total light transmittance except that the integrating sphere was not utilized. Then, diffused light transmittance was determined from the following calculation:

(total light transmittance)−(parallel light transmittance)

and, haze was determined from the following calculation:

haze=(diffused light transmittance)÷(total light transmittance)×100(%)

### <Appearance of Resist Surface>

The patterned resist surface of 50 μm×50 μm, for which the resolution had been determined, was observed by means of a scanning electron microscope (SEM), and the resist surface was evaluated in accordance with the criteria shown below.

### —Evaluation Criteria—

A: There exists no defect or there exist 1 to 5 defects;
   the defects extend no effect on the resulting pattern; and
   there exists no disconnection in wiring pattern after etching.
B: There exist 5 to 10 defects;
   the defects extend no effect on the resulting pattern; and
   there exists no disconnection in wiring pattern after etching.
C: There exist 11 to 20 defects;
   the defects cause abnormal shape at the edge of pattern; and
   there exists disconnection in wiring pattern after etching.
D: There exist 21 or more defects;
   the defects cause abnormal shape at the edge of pattern; and
   there exists disconnection in wiring pattern after etching.

### EXAMPLE 15

A pattern forming material and a laminated body were prepared in the same manner as Example 14, except that the support was prepared in the following way.

### —Preparation of Support—

Polyethylene terephthalate, containing silica particles of average particle size 1.5 μm at a content of 80 ppm, was dried, melted and extruded, and cooled and solidified in a conventional way to form an unoriented film. Then, the unoriented film was stretched 3.5 times in longitudinal direction at 85° C. using a pair of rolls rotating in different peripheral speeds to form a uniaxially oriented film.

Separately, silica particles having an average particle size of 2.5 μm, silica particles having an average particle size of 0.04 μm, and lauryldiphenyletherdisulfonate as an antistatic agent were blended to 100 parts of aqueous dispersion of polyester resin (Vylonal, by Toyobo Co.) in amounts of 1%, 8%, and 10% by mass respectively based on the aqueous dispersion of polyester resin. Then, the mixture was diluted by 1200 parts of water and 800 parts of ethyl alcohol and allowed to stand for 48 hours at 40° C. to prepare a coating liquid for resin layer.

The coating liquid was coated on one side of the uniaxially oriented film by way of gravure printing, and the coating was dried by warm air at 70° C. Then, the uniaxially oriented film was oriented 3.5 times in traverse direction at 98° C. by a tenter, and was thermally fixed at 200 to 210° C., thereby biaxially oriented polyester film of 16 μm thick was prepared that was coated with the resin layer.

The resulting biaxially oriented polyester film as a support was determined as to the total light transmittance and haze. Further, the laminated body was evaluated as to the sensitivity, resolution, and appearance of resist surface. These results are shown in Table 4. The shortest developing period was 7 seconds.

### EXAMPLE 16

A pattern forming material and a laminated body were produced in the same manner as Example 14, except that the support was changed into polyethylene terephthalate film (R340G, 16 μm thick, by Mitsubishi Chemical Polyester Co.). The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 17

A pattern forming material and a laminated body were produced in the same manner as Example 14, except that dodecapropyleneglycol diacrylate was not added into the solution of the photosensitive resin composition. The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 18

A pattern forming material and a laminated body were produced in the same manner as Example 15, except that dodecapropyleneglycol diacrylate was not added into the solution of the photosensitive resin composition. The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 19

A pattern forming material and a laminated body were produced in the same manner as Example 16, except that dodecapropyleneglycol diacrylate was not added into the solution of the photosensitive resin composition. The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 20

A pattern forming material and a laminated body were produced in the same manner as Example 14, except that the exposing apparatus was changed into the pattern forming apparatus employed in Example 13. The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 21

A pattern forming material and a laminated body were produced in the same manner as Example 15, except that the exposing apparatus was changed into the pattern forming apparatus employed in Example 13. The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 22

A pattern forming material and a laminated body were produced in the same manner as Example 16, except that the exposing apparatus was changed into the pattern forming apparatus employed in Example 13. The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 23

A pattern forming material and a laminated body were produced in the same manner as Example 14, except that the support was changed into polyethylene terephthalate film (16FB50, by Toray Industries Inc.). The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 24

A pattern forming material and a laminated body were produced in the same manner as Example 14, except that the support was changed into polyethylene terephthalate film (R310, 16 μm thick, by Mitsubishi Chemical Polyester Co.). The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 25

A pattern forming material and a laminated body were produced in the same manner as Example 17, except that the support was changed into polyethylene terephthalate film (16FB50, by Toray Industries Inc.). The support was evaluated as to the total light transmittance and haze; and the laminated body was evaluated as to the sensitivity, resolution, and appearance of resist surface. These results are shown in Table 4. The shortest developing period was 7 seconds.

### EXAMPLE 26

A pattern forming material and a laminated body were produced in the same manner as Example 17, except that the support was changed into polyethylene terephthalate film (R310, 16 μm thick, by Mitsubishi Chemical Polyester Co.). The support was evaluated as to the total light transmittance and haze; and the laminated body was evaluated as to the sensitivity, resolution, and appearance of resist surface. These results are shown in Table 4. The shortest developing period was 7 seconds.

TABLE 4

| | Support | | | | |
|---|---|---|---|---|---|
| | | Total Light | | | Appearance |
| | | Transmittance | Sensitivity¹⁾ | Resolution | of Resist |
| | Haze % | % | mJ/cm² | μm | Surface |
| Ex. 14 | 0.8 | 87 | 5 | 15 | A |
| Ex. 15 | 2.8 | 90 | 5 | 15 | A |
| Ex. 16 | 2.8 | 89 | 5 | 15 | A |
| Ex. 17 | 0.8 | 87 | 5 | 15 | A |
| Ex. 18 | 2.8 | 90 | 5 | 15 | A |
| Ex. 19 | 2.8 | 89 | 5 | 15 | A |
| Ex. 20 | 0.8 | 87 | 5 | 12 | A |
| Ex. 21 | 2.8 | 90 | 5 | 12 | A |
| Ex. 22 | 2.8 | 89 | 5 | 12 | A |
| Ex. 23 | 5.0 | 88 | 5 | 15 | B |
| Ex. 24 | 4.7 | 88 | 5 | 15 | B |
| Ex. 25 | 5.0 | 88 | 5 | 15 | B |
| Ex. 26 | 4.7 | 88 | 5 | 15 | B |

¹⁾minimum energy of laser beam

The results of Table 4 demonstrate that the pattern forming material according to the present invention can bring about highly fine and precise patterns with superior appearance of resist surface. Further, from the results of Examples 20 to 22, in which a pattern forming apparatus with a toric surface was employed, it is demonstrated that higher resolution can be obtained.

The pattern forming materials according to the present invention can suppress sensitivity drop and provide highly fine and precise patterns, therefore, may be widely applied to produce various patterns, to form patterns such as wiring patterns, to produce liquid crystal materials such as color filters, column materials, rib materials, spacers, partitions, and the like, and to produce holograms, micromachines, proofs, and the like; in particular, the pattern forming materials can be properly applied to form highly fine and precise wiring patterns.

The pattern forming apparatuses and the pattern forming processes according to the present invention can also be properly applied, owing to the pattern forming material according to the present invention, to produce various patterns, to form patterns such as wiring patterns, in particular, to form highly fine and precise wiring patterns.

1. A pattern forming material comprising:
a support, and
a photosensitive layer on the support,
wherein the photosensitive layer comprises a polymerization inhibitor, a binder, a polymerizable compound, and a photopolymerization initiator,
the photosensitive layer is exposed by means of a laser beam and developed by means of a developer to form a pattern, and
the minimum energy of the laser beam is 0.1 mJ/cm² to 10 mJ/cm², which is required to yield substantially the same thickness of photosensitive layer subsequent to the developing as the thickness of the photosensitive layer prior to the exposing.

2. The pattern forming material according to claim 1, wherein the haze of the support is 5.0% or less.

3. The pattern forming material according to claim 1, wherein the total light transmittance of the support is 86% or more.

4. The pattern forming material according to one of claims 2 and 3, wherein the haze and the total light transmittance of the support is determined at an optical wavelength of 405 nm.

5. The pattern forming material according to claim 1, wherein a coating layer that contains inert fine particles is provided on at least one side of the support.

6. The pattern forming material according to claim 1, wherein the support is formed of a biaxially oriented polyester film.

7. The pattern forming material according to claim 1,
wherein the laser beam from a laser source is modulated by a laser modulator that comprises plural imaging portions each capable of receiving the laser beam and outputting the modulated laser beam,
the modulated laser beam is transmitted through a microlens array of plural microlenses each having a non-spherical surface capable of compensating the aberration due to distortion of the output surface of the imaging portions, and
the photosensitive layer is exposed by the modulated and transmitted laser beam.

8. The pattern forming material according to claim 1,
wherein the laser beam from a laser source is modulated by a laser modulator that comprises plural imaging portions each capable of receiving the laser beam and outputting the modulated laser beam,
the modulated laser beam is transmitted through a microlens array of plural microlenses each having an aperture configuration capable of substantially shielding incident light other than the modulated laser beam from the laser modulator, and
the photosensitive layer is exposed by the modulated and transmitted laser beam.

9. The pattern forming material according to claim 1, wherein the polymerization inhibitor comprises at least one of an aromatic ring, a heterocyclic ring, an imino group, and a phenolic hydroxide group.

10. The pattern forming material according to claim 1, wherein the polymerization inhibitor comprises a compound selected from the group consisting of compounds having at least two phenolic hydroxide groups, compounds having an aromatic group substituted by an imino group, compounds having a heterocyclic ring substituted by an imino group, and hindered amine compounds.

11. The pattern forming material according to claim 1, wherein the polymerization inhibitor comprises a compound selected from the group consisting of catechol, phenothiazine, phenoxazine, hindered amines, and derivatives thereof.

12. The pattern forming material according to claim 1, wherein the content of the polymerization inhibitor is 0.005% by mass to 0.5% by mass based on the polymerizable compound.

13. The pattern forming material according to claim 1, wherein the minimum energy of the laser beam is determined at an optical wavelength of 405 nm.

14. The pattern forming material according to claim 1, wherein the photosensitive layer comprises a photosensitizer.

15. The pattern forming material according to claim 14, wherein the maximum absorption wavelength of the photosensitizer appears within a range of 380 nm to 450 nm.

16. The pattern forming material according to claim 14, wherein the photosensitizer is a fused ring compound.

17. The pattern forming material according to claim 14, wherein the photosensitizer comprises a compound selected from the group consisting of acridones, acridines, and coumarins.

18. The pattern forming material according to claim 1, wherein the binder comprises a compound having an acidic group.

19. The pattern forming material according to claim 1, wherein the binder comprises a vinyl copolymer.

20. The pattern forming material according to claim 1, wherein the binder comprises a copolymer selected from the group consisting of styrene copolymers and styrene derivative copolymers.

21. The pattern forming material according to claim 1, wherein the binder has an acidic value of 70 mg KOH/g to 250 mg KOH/g.

22. The pattern forming material according to claim 1, wherein the polymerizable compound comprises a monomer that contains at least one of a urethane group and an aryl group.

23. The pattern forming material according to claim 1, wherein the polymerizable compound has a bisphenol backbone.

24. The pattern forming material according to claim 1, wherein the photopolymerization initiator comprises a compound selected from the group consisting of halogenated hydrocarbon derivatives, hexaaryl biimidazoles, oxime derivatives, organic peroxides, thio compounds, ketone compounds, aromatic onium salts, and metallocenes.

25. The pattern forming material according to claim 1, wherein the photopolymerization initiator comprises a derivative of 2,4,5-triarylimidazole dimer.

26. The pattern forming material according to claim 1, wherein the thickness of the photosensitive layer is 1 μm to 100 μm.

27. The pattern forming material according to claim 1, wherein the support is of an elongated shape.

28. The pattern forming material according to claim 1, wherein the pattern forming material is of an elongated shape formed by winding into a roll shape.

29. The pattern forming material according to claim 1, wherein a protective film is provided on the photosensitive layer of the pattern forming material.

30. A pattern forming apparatus comprising:
a laser source,
a laser modulator, and
a pattern forming material,
wherein the laser source is capable of irradiating a laser beam, and the laser modulator is capable of modulating the laser beam from the laser source and also capable of exposing the photosensitive layer of the pattern forming material,
the pattern forming material comprises a support and a photosensitive layer on the support, the photosensitive layer comprises a polymerization inhibitor, a binder, a polymerizable compound, and a photopolymerization initiator,
the photosensitive layer is exposed by means of a laser beam and developed by means of a developer to form a pattern, and
the minimum energy of the laser beam is 0.1 mJ/cm² to 10 mJ/cm², which is required to yield substantially the same thickness of photosensitive layer subsequent to the developing as the thickness of the photosensitive layer prior to the exposing.

31. The pattern forming apparatus according to claim 30, wherein the laser modulator further comprises a pattern signal generator configured to generate a control signal based on pattern information, and the laser modulator modulates the laser beam from the laser source depending on the control signal from the pattern signal generator.

32. The pattern forming apparatus according to and claim 30, wherein the laser modulator is capable of controlling a part of the plural imaging portions depending on pattern information.

33. The pattern forming apparatus according to claim 30, wherein the laser modulator is a spatial light modulator.

34. The pattern forming apparatus according to claim 33, wherein the spatial light modulator is a digital micromirror device (DMD).

35. The pattern forming apparatus according to claim 32, wherein the imaging portions are comprised of micromirrors.

36. The pattern forming process according to claim 30, wherein the laser source is capable of irradiating two or more types of laser beams together with.

37. The pattern forming process according to claim 30, wherein the laser source comprises plural lasers, a multimode optical fiber, and a collective optical system that collects the laser beams from the plural lasers into the multimode optical fiber.

38. A pattern forming process comprising:
exposing a photosensitive layer of a pattern forming material,
wherein the pattern forming material comprises a support and the photosensitive layer on the support, and the photosensitive layer comprises a polymerization inhibitor, a binder, a polymerizable compound, and a photopolymerization initiator,
the photosensitive layer is exposed by means of a laser beam and developed by means of a developer to form a pattern, and
the minimum energy of the laser beam is 0.1 mJ/cm² to 10 mJ/cm², which is required to yield substantially the same thickness of photosensitive layer subsequent to the developing as the thickness of the photosensitive layer prior to the exposing.

39. The pattern forming process according to claim 38, wherein the pattern forming material is laminated on the substrate under one of heating and pressing and is exposed.

40. The pattern forming process according to claim 38, wherein the exposing is performed image-wise depending on pattern information to be formed.

41. The pattern forming process according to claim 38, wherein the exposing is performed by means of a laser beam that is modulated depending on a control signal, and the control signal is generated depending on pattern information to be formed.

42. The pattern forming process according to claim 38, wherein the exposing is performed by use of a laser source for irradiating a laser beam and a laser modulator for modulating the laser beam depending on pattern information to be formed.

43. The pattern forming process according to claim 42,
wherein the photosensitive film is exposed by means of a laser beam subjected to modulating by a laser modulator and then compensating, and
the compensating is performed by transmitting the modulated laser beam through plural microlenses each having a non-spherical surface capable of compensating the aberration due to distortion of the output surface of the imaging portion.

44. The pattern forming process according to claim 42,
wherein the photosensitive film is exposed by means of a laser beam subjected to modulating by a laser modulator and then transmitting through a microlens array of plural microlenses, and
the microlens array has an aperture configuration of the plural microlenses capable of substantially shielding incident light other than the modulated laser beam from the laser modulator.

45. The pattern forming process according to claim 44, wherein each of the microlenses has a non-spherical surface capable of compensating the aberration due to distortion of the output surface of the imaging portions.

46. The pattern forming process according to one of claims 43 and 44, wherein the non-spherical surface is a toric surface.

47. The pattern forming process according to claim 44, wherein each of the microlenses has a circular aperture configuration.

48. The pattern forming process according to claim 44, wherein the aperture configuration of the plural microlenses is defined by light shielding provided on the microlens surface.

49. The pattern forming process according to claim 38, wherein the exposing is performed by a laser beam transmitted through an aperture array.

50. The pattern forming process according to claim 38, wherein the exposing is performed while moving relatively the laser beam and the photosensitive layer.

51. The pattern forming process according to claim 38, wherein the exposing is performed on a partial region of the photosensitive layer.

52. The pattern forming process according to claim 38, wherein developing of the photosensitive layer is performed subsequent to the exposing.

53. The pattern forming process according to claim 52, wherein a permanent pattern is formed subsequent to the developing.

54. The pattern forming process according to claim 53, wherein the permanent pattern is a wiring pattern, and the permanent pattern is formed by at least one of etching and plating.
